(19) United States
(12) Patent Application Publication
(10) Pub. No.: US 2026/0013110 A1
(43) Pub. Date: Jan. 8, 2026

(54) SEMICONDUCTOR DEVICE, METHOD FOR MANUFACTURING SEMICONDUCTOR DEVICE, AND ELECTRONIC APPLIANCE

(71) Applicant: Semiconductor Energy Laboratory Co., Ltd., Atsugi-shi, Kanagawa-ken (JP)

(72) Inventors: Shunpei YAMAZAKI, Setagaya (JP); Takanori MATSUZAKI, Atsugi (JP); Fumito ISAKA, Zama (JP)

(21) Appl. No.: 19/116,594

(22) PCT Filed: Oct. 23, 2023
(86) PCT No.: PCT/IB2023/060659

§ 371 Date: Mar. 28, 2025

(30) Foreign Application Priority Data
Oct. 28, 2022 (JP) 2022-173648

(51) Int. Cl. H10B 12/00

(52) U.S. Cl. CPC H10B 12/33; H10B 12/05

(57) ABSTRACT

A semiconductor device with favorable electrical characteristics is provided. The semiconductor device includes a transistor, a first interlayer insulating layer, and a second interlayer insulating layer over the first interlayer insulating layer. The transistor includes a first conductive layer functioning as one of a source electrode and a drain electrode and a second conductive layer functioning as the other of the source electrode and the drain electrode, and the first and second interlayer insulating layers are provided between the first conductive layer and the second conductive layer. An opening portion reaching the first conductive layer is provided in the first and second interlayer insulating layers and the second conductive layer, and a semiconductor layer, a first gate insulating layer, and a first gate electrode are provided in this order to include regions positioned in the opening portion. A second gate electrode is provided between the first interlayer insulating layer and the second interlayer insulating layer to cover a side surface of the semiconductor layer. The second gate electrode includes an oxide region including a region in contact with the semiconductor layer. The oxide region functions as a second gate insulating layer.

### TECHNICAL FIELD

One embodiment of the present invention relates to a semiconductor device and a method for manufacturing a semiconductor device. Another embodiment of the present invention relates to a storage device and a method for manufacturing a storage device. Another embodiment of the present invention relates to a transistor and a method for manufacturing a transistor. One embodiment of the present invention relates to an electronic appliance.

Note that one embodiment of the present invention is not limited to the above technical field. Examples of the technical field of one embodiment of the present invention include a semiconductor device, a display device, a light-emitting device, a power storage device, a storage device, an electronic appliance, a lighting device, an input device (e.g., a touch sensor), an input/output device (e.g., a touch panel), a method for driving any of them, and a method for manufacturing any of them.

Note that in this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. In some cases, a storage device, a display device, a light-emitting device, a lighting device, and an electronic appliance themselves are semiconductor devices and also include a semiconductor device.

### BACKGROUND ART

Recently, development of semiconductor devices has been proceeding, and large scale integration circuits (LSI) are used in the semiconductor devices. For example, central processing units (CPUs), memories, and the like are used in the semiconductor devices. A CPU is an aggregation of semiconductor elements; the CPU includes a semiconductor integrated circuit (including at least a transistor and a memory) formed into a chip by processing a semiconductor wafer and is provided with an electrode serving as a connection terminal.

A semiconductor circuit (IC chip) of a CPU, a memory, or the like is mounted on a circuit board, for example, a printed wiring board, to be used as one of components of a variety of electronic appliances.

A technique in which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a semiconductor thin film usable for the transistor and further, an oxide semiconductor has been attracting attention as another material.

It is known that a transistor including an oxide semiconductor has an extremely low leakage current in a non-conduction state. For example, Patent Document 1 discloses a low-power-consumption CPU utilizing a feature of a low leakage current of the transistor including an oxide semiconductor. Furthermore, for example, Patent Document 2 discloses a storage device that can retain stored contents for a long time by utilizing a feature of a low leakage current of the transistor including an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique for achieving an integrated circuit with higher density by stacking a plurality of memory cells by stacking a first transistor including an oxide semiconductor and a second transistor including an oxide semiconductor.

Furthermore, by employing vertical transistors, an integrated circuit with higher density can be achieved. For example, Patent Document 4 discloses a vertical transistor in which a side surface of an oxide semiconductor is covered with a gate electrode with a gate insulating layer therebetween.

### REFERENCES

### Patent Documents

[Patent Document 1] Japanese Published Patent Application No. 2012-257187

[Patent Document 2] Japanese Published Patent Application No. 2011-151383

[Patent Document 3] PCT International Publication No. 2021/053473

[Patent Document 4] Japanese Published Patent Application No. 2013-211537

### Non-Patent Document

[Non-Patent Document 1] M. Oota et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

The threshold voltage of a transistor affects operation of the transistor. For example, an n-channel transistor tends to have normally-on characteristics when the threshold voltage of the transistor is low.

An object of one embodiment of the present invention is to provide a semiconductor device in which the threshold voltage of a transistor can be controlled or a storage device in which the threshold voltage of a transistor can be controlled. Another object of one embodiment of the present invention is to provide a semiconductor device with favorable electrical characteristics or a storage device with favorable electrical characteristics. Another object of one embodiment of the present invention is to provide a highly reliable semiconductor device or a highly reliable storage device. Another object of one embodiment of the present invention is to provide a semiconductor device driven at high speed or a storage device driven at high speed. Another object of one embodiment of the present invention is to provide a semiconductor device that can be miniaturized or highly integrated or a storage device that can be miniaturized or highly integrated. Another object of one embodiment of the present invention is to provide a small-sized semiconductor device or a small-sized storage device. Another object of one embodiment of the present invention is to provide a storage device with large capacity. Another object of one embodiment of the present invention is to provide a semiconductor device with low power consumption or a storage device with low power consumption. Another object of one embodiment of the present invention is to provide an inexpensive semiconductor device or an inexpensive storage device. Another object of one embodiment of the present invention is to provide a transistor with a high on-state current. Another object of one embodiment of the present invention is to provide a transistor with a low off-state current. Another object of one embodiment of the present invention is to provide a transistor with favorable electrical characteristics. Another object of one embodiment of the present invention is to provide a novel semiconductor device, a novel storage device, or a novel transistor.

An object of one embodiment of the present invention is to provide a method for manufacturing a semiconductor device in which the threshold voltage of a transistor can be controlled or a method for manufacturing a storage device in which the threshold voltage of a transistor can be controlled. Another object of one embodiment of the present invention is to provide a method for manufacturing a semiconductor device with favorable electrical characteristics or a method for manufacturing a storage device with favorable electrical characteristics. Another object of one embodiment of the present invention is to provide a method for manufacturing a highly reliable semiconductor device or a method for manufacturing a highly reliable storage device. Another object of one embodiment of the present invention is to provide a method for manufacturing a semiconductor device driven at high speed or a method for manufacturing a storage device driven at high speed. Another object of one embodiment of the present invention is to provide a method for manufacturing a semiconductor device that can be miniaturized or highly integrated or a method for manufacturing a storage device that can be miniaturized or highly integrated. Another object of one embodiment of the present invention is to provide a method for manufacturing a small-sized semiconductor device or a method for manufacturing a small-sized storage device.

Another object of one embodiment of the present invention is to provide a method for manufacturing a storage device with large capacity. Another object of one embodiment of the present invention is to provide a method for manufacturing a semiconductor device with low power consumption or a method for manufacturing a storage device with low power consumption. Another object of one embodiment of the present invention is to provide a method for manufacturing a semiconductor device with high yield or a method for manufacturing a storage device with high yield. Another object of one embodiment of the present invention is to provide a method for manufacturing a transistor with a high on-state current. Another object of one embodiment of the present invention is to provide a method for manufacturing a transistor with a low off-state current. Another object of one embodiment of the present invention is to provide a method for manufacturing a transistor with favorable electrical characteristics. Another object of one embodiment of the present invention is to provide a method for manufacturing a novel semiconductor device, a method for manufacturing a novel storage device, or a method for manufacturing a novel transistor.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a semiconductor device which includes a transistor, a first insulating layer, and a second insulating layer and in which the transistor includes a first conductive layer, a second conductive layer, a third conductive layer, a fourth conductive layer, a semiconductor layer, and a third insulating layer; the first insulating layer is provided over the first conductive layer; the second conductive layer is provided over the first insulating layer; the second insulating layer is provided over the second conductive layer; the third conductive layer is provided over the second insulating layer; the first insulating layer, the second conductive layer, the second insulating layer, and the third conductive layer are provided with an opening portion reaching the first conductive layer; the second conductive layer is provided with an oxide region including a side surface in the opening portion; the semiconductor layer is provided to include a region positioned in the opening portion; the semiconductor layer includes a region in contact with the first conductive layer, a region in contact with the oxide region, and a region in contact with the third conductive layer; the third insulating layer is provided over the semiconductor layer to include a region positioned in the opening portion; and the fourth conductive layer is provided to include a region positioned in the opening portion and to include a region facing the semiconductor layer with the third insulating layer sandwiched therebetween.

Alternatively, in the above embodiment, the oxide region may include an oxide of a material that the second conductive layer comprises.

Alternatively, in the above embodiment, the second conductive layer and the fourth conductive layer may include regions sandwiching a channel formation region of the semiconductor layer in the opening portion.

Alternatively, in the above embodiment, the first conductive layer may include a first layer and a second layer, the second layer may be provided over the first layer, and the semiconductor layer may include a region in contact with a top surface of the first layer and a region in contact with a side surface of the second layer.

Alternatively, in the above embodiment, the first insulating layer may include a first layer, a second layer, and a third layer; the second insulating layer may include a fourth layer, a fifth layer, and a sixth layer; the second layer may be provided over the first layer; the third layer may be provided over the second layer; the fifth layer may be provided over the fourth layer; the sixth layer may be provided over the fifth layer; and the first layer, the third layer, the fourth layer, and the sixth layer may include nitrogen.

Alternatively, in the above embodiment, the second layer and the fifth layer may include oxygen.

An electronic device including the semiconductor device of one embodiment of the present invention and a camera is also one embodiment of the present invention.

Another embodiment of the present invention is a method for manufacturing a semiconductor device, the method including: forming a first conductive layer; forming a first insulating layer over the first conductive layer; forming a second conductive layer over the first insulating layer; forming a second insulating layer over the second conductive layer; forming a third conductive layer over the second insulating layer; forming, in the first insulating layer, the second conductive layer, the second insulating layer, and the third conductive layer, an opening portion reaching the first conductive layer; performing oxidation treatment on a side surface of the second conductive layer in the opening portion to form an oxide region in the second conductive layer; forming a semiconductor layer to include a region positioned in the opening portion and to include a region in contact with the first conductive layer, a region in contact with the oxide region, and a region in contact with the third conductive layer; forming a third insulating layer over the semiconductor layer to include a region positioned in the opening portion; and forming a fourth conductive layer to include a region positioned in the opening portion and to include a region facing the semiconductor layer with the third insulating layer sandwiched therebetween.

Alternatively, in the above embodiment, the oxidation treatment may be performed by microwave treatment in an atmosphere containing oxygen.

Alternatively, in the above embodiment, a first layer and a second layer over the first layer may be formed as the first conductive layer; an opening portion reaching the second layer may be formed in the first insulating layer, the second conductive layer, the second insulating layer, and the third conductive layer after formation of the third conductive layer; and a region of the second layer overlapping with the opening portion may be removed after the oxidation treatment but before formation of the semiconductor layer.

Alternatively, in the above embodiment, the side surface of the second conductive layer in the opening portion may be processed after formation of the opening portion but before formation of the oxide region.

Alternatively, in the above embodiment, the processing may be performed by isotropic etching.

Alternatively, in the above embodiment, a fourth insulating layer including a region in contact with the side surface of the second conductive layer in the opening portion may be formed after formation of the opening portion but before formation of the oxide region; the oxidation treatment may be performed; the fourth insulating layer may be removed; and the semiconductor layer may be formed.

Alternatively, in the above embodiment, a first layer, a second layer over the first layer, and a third layer over the second layer may be formed as the first insulating layer; a fourth layer, a fifth layer over the fourth layer, and a sixth layer over the fifth layer may be formed as the second insulating layer; the fourth insulating layer may be formed to include a region in contact with a top surface of the sixth layer; the fourth insulating layer may include oxygen; and the sixth layer may include nitrogen.

Alternatively, in the above embodiment, the first layer, the third layer, and the fourth layer may include nitrogen.

Alternatively, in the above embodiment, the second layer and the fifth layer may include oxygen.

Alternatively, in the above embodiments, the semiconductor layer may include a metal oxide. The metal oxide may include one or more selected from indium, zinc, and an element M, and the element M may be one or more selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

### Effect of the Invention

One embodiment of the present invention can provide a semiconductor device in which the threshold voltage of a transistor can be controlled or a storage device in which the threshold voltage of a transistor can be controlled. Another embodiment of the present invention can provide a semiconductor device with favorable electrical characteristics or a storage device with favorable electrical characteristics. Another embodiment of the present invention can provide a highly reliable semiconductor device or a highly reliable storage device. Another embodiment of the present invention can provide a semiconductor device driven at high speed or a storage device driven at high speed. Another embodiment of the present invention can provide a semiconductor device that can be miniaturized or highly integrated or a storage device that can be miniaturized or highly integrated. Another embodiment of the present invention can provide a small-sized semiconductor device or a small-sized storage device. Another embodiment of the present invention can provide a storage device with large capacity. Another embodiment of the present invention can provide a semiconductor device with low power consumption or a storage device with low power consumption. Another embodiment of the present invention can provide an inexpensive semiconductor device or an inexpensive storage device. Another embodiment of the present invention can provide a transistor with a high on-state current. Another embodiment of the present invention can provide a transistor with a low off-state current. Another embodiment of the present invention can provide a transistor with favorable electrical characteristics. Another embodiment of the present invention can provide a novel semiconductor device, a novel storage device, or a novel transistor.

One embodiment of the present invention can provide a method for manufacturing a semiconductor device in which the threshold voltage of a transistor can be controlled or a method for manufacturing a storage device in which the threshold voltage of a transistor can be controlled. Another embodiment of the present invention can provide a method for manufacturing a semiconductor device with favorable electrical characteristics or a method for manufacturing a storage device with favorable electrical characteristics. Another embodiment of the present invention can provide a method for manufacturing a highly reliable semiconductor device or a method for manufacturing a highly reliable storage device. Another embodiment of the present invention can provide a method for manufacturing a semiconductor device driven at high speed or a method for manufacturing a storage device driven at high speed. Another embodiment of the present invention can provide a method for manufacturing a semiconductor device that can be miniaturized or highly integrated or a method for manufacturing a storage device that can be miniaturized or highly integrated. Another embodiment of the present invention can provide a method for manufacturing a small-sized semiconductor device or a method for manufacturing a small-sized storage device. Another embodiment of the present invention can provide a method for manufacturing a storage device with large capacity. Another embodiment of the present invention can provide a method for manufacturing a semiconductor device with low power consumption or a method for manufacturing a storage device with low power consumption. Another embodiment of the present invention can provide a method for manufacturing a semiconductor device with high yield or a method for manufacturing a storage device with high yield. Another embodiment of the present invention can provide a method for manufacturing a transistor with a high on-state current. Another embodiment of the present invention can provide a method for manufacturing a transistor with a low off-state current. Another embodiment of the present invention can provide a method for manufacturing a transistor with favorable electrical characteristics. Another embodiment of the present invention can provide a method for manufacturing a novel semiconductor device, a method for manufacturing a novel storage device, or a method for manufacturing a novel transistor.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 is a perspective view illustrating a structure example of a semiconductor device.

FIG. 2A1 and FIG. 2A2 are plan views illustrating a structure example of a semiconductor device. FIG. 2B, FIG. 2C, and FIG. 2D are cross-sectional views illustrating the structure examples of the semiconductor device.

FIG. 3A is a cross-sectional view illustrating a structure example of a semiconductor device.

FIG. 3B is a plan view illustrating the structure example of the semiconductor device.

FIG. 4A to FIG. 4C are cross-sectional views illustrating a structure example of a semiconductor device.

FIG. 5A to FIG. 5D are cross-sectional views illustrating structure examples of a semiconductor device.

FIG. 6A to FIG. 6D are cross-sectional views illustrating structure examples of a semiconductor device.

FIG. 7A1 and FIG. 7A2 are plan views illustrating a structure example of a semiconductor device. FIG. 7B and FIG. 7C are cross-sectional views illustrating the structure example of the semiconductor device.

FIG. 8A to FIG. 8C are cross-sectional views illustrating a structure example of a semiconductor device.

FIG. 9A to FIG. 9D are cross-sectional views illustrating structure examples of a semiconductor device.

FIG. 10A and FIG. 10B are plan views illustrating structure examples of a semiconductor device.

FIG. 11A is a plan view illustrating a structure example of a semiconductor device. FIG. 11B and FIG. 11C are cross-sectional views illustrating the structure example of the semiconductor device.

FIG. 12A is a plan view illustrating a structure example of a semiconductor device. FIG. 12B and FIG. 12C are cross-sectional views illustrating the structure example of the semiconductor device.

FIG. 13A is a plan view illustrating an example of a method for manufacturing a semiconductor device. FIG. 13B and FIG. 13C are cross-sectional views illustrating the example of the method for manufacturing the semiconductor device.

FIG. 14A is a plan view illustrating an example of a method for manufacturing a semiconductor device. FIG. 14B and FIG. 14C are cross-sectional views illustrating the example of the method for manufacturing the semiconductor device.

FIG. 15A1 and FIG. 15A2 are plan views illustrating an example of a method for manufacturing a semiconductor device. FIG. 15B and FIG. 15C are cross-sectional views illustrating the example of the method for manufacturing the semiconductor device.

FIG. 16A is a plan view illustrating an example of a method for manufacturing a semiconductor device. FIG. 16B and FIG. 16C are cross-sectional views illustrating the example of the method for manufacturing the semiconductor device.

FIG. 17A to FIG. 17F are cross-sectional views illustrating an example of a method for manufacturing a semiconductor device.

FIG. 18A1 and FIG. 18A2 are plan views illustrating an example of a method for manufacturing a semiconductor device. FIG. 18B and FIG. 18C are cross-sectional views illustrating the example of the method for manufacturing the semiconductor device.

FIG. 19A1 and FIG. 19A2 are plan views illustrating an example of a method for manufacturing a semiconductor device. FIG. 19B and FIG. 19C are cross-sectional views illustrating the example of the method for manufacturing the semiconductor device.

FIG. 20A1 and FIG. 20A2 are plan views illustrating an example of a method for manufacturing a semiconductor device. FIG. 20B to FIG. 20E are cross-sectional views illustrating the example of the method for manufacturing the semiconductor device.

FIG. 21A is a plan view illustrating an example of a method for manufacturing a semiconductor device. FIG. 21B to FIG. 21E are cross-sectional views illustrating the example of the method for manufacturing the semiconductor device.

FIG. 22A1 and FIG. 22A2 are plan views illustrating a structure example of a storage device.

FIG. 22B and FIG. 22C are cross-sectional views illustrating the structure example of the storage device. FIG. 22D1 and FIG. 22D2 are circuit diagrams illustrating the structure examples of the storage device.

FIG. 23A is a plan view illustrating a structure example of a storage device. FIG. 23B and FIG. 23C are cross-sectional views illustrating the structure example of the storage device.

FIG. 24A is a plan view illustrating a structure example of a storage device. FIG. 24B is a cross-sectional view illustrating the structure example of the storage device.

FIG. 25A is a plan view illustrating a structure example of a storage device. FIG. 25B is a cross-sectional view illustrating the structure example of the storage device.

FIG. 26A is a plan view illustrating a structure example of a storage device. FIG. 26B is a cross-sectional view illustrating the structure example of the storage device.

FIG. 27 is a cross-sectional view illustrating a structure example of a storage device.

FIG. 28A to FIG. 28C are plan views illustrating structure examples of a storage device.

FIG. 29A to FIG. 29C are plan views illustrating structure examples of a storage device.

FIG. 30 is a block diagram illustrating a structure example of a storage device.

FIG. 31A is a schematic view illustrating a structure example of a storage device. FIG. 31B is a circuit diagram illustrating the structure example of the storage device.

FIG. 32A and FIG. 32B are schematic views illustrating structure examples of storage devices.

FIG. 33 is a circuit diagram illustrating a structure example of a storage device.

FIG. 34A and FIG. 34B are diagrams illustrating an example of a chip on which a storage device is mounted.

FIG. 35A and FIG. 35B are diagrams illustrating examples of electronic components.

FIG. 36A to FIG. 36E are schematic views illustrating examples of storage devices.

FIG. 37A to FIG. 37H are diagrams illustrating examples of electronic components.

FIG. 38 is a diagram illustrating an example of a device for space.

FIG. 39A is a cross-sectional view illustrating a structure of a sample. FIG. 39B is a schematic view illustrating a measurement system.

FIG. 40A to FIG. 40C are cross-sectional STEM images of samples.

FIG. 41A to FIG. 41C are graphs showing current-voltage characteristics.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings. For example, in the actual manufacturing process, a layer, a resist mask, or the like might be unintentionally reduced in size by treatment such as etching, which might not be reflected in the drawings for easy understanding.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

A transistor is a kind of semiconductor element and can achieve a function of amplifying a current or a voltage, a switching operation for controlling conduction or non-conduction, and the like. An IGFET (Insulated Gate Field Effect Transistor) and a thin film transistor (TFT) are in the category of a transistor in this specification.

In this specification and the like, a transistor is an element having at least three terminals including a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, the channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases or the crystallinity decreases in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause formation of oxygen vacancies (also referred to as Vo) in an oxide semiconductor, for example.

Note that in this specification and the like, an oxynitride refers to a material in which the oxygen content is higher than the nitrogen content. A nitride oxide refers to a material in which the nitrogen content is higher than the oxygen content.

The contents of elements included in films, such as hydrogen, oxygen, carbon, and nitrogen, can be analyzed using secondary ion mass spectrometry (SIMS) or X-ray photoelectron spectroscopy (XPS). When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, analysis with a combination of SIMS and XPS is preferably used.

In addition, in this specification and the like, the terms “film,” “layer,” and the like can be interchanged with each other depending on the situation. For example, the term “conductive layer” can be changed into the term “conductive film” in some cases, and the term “conductive film” can be changed into the term “conductive layer” in some cases. For example, the term “insulating film” can be changed into the term “insulating layer” in some cases, and the term “insulating layer” can be changed into the term “insulating film” in some cases. For example, the term “semiconductor film” can be changed into the term “semiconductor layer” in some cases, and the term “semiconductor layer” can be changed into the term “semiconductor film” in some cases.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and for example, a potential supplied to a wiring, a potential applied to a circuit, and a potential output from a circuit change with a change of the reference potential.

In this specification and the like, the term “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode or a wiring.

Unless otherwise specified, an off-state current in this specification and the like refers to a leakage current between a source and a drain generated when a transistor is in an off state (also referred to as a non-conducting state or a cutoff state). Unless otherwise specified, an off state in an n-channel transistor refers to a state where a voltage V_{gs} between its gate and source is lower than a threshold voltage Vₜₕ (in a p-channel transistor, higher than Vₜₕ).

In this specification and the like, a top-view shape of a component means the contour shape of the component in a plan view. A plan view means that the component is observed from a normal direction of a surface where the component is formed or from a normal direction of a surface of a support (e.g., a substrate) where the component is formed.

In this specification and the like, a tapered shape refers to such a shape that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, terms for describing arrangement, such as “over”, “under”, “left”, and “right”, are used for convenience in describing a positional relation between components with reference to drawings. The positional relation between components is changed as appropriate in accordance with the direction in which the components are described. Thus, without limitation to terms described in this specification, the description can be changed appropriately depending on the situation.

In this specification and the like, a metal oxide is an oxide of a metal in a broad sense. Metal oxides are classified into an oxide insulator, an oxide conductor (including a transparent oxide conductor), and an oxide semiconductor (also simply referred to as an OS), for example. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor. Note that a metal oxide containing nitrogen is also referred to as a metal oxide in some cases. Furthermore, a metal oxide containing nitrogen may be referred to as a metal oxynitride.

### Embodiment 1

In this embodiment, a semiconductor device of one embodiment of the present invention and a manufacturing method thereof will be described with reference to drawings.

One embodiment of the present invention relates to a semiconductor device including a transistor. The transistor can be a transistor in which a semiconductor layer is provided in an opening portion that is formed in a first interlayer insulating layer over a substrate and a second interlayer insulating layer over the first interlayer insulating layer. With this structure, the channel length direction of the transistor can be a direction that is along side surfaces of the first and second interlayer insulating layers in the opening portion. Thus, the channel length is not affected by the performance of a light-exposure apparatus used for manufacturing the transistor and can be shorter than the resolution limit of the light-exposure apparatus. Thus, the on-state current of the transistor can be increased, and the semiconductor device can be driven at high speed.

Here, a first conductive layer provided under the opening portion is used as one of a source electrode and a drain electrode of the transistor. Specifically, the first and second interlayer insulating layers are provided over the first conductive layer, and the opening portion is provided in the first and second interlayer insulating layers so as to reach the first conductive layer. As the other of the source electrode and the drain electrode of the transistor, a second conductive layer that is provided over the second interlayer insulating layer and has an opening portion overlapping with the above-described opening portion is used. Furthermore, the semiconductor layer is provided to include a region in contact with the first conductive layer and a region in contact with the second conductive layer. A first gate insulating layer is provided over the semiconductor layer, and a first gate electrode is provided over the first gate insulating layer.

Meanwhile, in an n-channel transistor, a shorter channel length leads to a lower threshold voltage, which sometimes causes the transistor to have normally-on characteristics, for example. Thus, the transistor included in the semiconductor device of one embodiment of the present invention is provided with a second gate electrode. This can control the threshold voltage of the transistor, for example. Thus, the threshold voltage of the transistor can be higher than that in the case where the transistor is not provided with the second gate electrode, for example, so that the transistor can be inhibited from having normally-on characteristics. In other words, the transistor can have normally-off characteristics. Accordingly, the semiconductor device can have favorable electrical characteristics.

In this specification and the like, a transistor having normally-on characteristics is regarded as being in a state where a channel exists in a semiconductor layer and a current flows between a source and a drain of the transistor even with no potential supplied to a gate of the transistor. Furthermore, a transistor having normally-off characteristics is regarded as being in a state where no current flows between a source and a drain of the transistor with no potential supplied to a gate of the transistor. Here, in the case of a transistor including a first gate electrode and a second gate electrode, the transistor in a state where a current flows between a source and a drain of the transistor even with no potential supplied to the first gate electrode having a function of controlling the amount of current flowing through a channel formation region of a semiconductor layer is regarded as having normally-on characteristics. The transistor in a state where no current flows between the source and the drain of the transistor with no potential supplied to the first gate electrode is regarded as having normally-off characteristics.

In the semiconductor device of one embodiment of the present invention, the second gate electrode is provided between the first interlayer insulating layer and the second interlayer insulating layer. The second gate electrode has an opening portion overlapping with the opening portion provided in the first and second interlayer insulating layers, and a side surface of the second gate electrode in the opening portion and a region in the vicinity of the side surface constitute an oxide region. The oxide region has a higher electrical resistivity than a region of the second gate electrode other than the oxide region and has an insulating property. The oxide region covers a region of the semiconductor layer that is positioned in the opening portion of the second gate electrode. In the above manner, the oxide region of the second gate electrode functions as a second gate insulating layer.

To manufacture the transistor included in the semiconductor device of one embodiment of the present invention, first, the first conductive layer over the substrate, the first interlayer insulating layer over the first conductive layer, the second gate electrode over the first interlayer insulating layer, the second interlayer insulating layer over the second gate electrode, and the second conductive layer over the second interlayer insulating layer are sequentially formed. Next, the opening portion reaching the first conductive layer is formed in the first interlayer insulating layer, the second gate electrode, the second interlayer insulating layer, and the second conductive layer. After that, oxidation treatment is performed on the side surface of the second gate electrode in the opening portion. Examples of the oxidation treatment include microwave treatment in an atmosphere containing oxygen. By the oxidation treatment, the oxide region is formed in the second gate electrode, and the oxide region functions as the second gate insulating layer.

In this specification and the like, the microwave treatment refers to treatment using an apparatus including a power source that generates high-density plasma with use of a microwave. In this specification and the like, the microwave refers to an electromagnetic wave having a frequency higher than or equal to 300 MHz and lower than or equal to 300 GHz. The microwave treatment can also be referred to as microwave-excited high-density plasma treatment.

Then, the semiconductor layer, the first gate insulating layer, and the first gate electrode are sequentially formed to include regions positioned in the opening portion. Through the above steps, the transistor included in the semiconductor device of one embodiment of the present invention can be manufactured.

### STRUCTURE EXAMPLE 1 OF SEMICONDUCTOR DEVICE

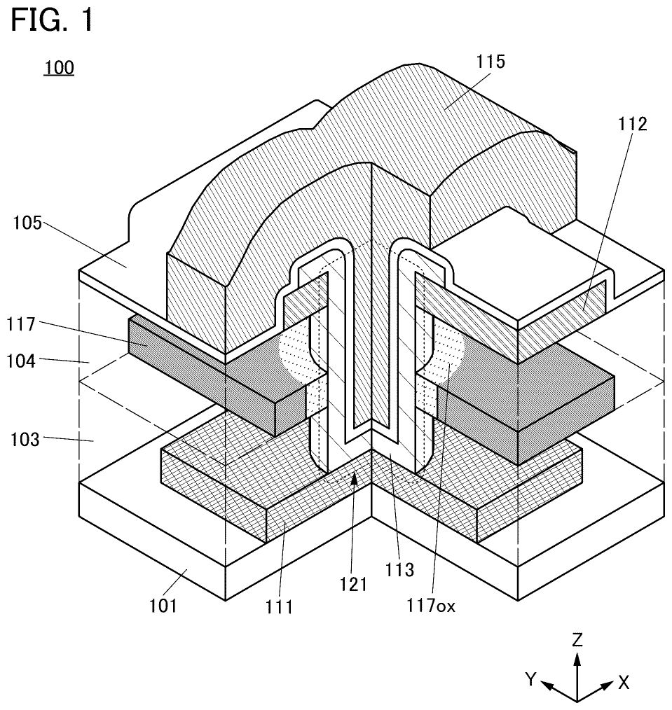

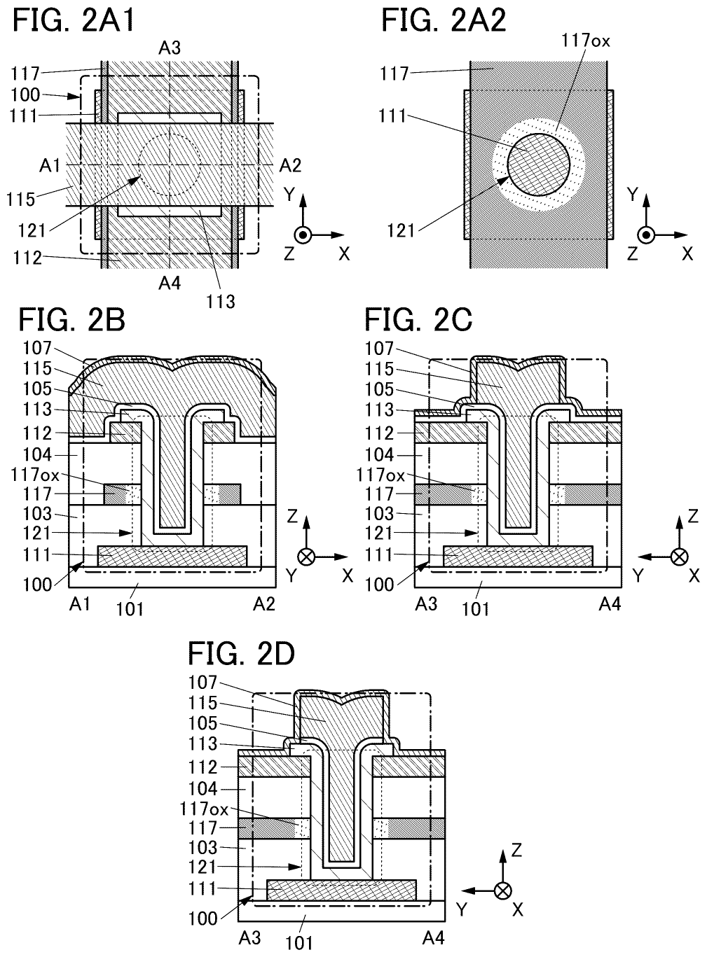

FIG. 1 is a perspective view illustrating a structure example of the semiconductor device of one embodiment of the present invention, and illustrates a structure example of a transistor 100 included in the semiconductor device. FIG. 2A1 is a plan view illustrating the structure example in FIG. 1 viewed in the Z direction, specifically, viewed in the Z direction from above, for example. For clarity of the drawing, some components, including insulating layers, are omitted in FIG. 2A1. Some components are omitted also in the following plan views. FIG. 2B is a cross-sectional view taken along the dashed-dotted line A1-A2 in FIG. 2A1, and FIG. 2C is a cross-sectional view taken along the dashed-dotted line A3-A4 in FIG. 2A1.

In FIG. 1, FIG. 2A1, FIG. 2B, and FIG. 2C, the X direction, the Y direction, and the Z direction are shown by coordinate axes. In FIG. 2A1, FIG. 2B, and FIG. 2C, the direction of the dashed-dotted line A1-A2 is the X direction, the direction of the dashed-dotted line A3-A4 is the Y direction, and the direction perpendicular to an XY plane is the Z direction. The X direction, the Y direction, and the Z direction can intersect with each other and, specifically, can be perpendicular to each other. Note that in the following drawings, the X direction, the Y direction, and the Z direction are shown by coordinate axes, and the definitions of the directions may be the same as or different from those in FIG. 1, FIG. 2A1, FIG. 2B, and FIG. 2C. In FIG. 1, FIG. 2A1, FIG. 2B, and FIG. 2C, the X direction, Y direction, and Z direction are shown by arrows; the forward direction and the reverse direction are not distinguished from each other unless otherwise specified. The same applies to the following drawings.

In this specification and the like, one of the X direction, the Y direction, and the Z direction may be referred to as a “first direction”. Another one of the directions may be referred to as a “second direction”. Furthermore, the remaining one of the directions may be referred to as a “third direction”.

The semiconductor device of one embodiment of the present invention includes an insulating layer 101 over a substrate (not illustrated) and the transistor 100 over the insulating layer 101. The semiconductor device of one embodiment of the present invention includes an insulating layer 103 over the insulating layer 101, an insulating layer 104 over the insulating layer 103, and an insulating layer 107 over the insulating layer 104 and the transistor 100. Here, the insulating layer 101, the insulating layer 103, and the insulating layer 104 function as interlayer insulating layers. It is preferable that these insulating layers and other layers functioning as interlayer insulating layers be planarized. Note that the layers functioning as the interlayer insulating layers are not necessarily planarized.

The transistor 100 includes a conductive layer 111, a conductive layer 112, a semiconductor layer 113, an insulating layer 105, a conductive layer 115, and a conductive layer 117. Here, FIG. 2A2 is a plan view obtained by omitting the conductive layer 115, the semiconductor layer 113, and the conductive layer 112 from FIG. 2A1. In the example illustrated in FIG. 2A1, the conductive layer 115 is provided to extend in the X direction and the conductive layer 112 is provided to extend in the Y direction. In the example illustrated in FIG. 2A1 and FIG. 2A2, the conductive layer 117 is provided to extend in the Y direction.

As each of the insulating layer 101, the insulating layer 103, the insulating layer 104, the insulating layer 105, and the insulating layer 107, a single layer or stacked layers of any of the insulators described in the later-described section [Insulator] can be used. As each of the conductive layer 111, the conductive layer 112, the conductive layer 115, and the conductive layer 117, a single layer or stacked layers of any of the conductors described in the later-described section [Conductor] can be used. As the semiconductor layer 113, a single layer or stacked layers of any of the metal oxides described in the later-described section [Metal oxide] can be used. As the semiconductor layer 113, a single layer or stacked layers of any of the materials, such as silicon, described in the later-described section [Other semiconductor materials] can be used.

In this specification and the like, a transistor including a metal oxide in a channel formation region of a semiconductor layer is referred to as an OS transistor. A transistor including silicon in a channel formation region of a semiconductor layer is referred to as a Si transistor. In the case where a metal oxide is used for the semiconductor layer 113, the transistor 100 can be an OS transistor. In the case where silicon is used for the semiconductor layer 113, the transistor 100 can be a Si transistor.

The conductive layer 111 has a function of one of a source electrode and a drain electrode of the transistor 100. The conductive layer 112 functions as the other of the source electrode and the drain electrode of the transistor 100. The insulating layer 105 functions as a gate insulating layer of the transistor 100. The conductive layer 115 and the conductive layer 117 function as gate electrodes of the transistor 100.

The conductive layer 111 is provided over the insulating layer 101, the insulating layer 103 is provided over the insulating layer 101 and the conductive layer 111, the conductive layer 117 is provided over the insulating layer 103, the insulating layer 104 is provided over the insulating layer 103 and the conductive layer 117, and the conductive layer 112 is provided over the insulating layer 104. The conductive layer 111 and the conductive layer 117 can have regions overlapping with each other with the insulating layer 103 therebetween. The conductive layer 117 and the conductive layer 112 can have regions overlapping with each other with the insulating layer 104 therebetween. In the above manner, the conductive layer 111 and the conductive layer 112 can have regions overlapping with each other with the insulating layer 103 and the insulating layer 104 therebetween.

An opening portion 121 reaching the conductive layer 111 is provided in the insulating layer 103, the conductive layer 117, the insulating layer 104, and the conductive layer 112. The opening portion 121 can be formed in the following manner: the insulating layer 103, the conductive layer 117, the insulating layer 104, and the conductive layer 112 are formed, and then, they are partly processed by an etching method, for example. Processing by a dry etching method is particularly preferable because it is suitable for fine processing.

FIG. 2A1 and FIG. 2A2 show an example in which the opening portion 121 is circular in a plan view. When the plan-view shape of the opening portion 121 is circular, the opening portion 121 can be formed with high processing accuracy and the opening portion 121 having a minute size can be formed. Note that in this specification and the like, a circular shape is not necessarily a perfect circular shape. For example, the plan-view shape of the opening portion 121 may be elliptical.

In the example shown in FIG. 1, FIG. 2A1, and FIG. 2B, a side end portion of the conductive layer 111 is positioned outward from a side end portion of the conductive layer 117 that does not face the opening portion 121 in the X direction, and the side end portion of the conductive layer 117 that does not face the opening portion 121 is positioned outward from a side end portion of the conductive layer 112 that does not face the opening portion 121 in the X direction. That is, in the example shown in FIG. 1, FIG. 2A1, and FIG. 2B, the side end portion of the conductive layer 112 that does not face the opening portion 121 overlaps with the conductive layer 117 and the conductive layer 111 in the X direction, the side end portion of the conductive layer 117 that does not face the opening portion 121 overlaps with the conductive layer 111 in the X direction, the side end portion of the conductive layer 111 does not overlap with the conductive layer 112 or the conductive layer 117 in the X direction, and the side end portion of the conductive layer 117 that does not face the opening portion 121 does not overlap with the conductive layer 112 in the X direction. Here, one embodiment of the present invention is not limited thereto; for example, the side end portion of the conductive layer 111 may be positioned inward from the side end portion of the conductive layer 117 that does not face the opening portion 121, or may be positioned inward from the side end portion of the conductive layer 112 that does not face the opening portion 121. Furthermore, the side end portion of the conductive layer 117 may be positioned inward from the side end portion of the conductive layer 112 that does not face the opening portion 121.

The semiconductor layer 113 is provided to cover the opening portion 121 and to include a region positioned in the opening portion 121. The semiconductor layer 113 can have a shape along the shapes of the top surface of the conductive layer 111, a side surface of the insulating layer 103, a side surface of the insulating layer 104, and a side surface and the top surface of the conductive layer 112. Thus, the semiconductor layer 113 has a depressed portion in a position overlapping with the opening portion 121. The semiconductor layer 113 can include a region in contact with the top surface of the conductive layer 111, a region in contact with the side surface of the insulating layer 103, a region in contact with the side surface of the insulating layer 104, a region in contact with the side surface of the conductive layer 112, and a region in contact with the top surface of the conductive layer 112.

The semiconductor layer 113 preferably covers a side end portion of the conductive layer 112 on the opening portion 121 side. For example, a side end portion of the semiconductor layer 113 is positioned over the conductive layer 112 in the structure illustrated in FIG. 1, FIG. 2A1, FIG. 2B, and FIG. 2C. In other words, a lower end portion of the semiconductor layer 113 is in contact with the top surface of the conductive layer 112 in this structure. Note that the side end portion of the semiconductor layer 113 may be positioned outward from the side end portion of the conductive layer 112 in the X direction. In that case, the semiconductor layer 113 can cover a side surface of the conductive layer 112 that does not face the opening portion 121.

In this specification and the like, an upper end portion refers to the uppermost portion of a side end portion, and a lower end portion refers to the lowermost portion of a side end portion. That is, the upper end portion and the lower end portion are each part of the side end portion.

Note that in the example illustrated in FIG. 1, FIG. 2A1, FIG. 2B, and FIG. 2C, the semiconductor layer 113 is divided in both the X direction and the Y direction to have an island shape. Here, the term “island shape” refers to a state where two or more layers formed using the same material in the same step are physically separated from each other.

The insulating layer 105 is provided to cover the opening portion 121 and to include a region positioned in the opening portion 121. The insulating layer 105 is provided over the semiconductor layer 113, the conductive layer 112, and the insulating layer 104. The insulating layer 105 can have a shape along the shapes of the top surface and a side surface of the semiconductor layer 113, the top surface and the side surface of the conductive layer 112, and the top surface of the insulating layer 104. Since the insulating layer 105 has the shape along the top surface and the side surface of the semiconductor layer 113, the insulating layer 105 has a depressed portion in a position overlapping with the opening portion 121. The insulating layer 105 can include a region in contact with the top surface of the semiconductor layer 113, a region in contact with the side surface of the semiconductor layer 113, a region in contact with the top surface of the conductive layer 112, a region in contact with the side surface of the conductive layer 112, and a region in contact with the top surface of the insulating layer 104.

The conductive layer 115 is provided over the insulating layer 105 and can include a region in contact with the top surface of the insulating layer 105 and a side surface of the depressed portion of the insulating layer 105. The conductive layer 115 includes a region positioned in the opening portion 121. The conductive layer 115 and the semiconductor layer 113 include regions facing each other with the insulating layer 105 sandwiched therebetween in a position along the sidewall and the bottom portion of the opening portion 121. Here, the semiconductor layer 113 can cover a side surface and the bottom surface of the conductive layer 115 with the insulating layer 105 therebetween in the opening portion 121. For example, in the opening portion 121, the insulating layer 105 can include a region in contact with the side surface of the semiconductor layer 113, a region in contact with the top surface of the depressed portion of the semiconductor layer 113, a region in contact with the side surface of the conductive layer 115, and a region in contact with the bottom surface of the conductive layer 115.

As described above, in the transistor 100 illustrated in FIG. 1, FIG. 2B, and FIG. 2C, the semiconductor layer, the gate insulating layer, and the gate electrode are provided in the opening portion formed in the interlayer insulating layers. Thus, the channel length direction of the transistor 100 can be a direction that is along the side surfaces of the insulating layer 103 and the insulating layer 104 in the opening portion 121. Thus, the channel length is not affected by the performance of a light-exposure apparatus used for manufacturing the transistor 100 and can be shorter than the resolution limit of the light-exposure apparatus. Accordingly, the transistor 100 can have a high on-state current. This allows the semiconductor device to be driven at high speed. Although the opening portion 121 entirely includes a region overlapping with the conductive layer 111, the semiconductor layer 113, and the conductive layer 115 in the example illustrated in FIG. 2A1, for example, it is allowable that part of the opening portion 121 does not overlap with at least one of the conductive layer 111, the semiconductor layer 113, and the conductive layer 115.

As illustrated in FIG. 1, FIG. 2B, and FIG. 2C, part of the conductive layer 115 is positioned outside the opening portion 121, that is, over the conductive layer 112 and the insulating layer 104. In this case, a side end portion of the conductive layer 115 is preferably positioned inward from the side end portion of the semiconductor layer 113 as illustrated in FIG. 2C. In that case, parasitic capacitance formed by the conductive layer 112, the insulating layer 105, and the conductive layer 115 can be low, for example. The side end portion of the conductive layer 115 may be positioned outward from the side end portion of the semiconductor layer 113. In that case, the conductive layer 115 can cover the entire semiconductor layer 113.

In the transistor 100, the conductive layer 117 including the opening portion 121 is provided between the insulating layer 103 and the insulating layer 104. The insulating layer 104 can cover the top surface and a side surface of the conductive layer 117. Here, as illustrated in FIG. 1, FIG. 2A2, FIG. 2B, and FIG. 2C, a side surface of the conductive layer 117 in the opening portion 121 and a region in the vicinity of the side surface constitute an oxide region 117ox. The oxide region 117ox has a higher electrical resistivity than the conductive layer 117 and has an insulating property. Here, since the oxide region 117ox has an insulating property, the oxide region 117ox can have a higher electrical resistivity than the semiconductor layer 113. The oxide region 117ox covers the region of the semiconductor layer 113 that is positioned in the opening portion 121. Specifically, the oxide region 117ox covers the region of the semiconductor layer 113 that is positioned in the opening portion 121 provided in the conductive layer 117. For example, in the opening portion 121, the oxide region 117ox is in contact with the semiconductor layer 113. The region of the conductive layer 117 that is not oxidized covers the oxide region 117ox. For example, the region of the conductive layer 117 that is not oxidized is not in contact with the semiconductor layer 113. In the above manner, the conductive layer 117 functions as the gate electrode, and the oxide region 117ox functions as a gate insulating layer. Note that the oxide region 117ox is not necessarily oxidized as long as it has an insulating property. The oxide region 117ox can be rephrased as a high-resistance region.

In this specification and the like, the oxide region 117ox can be included in the conductive layer 117, that is, the oxide region 117ox can be part of the conductive layer 117. Note that the oxide region 117ox is not necessarily included in the conductive layer 117.

Thus, the transistor 100 has a dual-gate structure including two gate electrodes, and the conductive layer 115 functioning as a first gate electrode and the conductive layer 117 functioning as a second gate electrode are provided to include regions sandwiching the channel formation region of the semiconductor layer 113 in the opening portion 121. Here, for example, the amount of current flowing through the channel formation region of the semiconductor layer 113 can be controlled in accordance with the potential of the conductive layer 115, and the threshold voltage of the transistor 100 can be controlled in accordance with the potential of the conductive layer 117.

As described above, the channel length of the transistor 100 is small, and is smaller than the resolution limit of a light-exposure apparatus, for example. In this case, if the transistor 100 is an n-channel transistor, the threshold voltage of the transistor 100 is low, and the transistor 100 sometimes has normally-on characteristics, for example. In view of this, by controlling the potential of the conductive layer 117 to control the threshold voltage of the transistor 100, or specifically, by making the threshold voltage of the transistor 100 higher than that in the case where the transistor 100 is not provided with the conductive layer 117, for example, the transistor 100 can be inhibited from having normally-on characteristics. In other words, the transistor 100 can have normally-off characteristics. Note that the threshold voltage of the transistor 100 may be controlled to be low, in which case the transistor 100 can have a high on-state current. Moreover, by controlling the threshold voltage of the transistor 100 with the potential of the conductive layer 117, a variation in electrical characteristics of the transistors 100, specifically, a variation in threshold voltage of the transistors 100, can be reduced. Accordingly, the semiconductor device can have favorable electrical characteristics.

Note that also in the case where the transistor 100 is a p-channel transistor, one embodiment of the present invention can be employed when the magnitude relations between various potentials, threshold voltages, and the like described in this specification are reversed as appropriate from those in the case where the transistor 100 is an n-channel transistor, for example.

In this specification and the like, the first gate electrode can be referred to as a front gate electrode, and the second gate electrode can be referred to as a back gate electrode. In the case where the conductive layer 115 is the first gate electrode and the conductive layer 117 is the second gate electrode, the insulating layer 105 can be a first gate insulating layer and the oxide region 117ox can be a second gate insulating layer. Note that the first gate electrode and the second gate electrode may be interchanged with each other. For example, the conductive layer 115 may be used as the second gate electrode, and the conductive layer 117 may be used as the first gate electrode. In that case, the insulating layer 105 can be referred to as the second gate insulating layer, and an insulating layer 106 can be referred to as the first gate insulating layer.

A constant potential can be supplied to the conductive layer 117, for example. When a ground potential or a negative potential is supplied to the conductive layer 117, for example, the transistor 100 can be inhibited from having normally-on characteristics. Note that a potential equal to the potential of the conductive layer 115 may be supplied to the conductive layer 117. In that case, the transistor 100 can have a higher on-state current, for example. In the case where the transistor 100 is an n-channel transistor, a potential supplied to the conductive layer 117 to turn on the transistor 100 may be higher than a potential supplied to the conductive layer 117 to turn off the transistor 100, for example. For example, a positive potential may be supplied to the conductive layer 117 to turn on the transistor 100, and the ground potential or a negative potential may be supplied to the conductive layer 117 to turn off the transistor 100.

For the conductive layer 117, a material that has increased electrical resistivity by a chemical reaction such as oxidation to have an insulating property is used, for example. For the conductive layer 117, for example, a metal or a nitride of a metal can be used. Examples of a material that can be used for the conductive layer 117 include tantalum nitride, titanium nitride, a nitride containing titanium and aluminum, a nitride containing tantalum and aluminum, and tungsten.

The oxide region 117ox includes an oxide of the material included in the conductive layer 117. For example, in the case where tantalum nitride is used for the conductive layer 117, the oxide region 117ox includes tantalum oxide; in the case where titanium nitride is used for the conductive layer 117, the oxide region 117ox includes titanium oxide. Note that nitrogen may be included in the oxide region 117ox, for example.

Here, an electric field from the conductive layer 117 sometimes does not reach the region of the semiconductor layer 113 that is not covered with the conductive layer 117. The electrical resistivity of the region of the semiconductor layer 113 that the electric field from the conductive layer 117 does not reach is preferably lower than the electrical resistivity of the region of the semiconductor layer 113 that the electric field from the conductive layer 117 reaches, in which case the transistor 100 can have a high on-state current, for example. For example, the electrical resistivity of the region in contact with the insulating layer 103 and that of the region in contact with the insulating layer 104 are preferably lower than the electrical resistivity of the region in contact with the oxide region 117ox.

For example, when an insulator containing nitrogen is used for each of the insulating layer 103 and the insulating layer 104, nitrogen can be supplied to the semiconductor layer 113. This enables generation of electrons as carriers in the semiconductor layer 113 and sometimes increases the carrier concentration in the case where the semiconductor layer 113 is formed using a metal oxide. Accordingly, the electrical resistivity of the region in contact with the insulating layer 103 and the region in contact with the insulating layer 104 can be lower than the electrical resistivity of the region in contact with the oxide region 117ox, for example. Examples of an insulator containing nitrogen include silicon nitride. For each of the insulating layer 103 and the insulating layer 104, silicon nitride oxide or aluminum nitride may be used, for example.

For the insulating layer 103 and the insulating layer 104, an insulator containing oxygen may be used. In that case, the insulating layer 103 and the insulating layer 104 provided in the vicinity of the channel formation region of the semiconductor layer 113 preferably include oxygen that is released by heating (hereinafter sometimes referred to as excess oxygen). When heat treatment is performed on the insulating layer 103 and the insulating layer 104 including excess oxygen, oxygen is supplied from the insulating layer 103 and the insulating layer 104 to the channel formation region of the semiconductor layer 113, so that oxygen vacancies and defects that are oxygen vacancies into which hydrogen enters (hereinafter also referred to as VoH) can be reduced. Thus, the transistor 100 can have stable electrical characteristics and increased reliability. Examples of an insulator containing oxygen include silicon oxide and silicon oxynitride.

Furthermore, for each of the insulating layer 103 and the insulating layer 104 provided in the vicinity of the channel formation region of the semiconductor layer 113, an insulator having a function of capturing hydrogen or a function of fixing hydrogen may be used. With such a structure, hydrogen in the channel formation region of the semiconductor layer 113 can be captured or fixed (also referred to as gettering), so that the hydrogen concentration of the semiconductor layer 113 can be reduced. Examples of the insulating layer 103 and the insulating layer 104 as described above include magnesium oxide and aluminum oxide.

The oxide region 117ox of the conductive layer 117 can be formed by oxidation treatment performed after the formation of the opening portion 121 in the conductive layer 112, the insulating layer 104, the conductive layer 117, and the insulating layer 103. Examples of the oxidation treatment include microwave treatment in an atmosphere containing oxygen.

Here, in the case where the above oxidation treatment is performed after the formation of the conductive layer 111 and the conductive layer 112, not only the conductive layer 117 but also the conductive layer 111 and the conductive layer 112 are subjected to the oxidation treatment. Thus, each of the conductive layer 111 and the conductive layer 112 is formed using a material that is less likely to be oxidized than the conductive layer 117 or a material having conductivity even after being oxidized. For each of the conductive layer 111 and the conductive layer 112, a conductive material containing oxygen can be used, for example. As each of the conductive layer 111 and the conductive layer 112, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

The insulating layer 107 is provided over the conductive layer 115 and the insulating layer 105. The insulating layer 107 can be provided to cover the top surface and a side surface of the conductive layer 115. The insulating layer 107 has a function of inhibiting entry of impurities into the transistor 100, for example, a function of inhibiting entry of impurities into the semiconductor layer 113.

Although the insulating layer 105 is provided to have a planar shape in the example illustrated in FIG. 1, FIG. 2B, and FIG. 2C, one embodiment of the present invention is not limited thereto. FIG. 2D illustrates an example in which a side end portion of the insulating layer 105 illustrated in FIG. 2C is aligned or substantially aligned with the side end portion of the conductive layer 115. For example, when the insulating layer 105 is processed with the same pattern as the conductive layer 115, the side end portion of the insulating layer 105 and the side end portion of the conductive layer 115 can be aligned or substantially aligned with each other.

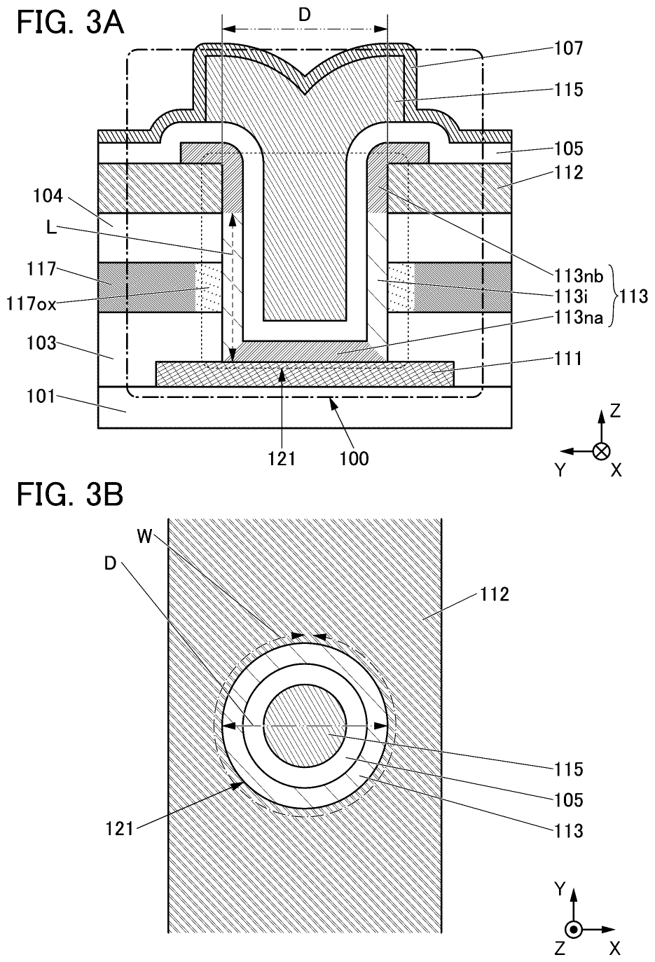

FIG. 3A is an enlarged view of the transistor 100 illustrated in FIG. 2C and the vicinity thereof. FIG. 3B is a plan view of an XY plane of the transistor 100 illustrated in FIG. 3A. Note that the conductive layer 111 and the conductive layer 117 are not shown in FIG. 3B.

As illustrated in FIG. 3A, the semiconductor layer 113 includes a region 113i, and a region 113na and a region 113nb provided such that the region 113i is sandwiched therebetween.

The region 113na is a region of the semiconductor layer 113 that is in contact with the conductive layer 111. At least part of the region 113na functions as one of a source region and a drain region of the transistor 100. The region 113nb is a region of the semiconductor layer 113 that is in contact with the conductive layer 112. At least part of the region 113nb functions as the other of the source region and the drain region of the transistor 100. As illustrated in FIG. 3B, the conductive layer 112 is in contact with the entire outer circumference of the semiconductor layer 113. Thus, the other of the source region and the drain region of the transistor 100 can be formed in the entire outer circumference of a portion of the semiconductor layer 113 that is formed in the same layer as the conductive layer 112.

The region 113i is a region of the semiconductor layer 113 that is between the region 113na and the region 113nb. At least part of the region 113i functions as the channel formation region of the transistor 100. That is, the channel formation region of the transistor 100 is positioned in a region of the semiconductor layer 113 that is between the conductive layer 111 and the conductive layer 112. In other words, the channel formation region of the transistor 100 is positioned in the region of the semiconductor layer 113 that is in contact with the insulating layer 103 or a region in the vicinity thereof, the region of the semiconductor layer 113 that is in contact with the oxide region 117ox or a region in the vicinity thereof, and the region of the semiconductor layer 113 that is in contact with the insulating layer 104 or in a region in the vicinity thereof.

The channel length of a transistor is the distance between a source region and a drain region. In other words, the channel length of the transistor 100 depends on the thicknesses of the insulating layer 103, the oxide region 117ox, and the insulating layer 104 over the conductive layer 111. In FIG. 3A, a channel length L of the transistor 100 is indicated by a dashed double-headed arrow. In the cross-sectional view, the channel length L is the distance between an end portion of the region where the semiconductor layer 113 is in contact with the conductive layer 111 and an end portion of the region where the semiconductor layer 113 is in contact with the conductive layer 112. That is, the channel length L corresponds to the lengths of the side surfaces of the insulating layer 103, the oxide region 117ox, and the insulating layer 104 in the opening portion 121 in the cross-sectional view.

While the channel length of a conventional transistor, a specific example of which is a planar transistor, is set by the light exposure limit of photolithography, the channel length in the present invention can be set by the thicknesses of the insulating layer 103, the oxide region 117ox, and the insulating layer 104 in a region overlapping with the conductive layer 111. Thus, the transistor 100 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 100 can have a high on-state current. This allows the semiconductor device to be driven at high speed.

Here, although the details will be described later, an OS transistor has higher resistance against a short-channel effect than a Si transistor. Furthermore, as described above, the transistor 100 having the structure illustrated in FIG. 3A, FIG. 3B, and the like can have a shorter channel length than a planar transistor, for example. Thus, in the case where the transistor 100 has the structure illustrated in FIG. 3A and FIG. 3B, for example, a metal oxide is preferably used for the semiconductor layer 113. Note that a material other than a metal oxide, such as silicon, may be used for the semiconductor layer 113.

In addition, as described above, the channel formation region, the source region, and the drain region can be formed in the opening portion 121. Thus, the footprint of the transistor can be reduced as compared with, for example, a planar transistor in which a channel formation region, a source region, and a drain region are provided separately on an XY plane. Accordingly, the semiconductor device can be reduced in size.

As illustrated in FIG. 3B, the semiconductor layer 113, the insulating layer 105, and the conductive layer 115 are provided concentrically on the XY plane including the channel formation region of the semiconductor layer 113. Thus, the side surface of the conductive layer 115 that is provided at the center faces the side surface of the semiconductor layer 113 with the insulating layer 105 therebetween. That is, in the plan view, the entire outer circumference of the semiconductor layer 113 serves as the channel formation region. In this case, for example, the channel width of the transistor 100 depends on the length of the outer circumference of the semiconductor layer 113. In other words, the channel width of the transistor 100 depends on the maximum width of the opening portion 121 (the maximum diameter in the case where the opening portion 121 is circular in the plan view). In FIG. 3A and FIG. 3B, a maximum width D of the opening portion 121 is indicated by a dashed double-dotted double-headed arrow. In FIG. 3B, a channel width W of the transistor 100 is indicated by a dashed-dotted double-headed arrow.

The maximum width D of the opening portion 121 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 121 is circular in the plan view, the maximum width D of the opening portion 121 corresponds to the diameter of the opening portion 121, and the channel width W can be “D×π”. When the above-described formation method of the opening portion of one embodiment of the present invention is employed, the maximum width D of the opening portion 121 can be easily reduced. Thus, the transistor 100 can be miniaturized. Meanwhile, by increasing the maximum width D of the opening portion 121, the channel width per unit area of the transistor 100 can be increased and the on-state current can be increased.

In the semiconductor device of one embodiment of the present invention, the channel length L of the transistor 100 is preferably shorter than at least the channel width W of the transistor 100. The channel length L of the transistor 100 is greater than or equal to 0.1 times and less than or equal to 0.99 times, preferably greater than or equal to 0.5 times and less than or equal to 0.8 times the channel width W of the transistor 100. This structure enables the transistor to have favorable electrical characteristics and high reliability.

By providing the semiconductor layer 113, the insulating layer 105, and the conductive layer 115 concentrically, the distance between the conductive layer 115 and the semiconductor layer 113 becomes substantially uniform. Thus, a gate electric field can be substantially uniformly applied to the semiconductor layer 113.

The sidewall of the opening portion 121 is preferably perpendicular to the top surface of the conductive layer 111, for example. Such a structure allows miniaturization of the transistor 100. Note that the sidewall of the opening portion 121 may have a tapered shape. Components of the semiconductor device of one embodiment of the present invention will be described below.

As the semiconductor layer 113, a single layer or stacked layers of any of the metal oxides described in the later-described section [Metal oxide] can be used as described above. As the semiconductor layer 113, a single layer or stacked layers of any of the materials, such as silicon, described in the later-described section [Other semiconductor materials] can be used.

In the case of using a metal oxide for the semiconductor layer 113, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be specifically used for the semiconductor layer 113. Note that a composition in the neighborhood includes the range of +30% of an intended atomic ratio. Gallium is preferably used as the element M.

When a film of the metal oxide is formed by a sputtering method, the above atomic ratio is not limited to the atomic ratio of the formed film of the metal oxide and may be the atomic ratio of a sputtering target used for forming the film of the metal oxide.

For analysis of the composition of the metal oxide used for the semiconductor layer 113, for example, energy dispersive X-ray spectroscopy (EDX), XPS, inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

For the formation of the metal oxide, an atomic layer deposition (ALD) method can be suitably used.

Alternatively, the metal oxide may be formed by a sputtering method or a chemical vapor deposition (CVD) method.

In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

It is preferable that the metal oxide used for the semiconductor layer 113 have crystallinity. Examples of an oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. For the semiconductor layer 113, the CAAC-OS or the nc-OS is preferably used, and the CAAC-OS is particularly preferably used.

The CAAC-OS preferably includes a plurality of layered crystal regions and the c-axis is preferably aligned in a normal direction of a surface where the CAAC-OS is formed. For example, the semiconductor layer 113 preferably includes a layered crystal that is substantially parallel to the sidewall of the opening portion 121, particularly the side surfaces of the insulating layer 103, the oxide region 117ox, and the insulating layer 104. With this structure, the layered crystals of the semiconductor layer 113 are formed substantially parallel to the channel length direction of the transistor 100, so that the on-state current of the transistor 100 can be increased.

A CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

A clear crystal grain boundary is difficult to observe in a CAAC-OS; thus, it can be said that a reduction in electron mobility due to the crystal grain boundary is less likely to occur. Thus, a metal oxide including a CAAC-OS is physically stable. Therefore, a metal oxide including a CAAC-OS is resistant to heat and has high reliability.

When a metal oxide having crystallinity, such as a CAAC-OS, is used for the semiconductor layer 113, oxygen extraction from the semiconductor layer 113 by the source electrode or the drain electrode can be inhibited. This can inhibit oxygen extraction from the semiconductor layer 113 even when heat treatment is performed; thus, the transistor 100 is stable with respect to high temperatures in a manufacturing process (what is called thermal budget).

The crystallinity of the semiconductor layer 113 can be analyzed with X-ray diffraction (XRD), a transmission electron microscope (TEM), or electron diffraction (ED), for example. Alternatively, any of these methods may be combined with each other for the analysis.

The thickness of the semiconductor layer 113 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

Although FIG. 1, FIG. 2B, FIG. 2C, and the like illustrate the semiconductor layer 113 having a single-layer structure, one embodiment of the present invention is not limited thereto. The semiconductor layer 113 may have a stacked-layer structure of a plurality of oxide layers with different chemical compositions. For example, a structure in which a plurality of kinds of metal oxides selected from the above-described metal oxides are stacked as appropriate may be used.

As described above, the semiconductor layer 113 can include the region in contact with the conductive layer 111 and the region in contact with the conductive layer 112. When the semiconductor layer 113 is in contact with the conductive layer 111, a metal compound or oxygen vacancies might be formed, and the resistance of the region 113na in the semiconductor layer 113 might be reduced. A reduction in the resistance of the semiconductor layer 113 in contact with the conductive layer 111 can reduce the contact resistance between the semiconductor layer 113 and the conductive layer 111. Similarly, when the semiconductor layer 113 is in contact with the conductive layer 112, the resistance of the region 113nb in the semiconductor layer 113 might be reduced. In that case, the contact resistance between the semiconductor layer 113 and the conductive layer 112 can be reduced.

The insulating layer 105, which functions as the gate insulating layer, can be formed using silicon oxide or silicon oxynitride, for example. Silicon oxide and silicon oxynitride are preferable because they are thermally stable.

For the insulating layer 105, any of the materials with a high relative permittivity, that is, high-k materials, described in the later-described section [Insulator] may be used. For example, hafnium oxide, aluminum oxide, or the like may be used.

The thickness of the insulating layer 105 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulating layer 105 preferably includes a region having the above-described thickness.

The concentration of impurities such as water and hydrogen in the insulating layer 105 is preferably reduced. This can inhibit entry of impurities such as water and hydrogen into the channel formation region of the semiconductor layer 113.

Although FIG. 1, FIG. 2B, FIG. 2C, and the like illustrate the insulating layer 105 having a single-layer structure, one embodiment of the present invention is not limited thereto. The insulating layer 105 may have a stacked-layer structure.

The conductive layer 115, which functions as the gate electrode, can be formed using a conductive material with high conductivity, such as tungsten, aluminum, or copper. The conductive layer 115 can be formed using an alloy, e.g., an alloy of aluminum and titanium (Al—Ti).

A conductive material that is less likely to be oxidized, a conductive material having a function of inhibiting diffusion of oxygen, or the like is preferably used for the conductive layer 115. Examples of the conductive material include a conductive material containing nitrogen (e.g., titanium nitride or tantalum nitride) and a conductive material containing oxygen (e.g., ruthenium oxide). In that case, the conductivity of the conductive layer 115 can be inhibited from being reduced. A semiconductor having high electrical conductivity, typified by polycrystalline silicon containing an impurity element such as phosphorus, or silicide such as nickel silicide may be used for the conductive layer 115.

Although FIG. 1, FIG. 2B, FIG. 2C, and the like illustrate the conductive layer 115 having a single-layer structure, one embodiment of the present invention is not limited thereto. The conductive layer 115 may have a stacked-layer structure.

The insulating layer 101 preferably has a low relative permittivity. In that case, parasitic capacitance generated between wirings can be reduced. As the insulating layer 101, a single layer or stacked layers of any of the insulators each including a material with a low relative permittivity and described in the later-described section [Insulator] can be used. In particular, silicon oxide and silicon oxynitride are preferable because they are thermally stable.

The concentration of impurities such as water and hydrogen in the insulating layer 101 is preferably reduced. This can inhibit entry of impurities such as water and hydrogen into the channel formation region of the semiconductor layer 113.

For the insulating layer 107, any of the insulators with a barrier property against hydrogen described in the later-described section [Insulator] is preferably used. In that case, hydrogen can be inhibited from being diffused from outside the transistor 100 to the semiconductor layer 113 through the insulating layer 105. Silicon nitride and silicon nitride oxide can be suitably used for the insulating layer 107 because silicon nitride and silicon nitride oxide release fewer impurities, such as water and hydrogen, and are less likely to transmit oxygen and hydrogen.

For the insulating layer 107, any of the insulators having a function of capturing hydrogen or a function of fixing hydrogen and described in the later-described section [Insulator] is preferably used. With this structure, diffusion of hydrogen into the semiconductor layer 113 from above the insulating layer 107 can be inhibited, and hydrogen in the semiconductor layer 113 can be captured or fixed, whereby the hydrogen concentration of the semiconductor layer 113 can be reduced. For the insulating layer 107, magnesium oxide, aluminum oxide, hafnium oxide, or the like can be used. Alternatively, for example, a stacked-layer film of aluminum oxide and silicon nitride over the aluminum oxide may be used for the insulating layer 107.

Although the insulating layer 107 is formed over the top surface of the transistor 100 in the structure illustrated in FIG. 2B, FIG. 2C, and the like, one embodiment of the present invention is not limited thereto. For example, the insulating layer 107 or an insulating layer whose function and material are similar to those of the insulating layer 107 may be formed on a side surface and the bottom surface of the transistor 100, in which case the transistor 100 is surrounded by the insulating layer 107. This structure can inhibit entry of impurities such as water and hydrogen into the transistor 100.

### STRUCTURE EXAMPLE 2 OF SEMICONDUCTOR DEVICE

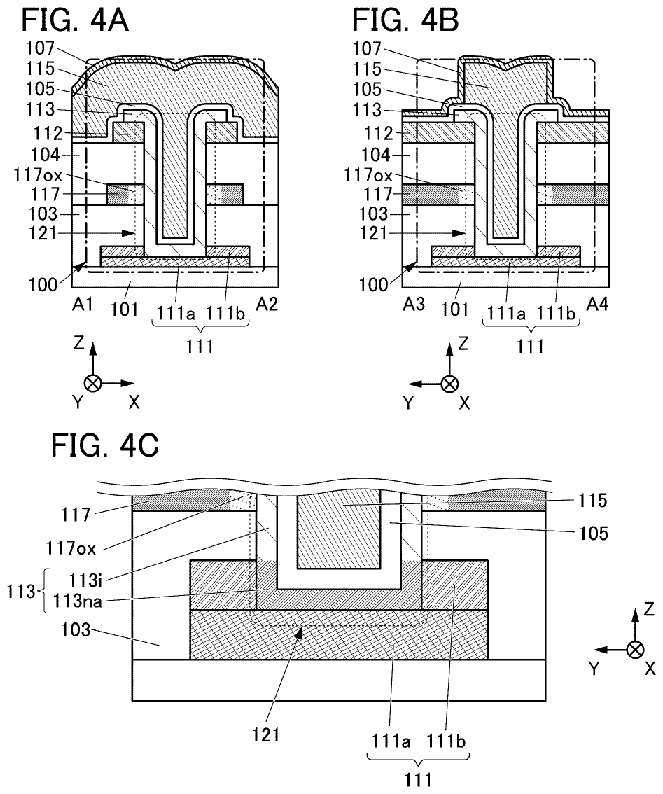

In FIG. 4A and FIG. 4B, the conductive layer 111 illustrated in FIG. 2B and FIG. 2C has a stacked-layer structure of two layers: a conductive layer 111a and a conductive layer 111b over the conductive layer 111a. FIG. 4C is an enlarged view of the conductive layer 111 illustrated in FIG. 4B and a region in the vicinity thereof. FIG. 4C illustrates the region 113na, at least part of which functions as one of the source region and the drain region of the transistor 100, and the region 113i, at least part of which functions as the channel formation region of the transistor 100.

In the example illustrated in FIG. 4A to FIG. 4C, the opening portion 121 is provided also in the conductive layer 111b and reaches the conductive layer 111a. In this case, the semiconductor layer 113 can include a region in contact with the top surface of the conductive layer 111a and a region in contact with a side surface of the conductive layer 111b in the opening portion 121.

To manufacture the transistor 100 having the structure illustrated in FIG. 4A to FIG. 4C, the insulating layer 101, the conductive layer 111a, the conductive layer 111b, the insulating layer 103, the conductive layer 117, the insulating layer 104, and the conductive layer 112 are formed, and then, the opening portion 121 reaching the conductive layer 111b is formed in the conductive layer 112, the insulating layer 104, the conductive layer 117, and the insulating layer 103. Next, oxidation treatment is performed on the conductive layer 117 to form the oxide region 117ox. Subsequently, a region of the conductive layer 111b that overlaps with the opening portion 121 is removed to make the opening portion 121 reach the conductive layer 111a. After that, the semiconductor layer 113, the insulating layer 105, and the conductive layer 115 are formed such that they each include the region positioned in the opening portion 121. Through the above process, the transistor 100 having the structure illustrated in FIG. 4A to FIG. 4C can be manufactured. Note that the conductive layer 111a is sometimes provided with a depressed portion including a region overlapping with the opening portion 121. Furthermore, the opening portion 121 sometimes does not reach the conductive layer 111a, in which case the conductive layer 111b is provided with a depressed portion including a region overlapping with the opening portion 121.

In the case where the structure illustrated in FIG. 4A to FIG. 4C is employed for the transistor 100, part of the conductive layer 111b is removed after the above oxidation treatment. Thus, even when the conductive layer 111b is oxidized by the above oxidation treatment, at least part of the region of the conductive layer 111 that has been oxidized by the above oxidation treatment can be removed. This can reduce the electric resistance at the contact interface between the conductive layer 111 and the semiconductor layer 113. It is thus possible to inhibit the absence of current flow and a reduction in current flow in the semiconductor layer 113 between the conductive layer 111 and the conductive layer 112 in the transistor 100 that is in an on state, for example. Therefore, the semiconductor device can have high reliability. It is also possible to use a material with low oxidation resistance and high conductivity for the conductive layer 111, expanding the range of choices for the material of the conductive layer 111. Note that also in the case where the conductive layer 111 is a single layer as illustrated in FIG. 1, FIG. 2B, FIG. 2C, and the like, at least part of the oxidized region of the conductive layer 111 may be removed after the above oxidation treatment. In that case, the conductive layer 111 includes a depressed portion including a region overlapping with the opening portion 121.

In the example illustrated in FIG. 4C, the top surface of the conductive layer 111 is positioned above the bottom surface of the conductive layer 115. Thus, the conductive layer 111 and the conductive layer 115 include regions facing each other with the semiconductor layer 113 and the insulating layer 105 sandwiched therebetween in a position along the sidewall of the opening portion 121. This can prevent formation of an offset region between the region 113i and the region 113na. Even in the case where there are no such facing regions, the length of the offset region between the region 113i and the region 113na can be shortened. Accordingly, the effective channel length of the transistor 100 can be inhibited from increasing because of the offset region. This can inhibit a reduction in the on-state current of the transistor 100.

For the conductive layer 111a and the conductive layer 111b, any of the conductors described in the later-described section [Conductor] can be used. For example, a conductive material with high conductivity, such as tungsten, aluminum, or copper, can be used for one or both of the conductive layer 111a and the conductive layer 111b. Like the conductive layer 111 illustrated in FIG. 2B and FIG. 2C, one or both of the conductive layer 111a and the conductive layer 111b can be formed using a conductive material containing oxygen. For example, one of the conductive layer 111a and the conductive layer 111b can be formed using tungsten, and the other of the conductive layer 111a and the conductive layer 111b can be formed using indium tin oxide to which silicon is added. Note that the conductive layer 111 may have a stacked-layer structure of three or more layers.

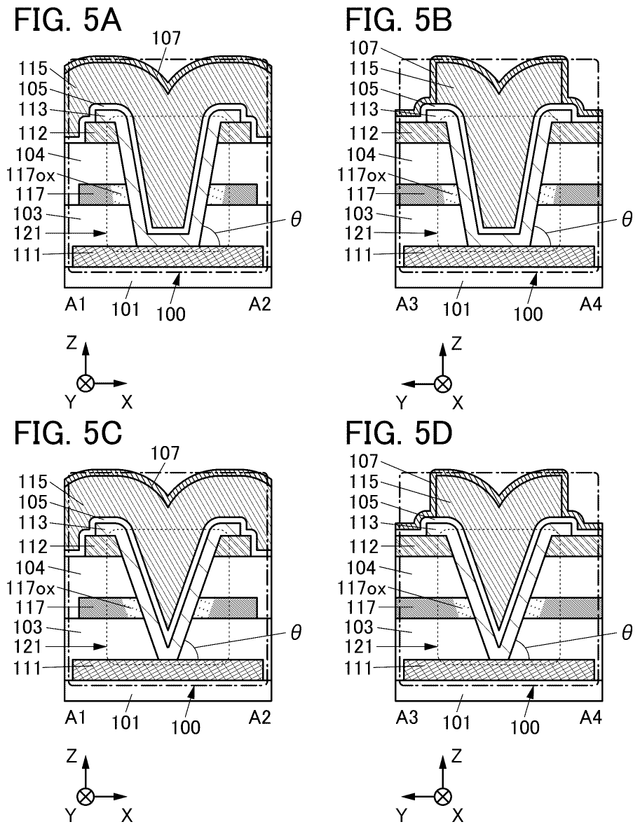

FIG. 5A and FIG. 5B illustrate an example in which the sidewall of the opening portion 121 illustrated in FIG. 2B and FIG. 2C has a tapered shape, i.e., the side surfaces of the insulating layer 103, the oxide region 117ox, the insulating layer 104, and the conductive layer 112 in the opening portion 121 have tapered shapes.

When the sidewall of the opening portion 121 has a tapered shape, the coverage with the semiconductor layer 113, the insulating layer 105, and the like can be improved, so that defects such as voids can be reduced. For example, an angle θ between the side surface of the insulating layer 103 and the top surface of the conductive layer 111 in the opening portion 121 is preferably greater than or equal to 45° and less than 90°, further preferably greater than or equal to 45° and less than or equal to 75°, still further preferably greater than or equal to 45° and less than or equal to 65°. Note that as described above, the sidewall of the opening portion 121 may be perpendicular to the top surface of the conductive layer 111. That is, the angle θ may be 90°.

The opening portion 121 illustrated in FIG. 5A and FIG. 5B has a frusto-conical shape. In this case, the opening portion 121 is circular in the plan view and the opening portion 121 is trapezoidal in the cross-sectional view. The area of the upper base plane of the frusto-conical shape (e.g., the top surface of the opening portion 121 provided in the conductive layer 112) is larger than the area of the lower base plane of the frusto-conical shape (the top surface of the conductive layer 111 exposed in the opening portion 121). In this case, the maximum diameter of the opening portion 121 is preferably calculated from the upper base plane of the frusto-conical shape.

In the case where the sidewall of the opening portion 121 has a tapered shape, the channel length can be set by the thicknesses of the insulating layer 103, the oxide region 117ox, and the insulating layer 104 in the region overlapping with the conductive layer 111 and the angle θ between the side surface of the insulating layer 103 and the top surface of the conductive layer 111 in the opening portion 121. The length of the outer circumference of the semiconductor layer 113 in the plan view is determined at, for example, the position of a region in contact with the conductive layer 112 or the position at half of the thickness of the conductive layer 117. Note that the length of the circumference of the opening portion 121 at an arbitrary position (depth) may be regarded as the channel width of the transistor 100 as necessary. For example, the length of the circumference at the lowest portion of the opening portion 121 may be regarded as the channel width, or the length of the circumference at the uppermost portion of the opening portion 121 may be regarded as the channel width.

Although the side surface of the conductive layer 112 in the opening portion 121, the side surface of the insulating layer 104 in the opening portion 121, the side surface of the oxide region 117ox in the opening portion 121, and the side surface of the insulating layer 103 in the opening portion 121 are aligned with each other in the structure illustrated in FIG. 5A and FIG. 5B, one embodiment of the present invention is not limited thereto. For example, the side surface of the conductive layer 112 in the opening portion 121 and the side surface of the insulating layer 104 in the opening portion 121 may be discontinuous. At least one of the inclination of the side surface of the conductive layer 112 in the opening portion 121, the inclination of the side surface of the insulating layer 104 in the opening portion 121, the inclination of the side surface of the oxide region 117ox in the opening portion 121, and the inclination of the side surface of the insulating layer 103 in the opening portion 121 may be different from the other(s). In addition, for example, the angle between the side surface of the conductive layer 112 and the top surface of the conductive layer 111 in the opening portion 121 is preferably smaller than the angle θ. With such a structure, the coverage of the side surface of the conductive layer 112 with the semiconductor layer 113 in the opening portion 121 is improved, so that defects such as voids can be reduced.

As illustrated in FIG. 5A and FIG. 5B, the bottom portion of the conductive layer 115 positioned in the opening portion 121 includes a flat region. Note that the bottom portion of the conductive layer 115 positioned in the opening portion 121 does not include a flat region in some cases depending on the maximum width of the opening portion 121 (the maximum diameter in the case where the opening portion 121 is circular in the plan view), and the thicknesses of the insulating layer 103, the oxide region 117ox, and the insulating layer 104 (corresponding to the depth of the opening portion 121), the thickness of the semiconductor layer 113, the thickness of the insulating layer 105, and the like in the region overlapping with the conductive layer 111. FIG. 5C and FIG. 5D illustrate an example in which the bottom portion of the conductive layer 115 in FIG. 5A and FIG. 5B positioned in the opening portion 121 has a needle-like shape.

Here, the needle-like shape refers to a shape tapering off toward the tip (at a position closer to the bottom portion of the conductive layer 115 positioned in the opening portion 121). Note that the needle-like tip may have an acute angle or a downward-convex curved surface shape. In addition, among the needle-like shapes, a shape whose tip has an acute angle may be referred to as a V shape.

A region of the conductive layer 115 that is positioned in the opening portion 121 and faces the semiconductor layer 113 with the insulating layer 105 therebetween functions as the gate electrode. Thus, the conductive layer 115 which is embedded in the opening portion 121 and whose bottom portion has a needle-like shape may be referred to as a needle-like gate. Furthermore, as illustrated in FIG. 5A and FIG. 5B, the conductive layer 115 whose bottom portion has a flat region may be referred to as a needle-like gate in some cases.

The sidewall of the opening portion 121 may have an inversely tapered shape. In other words, the angle θ may be greater than 90°.

Here, the inversely tapered shape refers to a shape whose side portion or upper portion protrudes outside from its bottom portion in the direction parallel to a substrate. In this case, the opening portion 121 has a frusto-conical shape. In this case, the opening portion 121 is circular in the plan view and the opening portion 121 is trapezoidal in the cross-sectional view. The area of the upper base plane of the frusto-conical shape (e.g., the top surface of the opening portion 121 provided in the conductive layer 112) is smaller than the area of the lower base plane of the frusto-conical shape (the top surface of the conductive layer 111 exposed in the opening portion 121). With such a structure, the area where the semiconductor layer 113 and the conductive layer 111 are in contact with each other can be increased.

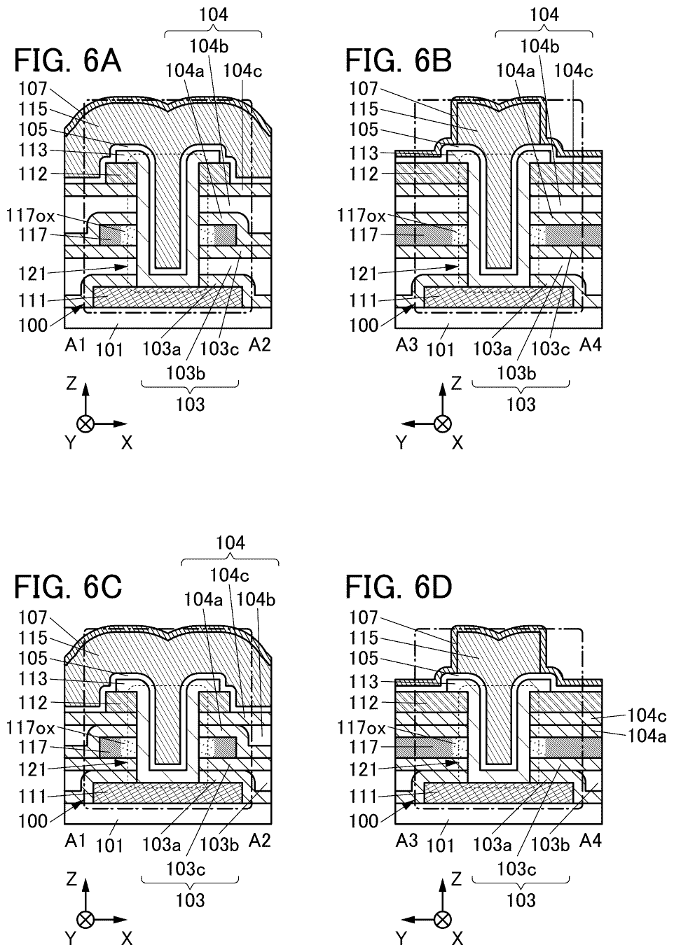

In FIG. 6A and FIG. 6B, the insulating layer 103 and the insulating layer 104 illustrated in FIG. 2B and FIG. 2C each have a stacked-layer structure of three layers. In the example illustrated in FIG. 6A and FIG. 6B, the insulating layer 103 includes an insulating layer 103a, an insulating layer 103b over the insulating layer 103a, and an insulating layer 103c over the insulating layer 103b. The insulating layer 104 includes an insulating layer 104a, an insulating layer 104b over the insulating layer 104a, and an insulating layer 104c over the insulating layer 104b.

The insulating layer 103a, the insulating layer 103c, the insulating layer 104a, and the insulating layer 104c can be formed using an insulator containing nitrogen, such as silicon nitride, silicon nitride oxide, or aluminum nitride. The insulating layer 103b and the insulating layer 104b can be layers that are planarized. The insulating layer 103b is preferably easier to planarize than the insulating layer 103a, and the insulating layer 104b is preferably easier to planarize than the insulating layer 104a. The insulating layer 103b and the insulating layer 104b can be formed using an insulator containing oxygen, such as silicon oxide, for example. In the semiconductor device with the above structure, the electrical resistivity of the region of the semiconductor layer 113 that is in contact with the insulating layer 103a, the region of the semiconductor layer 113 that is in contact with the insulating layer 103c, the region of the semiconductor layer 113 that is in contact with the insulating layer 104a, and the region of the semiconductor layer 113 that is in contact with the insulating layer 104c can be lower than the electrical resistivity of the region of the semiconductor layer 113 that is in contact with the oxide region 117ox, and can be lower than the electrical resistivity of the region of the semiconductor layer 113 that is in contact with the insulating layer 103b and the region of the semiconductor layer 113 that is in contact with the insulating layer 104b.

When the insulating layer 103 and the insulating layer 104 each have the structure illustrated in FIG. 6A and FIG. 6B, the electrical resistivity of at least part of the region of the semiconductor layer 113 that is in contact with the insulating layer 103 and at least part of the region of the semiconductor layer 113 that is in contact with the insulating layer 104 can be lower than the electrical resistivity of the region of the semiconductor layer 113 that is in contact with the oxide region 117ox, for example, while the insulating layer 103 and the insulating layer 104 are planarized. In that case, the semiconductor device can be easy to manufacture and can be driven at higher speed than in the case where the insulating layer 103 and the insulating layer 104 do not include a layer including nitrogen, for example. When the thicknesses of the insulating layer 103b and the insulating layer 104b are small, the height of the region of the semiconductor layer 113 that the electric field from the conductive layer 117 does not reach and that does not include nitrogen, for example, can be small, so that the on-state current of the transistor 100 can be high. By contrast, when the thickness of the insulating layer 103b is large, parasitic capacitance formed by the conductive layer 111, the insulating layer 103, and the conductive layer 117 can be low. When the thickness of the insulating layer 104b is large, parasitic capacitance formed by the conductive layer 117, the insulating layer 104, and the conductive layer 112 can be low.

FIG. 6C and FIG. 6D illustrate an example in which the insulating layer 103b and the insulating layer 104b illustrated in FIG. 6A and FIG. 6B are not in contact with the semiconductor layer 113. In the example illustrated in FIG. 6C and FIG. 6D, the top surface of the insulating layer 103a and the top surface of the insulating layer 103b can be level or substantially level with each other. In addition, the top surface of the insulating layer 104a and the top surface of the insulating layer 104b can be level or substantially level with each other. The top surface of the insulating layer 103a can include a region in contact with the insulating layer 103c as well as a region in contact with the insulating layer 103b. The top surface of the insulating layer 104a can include a region in contact with the insulating layer 104c as well as a region in contact with the insulating layer 104b.

In the example illustrated in FIG. 6C and FIG. 6D, for example, the transistor 100 can have a shorter channel length than the transistor 100 in the example illustrated in FIG. 6A and FIG. 6B to have a higher on-state current. Meanwhile, in the example illustrated in FIG. 6A and FIG. 6B, the parasitic capacitance formed by the conductive layer 111, the insulating layer 103, and the conductive layer 117 and the parasitic capacitance formed by the conductive layer 117, the insulating layer 104, and the conductive layer 112 can be lower than those in the example illustrated in FIG. 6C and FIG. 6D. In the example illustrated in FIG. 6A and FIG. 6B, when the insulating layer 103b and the insulating layer 104b include excess oxygen, VoH in the channel formation region of the semiconductor layer 113 can be reduced. Thus, the transistor 100 can have stable electrical characteristics and increased reliability.

In the examples illustrated in FIG. 6A to FIG. 6D, the insulating layer 103c can include a region in contact with the bottom surface of the conductive layer 117, and the insulating layer 104a can include a region in contact with the top surface and the side surface of the conductive layer 117. In that case, using insulating layers without oxygen as the insulating layer 103c and the insulating layer 104a can inhibit oxidation of a region of the conductive layer 117 that is away from the semiconductor layer 113 even when the insulating layer 103b and the insulating layer 104b include oxygen, for example. This can inhibit an increase in wiring resistance of the conductive layer 117. Using an insulating layer without oxygen as the insulating layer 104c can inhibit oxidation of the conductive layer 112 even when the insulating layer 104b includes oxygen, for example. Note that the insulating layer 104c may be omitted, in which case the insulating layer 104 has a two-layer structure of the insulating layer 104a and the insulating layer 104b. Reducing the number of layers in the insulating layer 104 can simplify the manufacturing process of the semiconductor device.

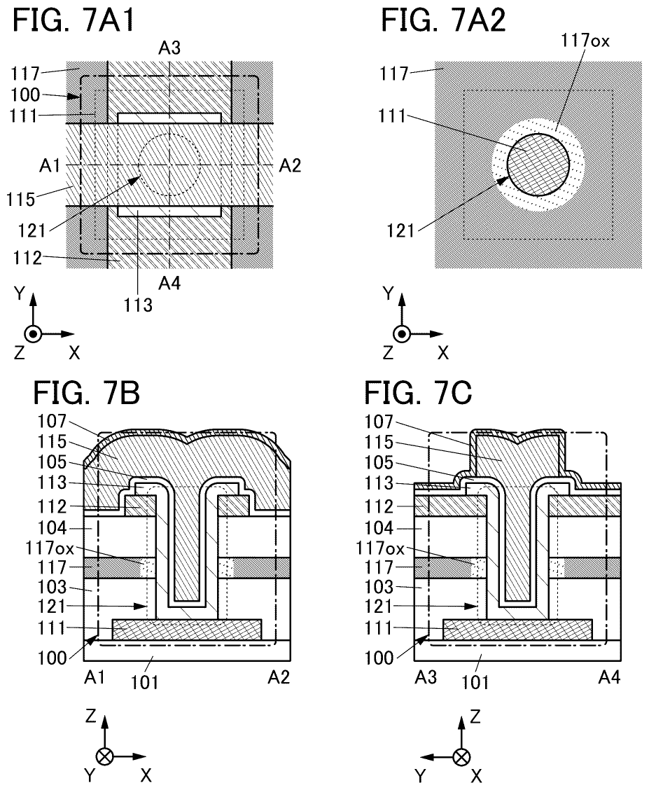

Although the shape of the conductive layer 117 is a belt-like shape extending in the Y direction in the example shown in FIG. 2A1, FIG. 2A2, FIG. 2B, and FIG. 2C, one embodiment of the present invention is not limited thereto. In FIG. 7A1, FIG. 7A2, FIG. 7B, and FIG. 7C, the conductive layer 117 illustrated in FIG. 2A1, FIG. 2A2, FIG. 2B, and FIG. 2C has a planar shape. Note that the conductive layer 117 may have a belt-like shape extending in the X direction.

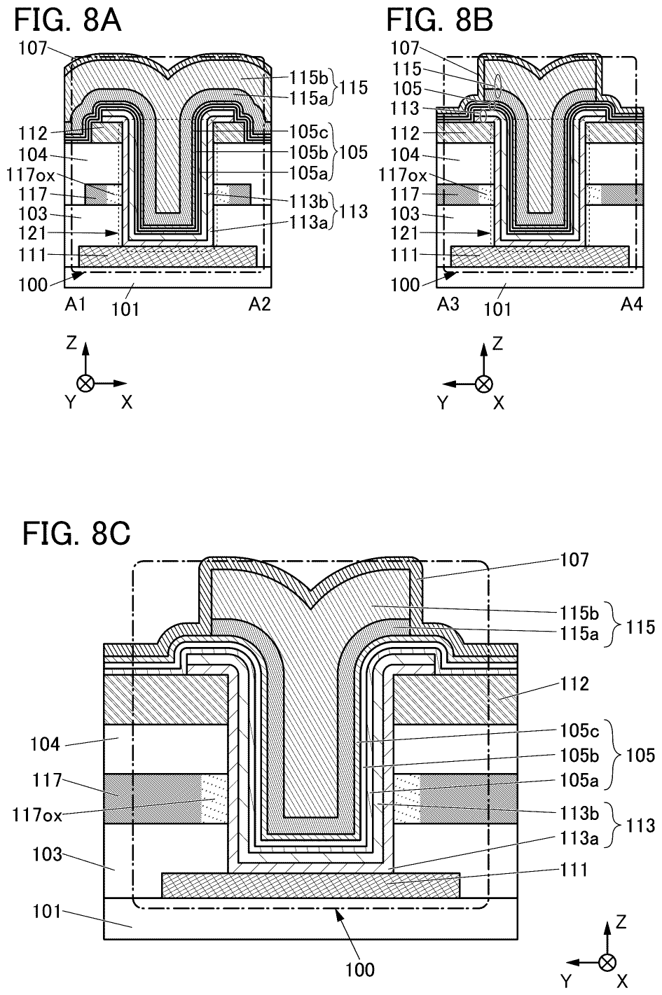

In FIG. 8A and FIG. 8B, the semiconductor layer 113, the insulating layer 105, and the conductive layer 115 illustrated in FIG. 2B and FIG. 2C each have a stacked-layer structure. FIG. 8C is an enlarged view of the transistor 100 in FIG. 8B.

In the example illustrated in FIG. 8A to FIG. 8C, the semiconductor layer 113 has a two-layer structure of a semiconductor layer 113a and a semiconductor layer 113b over the semiconductor layer 113a. In the example illustrated in FIG. 8A to FIG. 8C, the insulating layer 105 has a three-layer structure of an insulating layer 105a, an insulating layer 105b over the insulating layer 105a, and an insulating layer 105c over the insulating layer 105b. In the example illustrated in FIG. 8A to FIG. 8C, the conductive layer 115 has a two-layer structure of a conductive layer 115a and a conductive layer 115b over the conductive layer 115a.

The conductivity of a material used for the semiconductor layer 113a is preferably different from the conductivity of a material used for the semiconductor layer 113b.

For example, a material having higher conductivity than the semiconductor layer 113b can be used for the semiconductor layer 113a. When a material having high conductivity is used for the semiconductor layer 113a, which is in contact with the conductive layer 111 and the conductive layer 112, the contact resistance between the semiconductor layer 113 and the conductive layer 111 and the contact resistance between the semiconductor layer 113 and the conductive layer 112 can be low. This enables the transistor 100 to have a high on-state current.

Here, using a high-conductivity material for the semiconductor layer 113b, which is provided on the conductive layer 115 side, may lead to a low threshold voltage and normally-on characteristics of the transistor 100, for example. Thus, the semiconductor layer 113b is preferably formed using a material having lower conductivity than the semiconductor layer 113a. In that case, the transistor 100 can have a high threshold voltage and can be inhibited from having normally-on characteristics when the transistor 100 is an n-channel transistor. In other words, the transistor 100 can have normally-off characteristics.

When the semiconductor layer 113 has a stacked-layer structure and the semiconductor layer 113a is formed using a material having higher conductivity than the semiconductor layer 113b as described above, the transistor 100 can have normally-off characteristics and a high on-state current. Thus, the semiconductor device can have low power consumption and can be driven at high speed.

Note that the carrier concentration of the semiconductor layer 113a is preferably higher than that of the semiconductor layer 113b. A high carrier concentration of the semiconductor layer 113a leads to high conductivity, so that the contact resistance between the semiconductor layer 113 and the conductive layer 111 and the contact resistance between the semiconductor layer 113 and the conductive layer 112 can be low. This enables the transistor 100 to have a high on-state current. A low carrier concentration of the semiconductor layer 113b leads to low conductivity, so that the transistor 100 can have normally-off characteristics.

Although a material having higher conductivity than the semiconductor layer 113b is used for the semiconductor layer 113a in the example described here, one embodiment of the present invention is not limited thereto. A material having lower conductivity than the semiconductor layer 113b may be used for the semiconductor layer 113a. In that case, the carrier concentration of the semiconductor layer 113a can be lower than that of the semiconductor layer 113b.

The band gap of a first metal oxide used for the semiconductor layer 113a and the band gap of a second metal oxide used for the semiconductor layer 113b are preferably different from each other. For example, the difference between the band gap of the first metal oxide and the band gap of the second metal oxide is preferably larger than or equal to 0.1 eV, further preferably larger than or equal to 0.2 eV, still further preferably larger than or equal to 0.3 eV.

The band gap of the first metal oxide used for the semiconductor layer 113a can be smaller than the band gap of the second metal oxide used for the semiconductor layer 113b. Thus, the contact resistance between the semiconductor layer 113 and the conductive layer 111 and the contact resistance between the semiconductor layer 113 and the conductive layer 112 can be low, so that the transistor 100 can have a high on-state current. In addition, the transistor 100 can have a high threshold voltage and normally-off characteristics.

Although the example in which the band gap of the first metal oxide is smaller than that of the second metal oxide is described here, one embodiment of the present invention is not limited to the example. The band gap of the first metal oxide may be larger than or equal to that of the second metal oxide.

As described above, the band gap of the first metal oxide used for the semiconductor layer 113a can be smaller than the band gap of the second metal oxide used for the semiconductor layer 113b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have a composition of In:M:Zn=1:1:1 [atomic ratio] or in the neighborhood thereof, and the second metal oxide can have a composition of In:M:Zn=1:3:2 [atomic ratio] or in the neighborhood thereof or a composition of In:M:Zn=1:3:4 [atomic ratio] or in the neighborhood thereof. It is particularly preferable to use one or more of gallium, aluminum, and tin as the element M.

The first metal oxide does not necessarily include the element M. For example, the first metal oxide used for the semiconductor layer 113a can be In—Zn oxide, and the second metal oxide used for the semiconductor layer 113b can be an In—M—Zn oxide. Specifically, the first metal oxide can be In—Zn oxide, and the second metal oxide can be In—Ga—Zn oxide. More specifically, the first metal oxide can have a composition of In:Zn=1:1 [atomic ratio] or in the neighborhood thereof or a composition of In:Zn=4:1 [atomic ratio] or in the neighborhood thereof, and the second metal oxide can have a composition of In:Ga:Zn=1:1:1 [atomic ratio] or in the neighborhood thereof.

Although the example in which the content percentage of the element M in the first metal oxide is lower than that of the element M in the second metal oxide is described here, one embodiment of the present invention is not limited to the example. The content percentage of the element M in the first metal oxide may be higher than that of the element M in the second metal oxide. As long as the compositions of the first metal oxide and the second metal oxide are different from each other, the content percentages of elements other than the element M may be different from each other. For example, the second metal oxide may be used for the semiconductor layer 113a, and the first metal oxide may be used for the semiconductor layer 113b.

The thickness of the semiconductor layer 113 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the semiconductor layer 113 (here, the semiconductor layer 113a and the semiconductor layer 113b) are determined such that the thickness of the semiconductor layer 113 is within the above-described range. The thickness of the semiconductor layer 113a can be determined such that the contact resistance between the semiconductor layer 113a and the conductive layer 111 and the contact resistance between the semiconductor layer 113a and the conductive layer 112 are within the desired range. The thickness of the semiconductor layer 113b can be determined such that the threshold voltage of the transistor 100 is within the desired range. Note that the thickness of the semiconductor layer 113a may be the same as or different from the thickness of the semiconductor layer 113b.

Although the semiconductor layer 113 has a stacked-layer structure of two layers of the semiconductor layer 113a and the semiconductor layer 113b in the structure shown in FIG. 8A to FIG. 8C, one embodiment of the present invention is not limited to the structure. The semiconductor layer 113 may have a stacked-layer structure of three or more layers.

In the case where the semiconductor layer 113 has a stacked-layer structure of three layers, for example, the semiconductor layer 113 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in this order from the conductive layer 111 side. Alternatively, the semiconductor layer 113 may have a structure in which a metal oxide with a composition of In:Ga:Zn=1:3:4 [atomic ratio] or in the neighborhood thereof, a metal oxide with a composition of In:Zn=4:1 [atomic ratio] or in the neighborhood thereof, and a metal oxide with a composition of In:Ga:Zn=1:3:4 [atomic ratio] or in the neighborhood thereof are provided in this order from the conductive layer 111. Such a structure can increase the off-state current of the transistor 100. Furthermore, a variation in electrical characteristics of the transistors 100 can be reduced, and the reliability of the semiconductor device can be increased.

For the insulating layer 105a, any of the insulators with a barrier property against oxygen described in the later-described section [Insulator] is preferably used. The insulating layer 105a includes a region in contact with the semiconductor layer 113. When the insulating layer 105a has a barrier property against oxygen, release of oxygen from the semiconductor layer 113 at the time of performing heat treatment can be inhibited, for example. This can inhibit formation of oxygen vacancies in the semiconductor layer 113. Accordingly, the transistor 100 can have favorable electrical characteristics, and the reliability of the semiconductor device of one embodiment of the present invention can be increased. For the insulating layer 105a, aluminum oxide is preferably used, for instance. In that case, the insulating layer 105a includes at least oxygen and aluminum.

For the insulating layer 105b, any of the materials with a low relative permittivity described in the later-described section [Insulator] is preferably used. In particular, silicon oxide and silicon oxynitride, which are thermally stable, are preferable. In that case, the insulating layer 105b includes at least oxygen and silicon. With such a structure, the parasitic capacitance between the conductive layer 115 and the conductive layer 112 can be reduced. The concentration of impurities such as water and hydrogen in the insulating layer 105b is preferably reduced.

For the insulating layer 105c, any of the insulators with a barrier property against hydrogen described in the later-described section [Insulator] is preferably used. In that case, diffusion of impurities included in the conductive layer 115 into the semiconductor layer 113 can be inhibited. In particular, silicon nitride is suitable for the insulating layer 105c because of having a high hydrogen barrier property. In that case, the insulating layer 105c includes at least nitrogen and silicon.

The insulating layer 105c may further have a barrier property against oxygen. The insulating layer 105c is provided between the insulating layer 105b and the conductive layer 115. Thus, diffusion of oxygen included in the insulating layer 105b into the conductive layer 115 can be prevented, and oxidation of the conductive layer 115 can be inhibited.

An insulator may be provided between the insulating layer 105b and the insulating layer 105c. For the insulator, any of the insulators having a function of capturing or fixing hydrogen and described in the later-described section [Insulator] is preferably used. Providing the insulator enables more effective capturing or fixing of hydrogen included in the semiconductor layer 113. Thus, the hydrogen concentration in the semiconductor layer 113 can be lowered. As the insulator, for example, hafnium oxide is preferably used. In that case, the insulator includes at least oxygen and hafnium. Alternatively, the insulator may have an amorphous structure.

The thicknesses of the insulating layer 105a to the insulating layer 105c are preferably small for miniaturization of the transistor 100, and are preferably within the above-described ranges. Typically, the thicknesses of the insulating layer 105a, the insulating layer 105b, the insulator having a function of capturing or fixing hydrogen, and the insulating layer 105c are 1 nm, 2 nm, 2 nm, and 1 nm, respectively. This structure enables the transistor 100 to have favorable electrical characteristics even when the transistor 100 is miniaturized.

Although the insulating layer 105 has a stacked-layer structure of three layers of the insulating layer 105a to the insulating layer 105c in the structure shown in FIG. 8A to FIG. 8C, one embodiment of the present invention is not limited to the structure. The insulating layer 105 may have a stacked-layer structure of two layers or four or more layers. In that case, the layers included in the insulating layer 105 are preferably selected as appropriate from the insulating layer 105a to the insulating layer 105c and the insulator having a function of capturing or fixing hydrogen.

In the case where the conductive layer 115 has a two-layer structure of the conductive layer 115a and the conductive layer 115b, for example, the conductive layer 115a can be formed using titanium nitride and the conductive layer 115b can be formed using tungsten. Providing the layer including tungsten in this manner can increase the conductivity of the conductive layer 115 and reduce the wiring resistance of the conductive layer 115.

Although the conductive layer 115 has a stacked-layer structure of two layers of the conductive layer 115a and the conductive layer 115b in the structure shown in FIG. 8A to FIG. 8C, one embodiment of the present invention is not limited to the structure. The conductive layer 115 may have a stacked-layer structure of three or more layers.

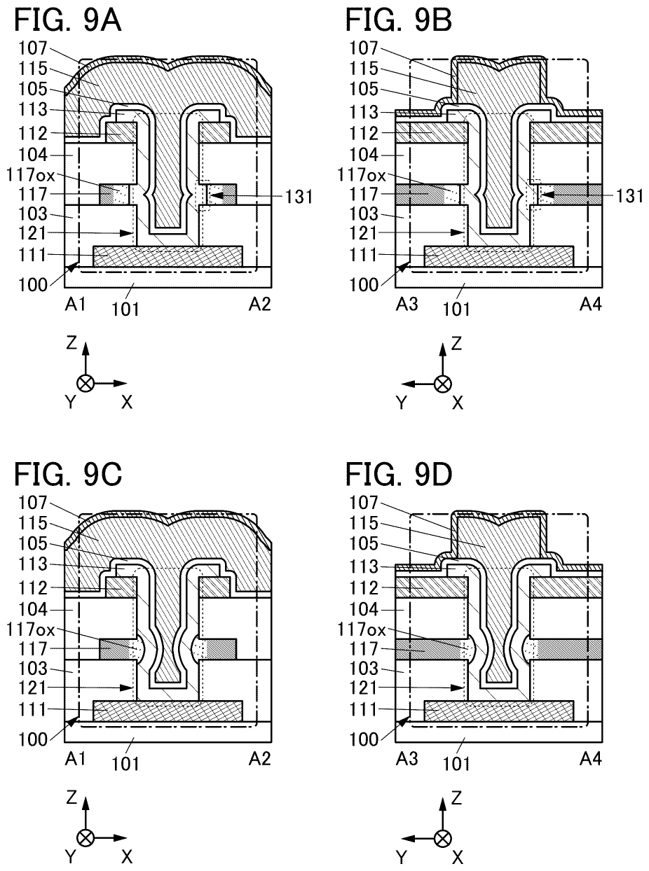

FIG. 9A and FIG. 9B illustrate an example in which, in the opening portion 121 illustrated in FIG. 2B and FIG. 2C, the side surface of the oxide region 117ox is positioned closer to a side opposite to the center of the conductive layer 111, i.e., closer to a side surface of the conductive layer 111, than the side surfaces of the insulating layer 103 and the insulating layer 104 are, for example. In the example illustrated in FIG. 9A and FIG. 9B, a depressed portion 131 is formed by the insulating layer 103, the insulating layer 104, and the oxide region 117ox.

Although the details will be described later, in the method for manufacturing the semiconductor device of one embodiment of the present invention, formation of the opening portion 121 in the conductive layer 117 may be followed by processing of the side surface of the conductive layer 117 in the opening portion 121 by, for example, isotropic etching, and subsequent oxidation treatment performed to form the oxide region 117ox. In that case, as illustrated in FIG. 9A and FIG. 9B, the side surface of the oxide region 117ox may be positioned closer to the side surface of the conductive layer 111 than the side surfaces of the insulating layer 103 and the insulating layer 104 are, for example.

FIG. 9C and FIG. 9D illustrate an example in which, in the opening portion 121 illustrated in FIG. 2B and FIG. 2C, the side surface of the oxide region 117ox is positioned closer to the center of the conductive layer 111 than the side surfaces of the insulating layer 103 and the insulating layer 104 are. In the example illustrated in FIG. 9C and FIG. 9D, the oxide region 117ox includes a protruding region, i.e., a projecting portion, in the opening portion 121.

When the oxide region 117ox is formed by oxidation of the conductive layer 117, the volume of the conductive layer 117 including the oxide region 117ox sometimes increases. In that case, the oxide region 117ox may include a protruding region in the opening portion 121 even when the side surfaces of the insulating layer 104, the conductive layer 117, and the insulating layer 103 in the opening portion 121 are aligned with each other at the time when the formation of the opening portion 121 in the insulating layer 104, the conductive layer 117, and the insulating layer 103 is completed, for example.

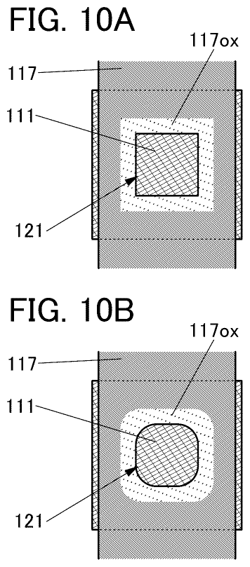

FIG. 10A shows an example in which the shape of the opening portion 121 shown in FIG. 2A2 is a quadrangle in a plan view. Although the shape of the opening portion 121 is a square in the plan view of FIG. 10A, the shape of the opening portion 121 is not limited thereto and may be, for example, a rectangle, a rhombus, or a parallelogram in the plan view. Furthermore, the shape of the opening portion 121 may be, for example, a triangle, a polygon with five or more corners, or a star shape in the plan view.

FIG. 10B illustrates an example in which the opening portion 121 illustrated in FIG. 10A has rounded corners. That is, FIG. 10B illustrates an example in which the shape of the opening portion 121 is a quadrangle with rounded corners in the plan view. Although the shape of the opening portion 121 is a square with rounded corners in the plan view in FIG. 10B, the shape of the opening portion 121 is not limited thereto and may be, in the plan view, a rectangle with rounded corners, a rhombus with rounded corners, a parallelogram with rounded corners, a triangle with rounded corners, a polygon with five or more corners that are rounded, or a star shape with rounded corners, for example.

In each of the examples shown in FIG. 2A2, FIG. 10A, FIG. 10B, and the like, the plan-view shape of the oxide region 117ox is similar to the plan-view shape of the opening portion 121. Specifically, in each of the shown examples, the plan-view shape of the boundary between the oxide region 117ox and the region of the conductive layer 117 that is not oxidized is similar to the plan-view shape of the side surface of the oxide region 117ox in the opening portion 121. However, one embodiment of the present invention is not limited thereto, and the type of the plan-view shape of the opening portion 121 may be different from the type of the plan-view shape of the oxide region 117ox. For example, the plan-view shape of the opening portion 121 may be a circular shape, and the plan-view shape of the boundary between the oxide region 117ox and the region of the conductive layer 117 that is not oxidized may be a quadrangular shape or a quadrangular shape with rounded corners. The plan-view shape of the opening portion 121 may be a quadrangular shape, and the plan-view shape of the boundary between the oxide region 117ox and the region of the conductive layer 117 that is not oxidized may be a quadrangular shape with rounded corners or a circular shape.

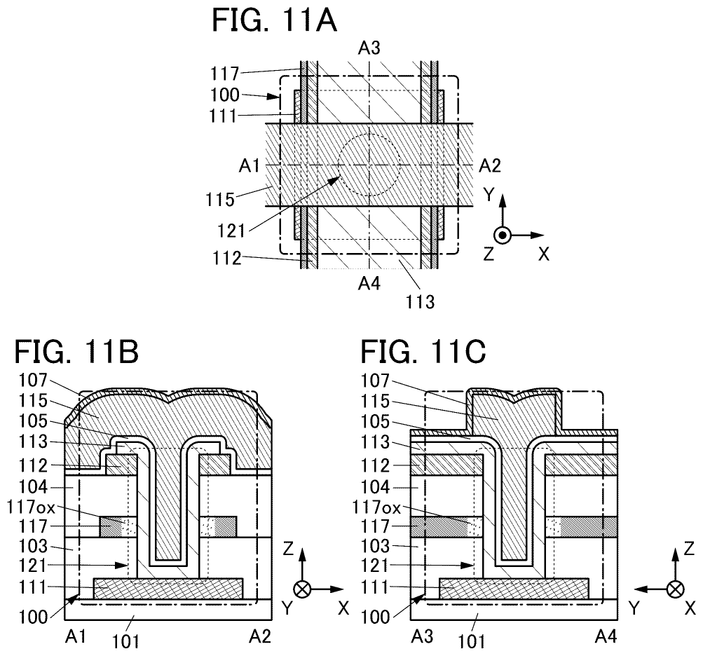

FIG. 11A, FIG. 11B, and FIG. 11C illustrate an example in which the semiconductor layer 113 illustrated in FIG. 2A1, FIG. 2B, and FIG. 2C is provided to extend in the Y direction. That is, in the example shown in FIG. 11A, FIG. 11B, and FIG. 11C, the semiconductor layer 113 extends in a direction parallel to the direction in which the conductive layer 112 extends. Also in the example illustrated in FIG. 11A, FIG. 11B, and FIG. 11C, the semiconductor layer 113 is divided in the X direction as in the example illustrated in FIG. 2A1, FIG. 2B, and FIG. 2C.

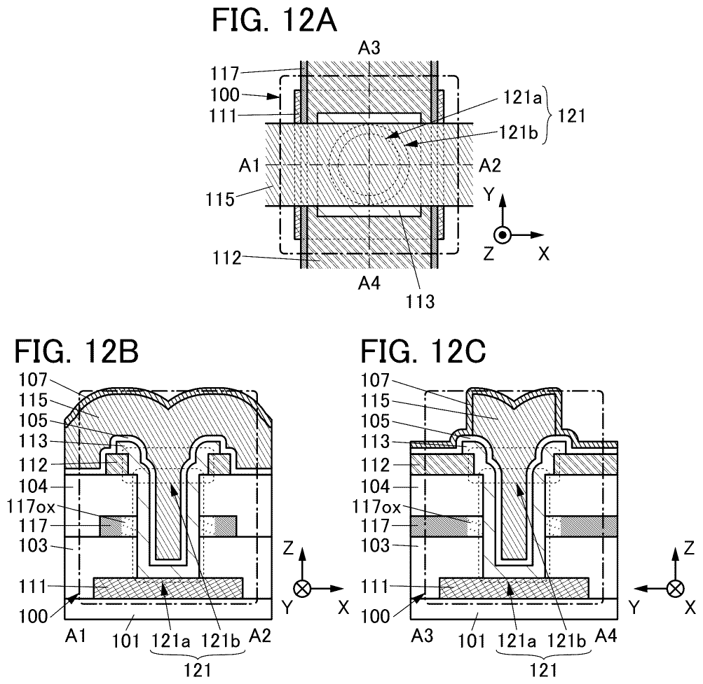

FIG. 12A, FIG. 12B, and FIG. 12C illustrate a modification example of the structure illustrated in FIG. 2A1, FIG. 2B, and FIG. 2C, where the plan-view shape of the opening portion 121 provided in the insulating layer 103, the oxide region 117ox, and the insulating layer 104 is different from the plan-view shape of the opening portion 121 provided in the conductive layer 112. Here, in FIG. 12A to FIG. 12C, the opening portion 121 provided in the insulating layer 103, the oxide region 117ox, and the insulating layer 104 is an opening portion 121a, and the opening portion 121 provided in the conductive layer 112 is an opening portion 121b. In the example illustrated in FIG. 12A to FIG. 12C, the opening portion 121b has a circular plan-view shape with a radius larger than that of the opening portion 121a. Note that one or both of the opening portion 121a and the opening portion 121b do not necessarily have a circular plan-view shape. For example, one or both of the plan-view shape of the opening portion 121a and the plan-view shape of the opening portion 121b can be any of the above-described shapes that the opening portion 121 can have, such as a quadrangular shape or a quadrangular shape with rounded corners.

Although the area of the opening portion 121b in the plan view is larger than the area of the opening portion 121a in the plan view in the example shown in FIG. 12A to FIG. 12C, the area of the opening portion 121b in the plan view may be smaller than the area of the opening portion 121a in the plan view. In that case, the conductive layer 112 includes a region protruding with respect to the sidewall of the opening portion 121a.

For example, in the case where the opening portion 121a and the opening portion 121b are formed in different processes, the plan-view shape of the opening portion 121a and the plan-view shape of the opening portion 121b may be different from each other. In the case where the opening portion 121a and the opening portion 121b are formed in the same process but the etching rate of the conductive layer 112 in the X direction and the Y direction is different from the etching rate of the insulating layer 103, the conductive layer 117, and the insulating layer 104 in the X direction and the Y direction, for example, the plan-view shape of the opening portion 121a and the plan-view shape of the opening portion 121b may be different from each other. For example, in the case where the etching rate of the conductive layer 112 in the X direction and the Y direction is higher than the etching rate of the insulating layer 103, the conductive layer 117, and the insulating layer 104 in the X direction and the Y direction, the area of the opening portion 121b in the plan view is sometimes larger than the area of the opening portion 121a in the plan view even when the opening portion 121a and the opening portion 121b are formed in the same process.

### <Constituent Material of Semiconductor Device>

Component materials that can be used for the semiconductor device are described below.

### [Substrate]

As the substrate where the transistor 100 is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate including silicon or germanium as a material and a compound semiconductor substrate including silicon carbide, silicon germanium, gallium arsenide, indium phosphide, zinc oxide, and gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, any of these substrates provided with elements may be used.

### [Insulator]

Examples of an insulator include an oxide, a nitride, an oxynitride, a nitride oxide, a metal oxide, a metal oxynitride, and a metal nitride oxide, each of which has an insulating property.

With further miniaturization of a transistor, for example, a problem of a leakage current may arise because of a thinned gate insulating layer. When a high-k material is used for an insulator functioning as a gate insulating layer, the voltage at the time of operation of the transistor can be reduced while the physical thickness of the gate insulating layer is kept. In addition, the equivalent oxide thickness (EOT) of the insulator functioning as the gate insulating layer can be reduced. In contrast, when a material with a low relative permittivity is used for the insulator functioning as an interlayer film, parasitic capacitance generated between wirings can be reduced. Thus, a material is preferably selected in accordance with the function of the insulator. Note that the material with a low relative permittivity is a material with high dielectric strength.

Examples of a material with a high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low relative permittivity include silicon oxide to which fluorine is added, silicon oxide to which carbon is added, and silicon oxide to which carbon and nitrogen are added. Another example is porous silicon oxide. These silicon oxides may contain nitrogen. Silicon oxide may be formed using, for example, organosilane such as tetraethoxysilane (TEOS).

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulating layer, preferably includes a region including excess oxygen. For example, when an insulator having a region including excess oxygen is in contact with a semiconductor layer or provided in the vicinity of the semiconductor layer, oxygen vacancies in the semiconductor layer can be reduced. As examples of an insulator in which a region including excess oxygen is easily formed, silicon oxide, silicon oxynitride, porous silicon oxide, and the like can be given.

Examples of an insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of an insulator having a function of capturing or fixing hydrogen include an oxide containing magnesium and an oxide containing one or both of aluminum and hafnium. These oxides preferably have an amorphous structure. In an oxide having an amorphous structure, an oxygen atom has a dangling bond, and the oxide has a property of capturing or fixing hydrogen with the dangling bond in some cases. Although these oxides preferably have an amorphous structure, a crystal region may be partly formed.

Note that in this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Moreover, a function of capturing or fixing a target substance can be rephrased as a barrier property. Note that hydrogen described as a target substance refers to at least one of a hydrogen atom, a hydrogen molecule, and a substance obtained by bonding with hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), a copper atom, and the like. Oxygen described as a target substance refers to, for example, at least one of an oxygen atom, an oxygen molecule, and the like. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive material containing oxygen may be referred to as an oxide conductor.

In addition, a conductive material containing tungsten, copper, or aluminum as its main component is preferable because it has high conductivity.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be trapped in some cases. Alternatively, hydrogen entering from a surrounding insulator or the like can be captured in some cases.

### [Metal Oxide]

A metal oxide has a lattice defect in some cases. Examples of a lattice defect include point defects such as an atomic vacancy and an exotic atom, linear defects such as transition, plane defects such as a grain boundary, and volume defects such as a cavity. Examples of a factor in generating a lattice defect include a deviation of the proportion of the number of constituent element atoms (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects for a semiconductor layer of a transistor may cause unstable electrical characteristics of the transistor. Hence, a metal oxide used for a semiconductor layer of a transistor preferably has a small number of lattice defects.

In particular, the electrical characteristics of a transistor including a metal oxide easily change when oxygen vacancies (Vo) and impurities exist in a channel formation region in the metal oxide, which might degrade the reliability. In some cases, hydrogen in the vicinity of the oxygen vacancies forms VoH and generates an electron serving as a carrier. Thus, when the channel formation region in the metal oxide includes oxygen vacancies, the transistor is likely to have normally-on characteristics. Therefore, oxygen vacancies and impurities are preferably reduced as much as possible in the channel formation region in the metal oxide. In other words, it is preferable that the channel formation region in the metal oxide have a reduced carrier concentration and be of an i-type (intrinsic) or be substantially of an i-type.

The kind of a lattice defect that is likely to be present in a metal oxide and the amount of lattice defects that are present there depend on the structure of the metal oxide, a method for forming a film of the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Accordingly, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, the transistor can have high reliability.

For the channel formation region of a transistor, a metal oxide that increases the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the surface over which the metal oxide is formed or the film surface of the metal oxide. This enables the plurality of layers to be placed parallel or substantially parallel to the surface over which the metal oxide is formed or the film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the mobility of the metal oxide. Thus, the use of the metal oxide for the channel formation region of a transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, the element M, and zinc. Note that the element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

For example, as the metal oxide of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like can be used. Alternatively, indium tin oxide containing silicon, gallium tin oxide (Ga—Sn oxide), aluminum tin oxide (Al—Sn oxide), or the like can be used. Alternatively, the above-described oxide having an amorphous structure can be used. For example, indium oxide having an amorphous structure, indium tin oxide having an amorphous structure, or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor including a metal element with a larger period number in the periodic table can have higher field-effect mobility in some cases. Examples of the metal element with a larger period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Incidentally, lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which can make the off-state current of the transistor low. Furthermore, a change in electrical characteristics of the transistor can be inhibited, and the reliability of the transistor can be increased.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. By an ALD method, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. The use of plasma in a PEALD method is sometimes preferable because it enables film formation at a lower temperature. Note that a precursor used in an ALD method sometimes contains an element such as carbon or chlorine. Thus, in some cases, a film provided by an ALD method includes a larger amount of an element such as carbon or chlorine than a film provided by another film formation method. Note that these elements can be quantified by XPS or SIMS.

When an ALD method is used as the formation method of a film of a metal oxide, employing one or both of a film formation condition with a high substrate temperature and impurity removal treatment makes it possible to form a film having smaller amounts of carbon and chlorine than a film formed using an ALD method without employing the condition or the treatment.

For example, impurity removal treatment is preferably intermittently performed in an atmosphere containing oxygen during formation of the film of the metal oxide. Furthermore, impurity removal treatment is preferably performed in an atmosphere containing oxygen after the formation of the film of the metal oxide. The impurities in the film can be removed by performing impurity removal treatment during and/or after the formation of the film of the metal oxide. This can inhibit impurities (e.g., hydrogen, carbon, and nitrogen) contained in a raw material such as a precursor from remaining in the metal oxide. Accordingly, the impurity concentration in the metal oxide can be reduced. Furthermore, the crystallinity of the metal oxide can be increased. Thus, the metal oxide can be a CAAC-OS, for example, and the semiconductor device can be highly reliable.

Examples of the impurity removal treatment include microwave treatment and heat treatment.

When microwave treatment is performed, the substrate temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C. The heat treatment temperature is preferably higher than or equal to 100° C., higher than or equal to 200° C., higher than or equal to 300° C., or higher than or equal to 400° C., and lower than or equal to 500° C. or lower than or equal to 450° C.

The temperature at the time of the impurity removal treatment is particularly preferably set lower than or equal to the maximum temperature in the manufacturing process of the transistor or the semiconductor device, in which case the impurity content in the metal oxide can be reduced without a decrease in productivity. For example, when the maximum temperature in manufacturing the semiconductor device of one embodiment of the present invention is lower than or equal to 500° C., preferably lower than or equal to 450° C., the productivity of the semiconductor device can be improved.

The microwave treatment is preferably performed with a microwave treatment apparatus including a power source for generating high-density plasma using microwaves, for example. Here, the frequency of the microwave treatment apparatus is preferably set higher than or equal to 300 MHz and lower than or equal to 300 GHz, further preferably higher than or equal to 2.4 GHz and lower than or equal to 2.5 GHZ, and can be set to 2.45 GHz, for example. Oxygen radicals at a high density can be generated with high-density plasma. The electric power of the power source that applies microwaves of the microwave treatment apparatus is preferably set higher than or equal to 1000 W and lower than or equal to 10000 W, further preferably higher than or equal to 2000 W and lower than or equal to 5000 W. The microwave treatment apparatus may be provided with a power source that applies RF (Radio Frequency) to the substrate side. Furthermore, application of RF to the substrate side allows oxygen ions generated by the high-density plasma to be introduced into the film efficiently.

The microwave treatment is preferably performed under reduced pressure, and the pressure is preferably set higher than or equal to 10 Pa and lower than or equal to 1000 Pa, further preferably higher than or equal to 300 Pa and lower than or equal to 700 Pa. The treatment temperature is preferably higher than or equal to room temperature (25° C.) and lower than or equal to 750° C., further preferably higher than or equal to 300° C. and lower than or equal to 500° C., still further preferably higher than or equal to 400° C. and lower than or equal to 450° C.

After the microwave treatment is performed, heat treatment may be successively performed without exposure to the air. The temperature of the heat treatment is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%.

The heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is preferably approximately 20%. Alternatively, the heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere. The heat treatment may be performed under an atmosphere of ultra-dry air (air with a water content lower than or equal to 20 ppm, lower than or equal to 1 ppm, further preferably lower than or equal to 10 ppb).

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide having a layered crystal structure with high crystallinity, specifically, a metal oxide having the CAAC structure can be formed.

Unlike a film formation method in which particles ejected from a target or the like are deposited, an ALD method is a film formation method in which a film is formed by reaction at a surface of an object. Thus, an ALD method is a film formation method that enables favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a sputtering method or a CVD method, in some cases. A method in which a sputtering method is used to form a film of the first metal oxide and an ALD method is used to form a film of the second metal oxide over the film of the first metal oxide is given as an example. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with an arbitrary composition can be formed by adjusting the amount of introduced source gases, the number of times of introduction (also referred to as the number of pulses), and the time required for one pulse (also referred to as the pulse time) in an ALD method. Moreover, for example, when the source gas is changed during the film formation by an ALD method, a film having a continuously changed composition can be formed. In the case where a film is formed while the source gas is changed, the time taken for transfer and pressure adjustment is saved, and thus, the time taken for the film formation can be shortened as compared to the case where a film is formed using a plurality of film formation chambers. Thus, the productivity of the semiconductor device can be increased in some cases.

### [[Transistor Including Metal Oxide]]

Next, the case where a metal oxide (oxide semiconductor) is used for a transistor will be described.

When a metal oxide (oxide semiconductor) of one embodiment of the present invention is used for a transistor, a transistor with high field-effect mobility can be achieved. In addition, a transistor with high reliability can be achieved. Furthermore, a miniaturized transistor can be achieved. For example, a transistor with a channel length greater than or equal to 2 nm and less than or equal to 30 nm can be manufactured.

An oxide semiconductor having a low carrier concentration is preferably used for a channel formation region of a transistor. For example, the carrier concentration of an oxide semiconductor in the channel formation region is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet still further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, an OS transistor includes an oxide semiconductor that is a semiconductor material having a large band gap, and thus can suppress the short-channel effect. In other words, a short-channel effect does not appear or hardly appears in an OS transistor.

Note that the short-channel effect refers to degradation of electrical characteristics which becomes apparent along with miniaturization of a transistor (a decrease in channel length). Specific examples of the short-channel effect include a decrease in threshold voltage, an increase in a subthreshold swing value (sometimes referred to as an S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be manufactured, the OS transistor is preferable to the Si transistor.

Even in the case where the carrier concentration of the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

An OS transistor having the above structure can achieve favorable electrical characteristics even when the OS transistor is miniaturized. For example, favorable electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be higher than or equal to 50 GHz, preferably higher than or equal to 100 GHz, further preferably higher than or equal to 150 GHz in a room temperature environment, for example.

The above comparison of the OS transistor with the Si transistor demonstrates that the OS transistor is advantageous over the Si transistor in that the off-state current is low and a short-channel transistor can be manufactured, for example.

### [[Impurity in Metal Oxide]]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor that is obtained by SIMS is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. The silicon concentration in the channel formation region of the oxide semiconductor that is obtained by SIMS is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor that contains nitrogen as a semiconductor is likely to have normally-on characteristics. When the oxide semiconductor contains nitrogen, trap states are sometimes formed. This might make the electrical characteristics of the transistor unstable. Therefore, the nitrogen concentration in the channel formation region of the oxide semiconductor that is obtained by SIMS is set lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

### [Other Semiconductor Materials]

The semiconductor layer 113 can be rephrased as a semiconductor layer including the channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As examples of silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables the semiconductor device to have a high on-state current.

### Manufacturing Method Example 1 of Semiconductor Device

As a method for manufacturing a semiconductor device of one embodiment of the present invention, an example of a method for manufacturing the semiconductor device illustrated in FIG. 2A1, FIG. 2B, and FIG. 2C is described below.

Hereinafter, a film of an insulating material for forming an insulating layer, a film of a conductive material for forming a conductive layer, or a film of a semiconductor material for forming a semiconductor layer can be formed by using a film formation method such as a sputtering method, a CVD method, an MBE method, a PLD method, or an ALD method as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. In contrast, such plasma damage does not occur in the case of a thermal CVD method that does not use plasma, and thus the yield of the semiconductor device can be increased. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, a CVD method and an ALD method are film formation methods that enable favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gas. For example, when the flow rate ratio of the source gas is changed during the film formation by a CVD method, a film having a continuously changed composition can be formed. In the case where a film is formed while the flow rate ratio of the source gas is changed, the time taken for transfer or pressure adjustment is saved, and thus, the time taken for the film formation can be shortened as compared to the case where a film is formed using a plurality of film formation chambers. Thus, the productivity of the semiconductor device can be increased in some cases.

By an ALD method, a film with a certain composition can be formed by concurrently introducing different kinds of precursors. In the case where different kinds of precursors are introduced, a film with a certain composition can be formed by controlling the number of cycles for each of the precursors.

In the drawings showing the method for manufacturing the semiconductor device of one embodiment of the present invention, each drawing A and each drawing A1 are plan views unless otherwise noted. Each drawing B is a cross-sectional view taken along the dashed-dotted line A1-A2 in each drawing A or each drawing A1, and each drawing C is a cross-sectional view taken along the dashed-dotted line A3-A4 in each drawing A or each drawing A1.

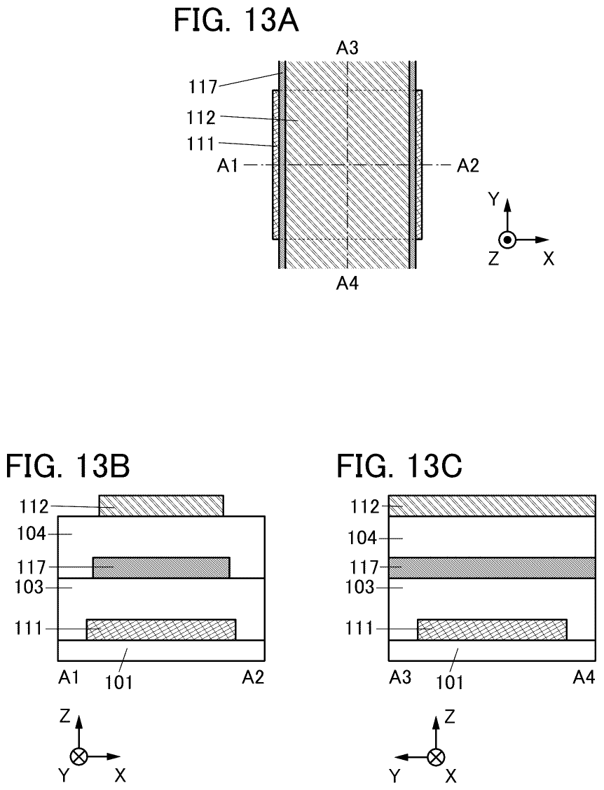

First, a substrate (not illustrated) is prepared, and the insulating layer 101 is formed over the substrate (FIG. 13A, FIG. 13B, and FIG. 13C). Any of the above-described insulating materials can be appropriately used for the insulating layer 101. The insulating layer 101 can be formed by using a film formation method such as a sputtering method, a CVD method, an MBE method, a PLD method, or an ALD method as appropriate.

Next, the conductive layer 111 is formed over the insulating layer 101 (FIG. 13A, FIG. 13B, and FIG. 13C). For example, the conductive layer 111 can be formed by forming and processing a conductive film to be the conductive layer 111. For the conductive film to be the conductive layer 111, any of the above-described conductive materials that can be used for the conductive layer 111 can be used as appropriate.

The conductive film to be the conductive layer 111 can be formed by using a film formation method such as a sputtering method, a CVD method, an MBE method, a PLD method, or an ALD method as appropriate. After the conductive film to be the conductive layer 111 is formed, a pattern is formed by a lithography method, for example, and the conductive film is processed by a dry etching method, a wet etching method, or the like using the pattern, whereby the conductive layer 111 can be formed. Here, for fine processing, the conductive film is preferably processed by a dry etching method.

Note that in a lithography method, first, a resist is exposed to light through a mask. Next, a region exposed to light is removed or left using a developing solution, so that a resist mask is formed. Thus, a pattern is formed.

The resist mask is formed through, for example, exposure of the resist to KrF excimer laser light, ArF excimer laser light, EUV light, or the like. A liquid immersion technique may be employed in which a gap between a substrate and a projection lens is filled with a liquid such as water in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

Next, etching treatment is performed using the resist mask. Thus, a conductive film, a semiconductor film, an insulating film, and the like can be processed into desired shapes.

In the case of performing dry etching treatment as the above etching treatment, an etching gas including a halogen can be used as an etching gas; specifically, an etching gas including one or more of fluorine, chlorine, and bromine can be used. As the etching gas, for example, a C₄F₆ gas, a C₅F₆ gas, a C₄F₈ gas, a CF₄ gas, a SF₆ gas, a NF₃ gas, a CHF₃ gas, a Cl₂ gas, a BCl₃ gas, a SiCl₄ gas, a CCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus can be used, for example.

Next, the insulating layer 103 is formed over the insulating layer 101 and the conductive layer 111 (FIG. 13A, FIG. 13B, and FIG. 13C). For the insulating layer 103, any of the above-described insulating materials can be appropriately used. The insulating layer 103 can be formed by using a film formation method such as a sputtering method, a CVD method, an MBE method, a PLD method, or an ALD method as appropriate. The top surface of the formed insulating layer 103 is preferably planarized by chemical mechanical polishing (CMP) treatment. The planarization treatment on the insulating layer 103 makes it possible to favorably form the conductive layer 117 in a later step. Furthermore, a film of aluminum oxide may be formed over the insulating layer 103 by a sputtering method, and then subjected to planarization treatment until the insulating layer 103 is reached. The planarization treatment can planarize and smooth the surface of the insulating layer 103. When the planarization treatment is performed with the aluminum oxide placed over the insulating layer 103, it is easy to detect the endpoint of the planarization treatment.

The planarization treatment may be skipped in some cases. In that case, the top surface of the insulating layer 103 has an upward-convex curved surface shape. By not performing planarization treatment, manufacturing cost can be reduced and production yield can be increased. Accordingly, the semiconductor device can be inexpensive.

Next, the conductive layer 117 is formed over the insulating layer 103 (FIG. 13A, FIG. 13B, and FIG. 13C). The conductive layer 117 can be formed by a method similar to a method that can be used for forming the conductive layer 111. For a conductive film to be the conductive layer 117, any of the above-described conductive materials that can be used for the conductive layer 117 can be appropriately used. Note that in the case where the conductive layer 117 is formed to have a planar shape as illustrated in FIG. 7A1, FIG. 7A2, FIG. 7B, and FIG. 7C, formation of a pattern by a lithography method and processing of the conductive film using the pattern may sometimes be skipped.

Next, the insulating layer 104 is formed over the insulating layer 103 and the conductive layer 117 (FIG. 13A, FIG. 13B, and FIG. 13C). The insulating layer 104 can be formed by a method similar to a method that can be used for forming the insulating layer 103. Any of the above-described insulating materials can be appropriately used for the insulating layer 104.

Here, the thicknesses of the insulating layer 103, the conductive layer 117, and the insulating layer 104 in the region overlapping with the conductive layer 111 correspond to the channel length of the transistor 100. Thus, the thicknesses of the insulating layer 103, the conductive layer 117, and the insulating layer 104 can be set as appropriate in accordance with the design value of the channel length of the transistor 100.

Next, the conductive layer 112 is formed over the insulating layer 104 (FIG. 13A, FIG. 13B, and FIG. 13C). The conductive layer 112 can be formed by a method similar to a method that can be used for forming the conductive layer 111. For a conductive film to be the conductive layer 112, any of the above-described conductive materials that can be used for the conductive layer 112 can be appropriately used.

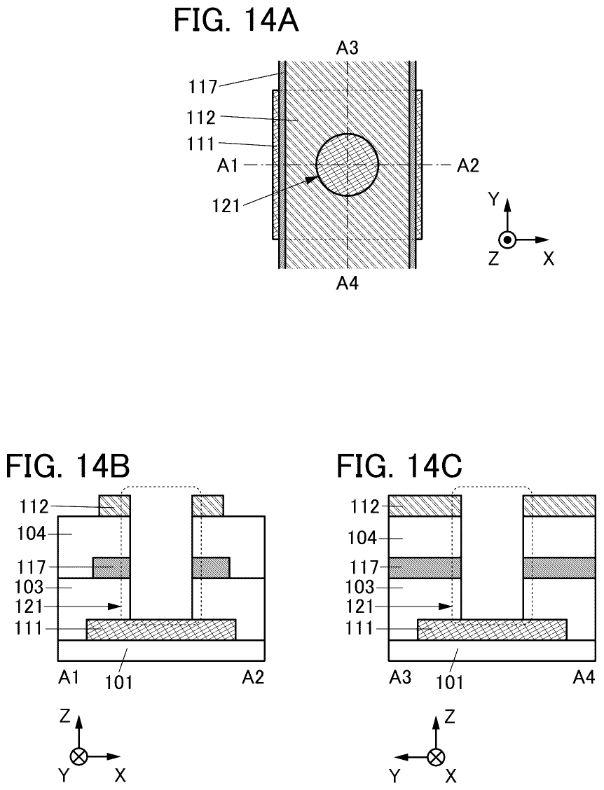

Then, part of the conductive layer 112, part of the insulating layer 104, part of the conductive layer 117, and part of the insulating layer 103 are processed to form the opening portion 121 reaching the conductive layer 111 (FIG. 14A, FIG. 14B, and FIG. 14C). The opening portion 121 can be formed by a lithography method and an etching method, for example.

As described above, the sidewall of the opening portion 121 is preferably perpendicular to the top surface of the conductive layer 111. With such a structure, the transistor 100 can be miniaturized. Alternatively, the sidewall of the opening portion 121 may have a tapered shape. When the sidewall of the opening portion 121 has a tapered shape, the coverage with a later-described metal oxide film to be the semiconductor layer 113 can be improved, for example, so that defects such as voids can be reduced. Here, the maximum width of the opening portion 121 (the maximum diameter in the case where the opening portion 121 is circular in the plan view) is preferably small.

Since the opening portion 121 has a high aspect ratio, the part of the conductive layer 112, the part of the insulating layer 104, the part of the conductive layer 117, and the part of the insulating layer 103 are preferably processed by anisotropic etching. Processing by a dry etching method is particularly preferable because it is suitable for fine processing. The part of the conductive layer 112, the part of the insulating layer 104, the part of the conductive layer 117, and the part of the insulating layer 103 may be processed under different conditions. Note that depending on the conditions for processing the part of the conductive layer 112, the part of the insulating layer 104, the part of the conductive layer 117, and the part of the insulating layer 103, at least one of the inclination of the side surface of the conductive layer 112 in the opening portion 121, the inclination of the side surface of the insulating layer 104 in the opening portion 121, the inclination of the side surface of the conductive layer 117 in the opening portion 121, and the inclination of the side surface of the insulating layer 103 in the opening portion 121 may be different from the other(s).

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in an atmosphere of a nitrogen gas or an inert gas, for example. Alternatively, the heat treatment may be performed under reduced pressure. By the above-described heat treatment, an impurity such as water contained in the insulating layer 103 and the insulating layer 104, for example, can be reduced before the later-described metal oxide film to be the semiconductor layer 113 is formed.

The gas used in the above heat treatment is preferably highly purified. For example, the amount of moisture contained in the gas used in the above heat treatment is lower than or equal to 1 ppb, preferably lower than or equal to 0.1 ppb, further preferably lower than or equal to 0.05 ppb. The heat treatment using a highly purified gas can prevent, for example, entry of moisture into the insulating layer 103 as much as possible.

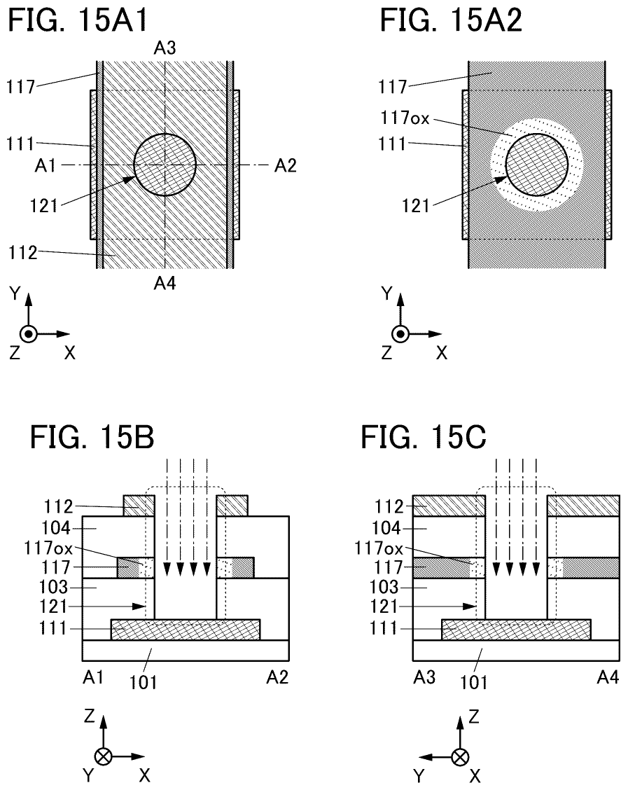

Next, oxidation treatment is performed on the side surface of the conductive layer 117 in the opening portion 121, so that the oxide region 117ox is formed in the conductive layer 117 (FIG. 15A1, FIG. 15A2, FIG. 15B, and FIG. 15C). Here, FIG. 15A2 is a plan view obtained by omitting the conductive layer 112 from FIG. 15A1.

The oxidation treatment can be performed by microwave treatment in an atmosphere containing oxygen. The dashed-dotted arrows in FIG. 15B and FIG. 15C indicate high-frequency waves such as microwaves or RF, oxygen plasma, oxygen radicals, or the like. Also in the following drawings illustrating the example of the method for manufacturing the semiconductor device, dashed-dotted arrows indicate high-frequency waves such as microwaves or RF, oxygen plasma, oxygen radicals, or the like.

For the conditions of the microwave treatment, the conditions of the microwave treatment described in <Constituent material of semiconductor device> above can be referred to, for example. Note that the method of the above oxidation treatment is not limited to microwave treatment, and oxygen plasma treatment or thermal oxidation treatment may be used, for example.

Here, part of the conductive layer 111 is exposed by the opening portion 121. The conductive layer 112 also has an exposed surface. Accordingly, not only the conductive layer 117 but also the conductive layer 111 and the conductive layer 112 are subjected to the oxidation treatment. Thus, as described above, each of the conductive layer 111 and the conductive layer 112 is formed using a material that is less likely to be oxidized than the conductive layer 117 or a material having conductivity even after being oxidized, and can be formed using a conductive material containing oxygen, for example.

Next, a semiconductor film to be the semiconductor layer 113 is formed in contact with the bottom portion and the sidewall of the opening portion 121 and at least part of the top surface of the conductive layer 112. For the semiconductor film, any of the above-described semiconductors that can be used for the semiconductor layer 113 can be used as appropriate, and a metal oxide film can be used, for example. The semiconductor film can be formed by using a film formation method such as a sputtering method, a CVD method, an MBE method, a PLD method, or an ALD method as appropriate. Here, the semiconductor film is preferably formed in contact with the bottom portion and the sidewall of the opening portion 121 with a high aspect ratio. Thus, the semiconductor film is preferably formed by a film formation method enabling favorable coverage, and is further preferably formed by a CVD method, an ALD method, or the like. The semiconductor film to be the semiconductor layer 113 can be a film of In—Ga—Zn oxide formed by an ALD method, for example.

In the case where the semiconductor layer 113 has a stacked-layer structure, the layers included in the semiconductor layer 113 may be formed by the same method or different methods. For example, in the case where the semiconductor layer 113 has a two-layer structure of the semiconductor layer 113a and the semiconductor layer 113b as illustrated in FIG. 8A to FIG. 8C, a semiconductor film to be the semiconductor layer 113a may be formed by a sputtering method and a semiconductor film to be the semiconductor layer 113b may be formed by an ALD method.

A metal oxide film formed by a sputtering method is likely to have crystallinity. Thus, in the case where a metal oxide film is used as the semiconductor film to be the semiconductor layer 113b, the crystallinity of the metal oxide film can be increased by using a metal oxide film with crystallinity as the semiconductor film to be the semiconductor layer 113a. Even when a pinhole, disconnection, or the like is formed in the metal oxide film to be the semiconductor layer 113a formed by a sputtering method, the pinhole, the disconnection, or the like can be filled with the metal oxide film to be the semiconductor layer 113b formed by an ALD method enabling favorable coverage. Note that both the semiconductor layer 113a and the semiconductor layer 113b may be formed by an ALD method. In that case, not only coverage with the semiconductor layer 113b but also coverage with the semiconductor layer 113a can be improved.

Here, the semiconductor film to be the semiconductor layer 113 is preferably formed in contact with the top surface of the conductive layer 111 in the opening portion 121, the side surfaces of the insulating layer 103, the oxide region 117ox, the insulating layer 104, and the conductive layer 112 in the opening portion 121, and the top surface of the conductive layer 112. When the semiconductor film is formed in contact with the conductive layer 111, the conductive layer 111 functions as the one of the source electrode and the drain electrode of the transistor 100. When the semiconductor film is formed in contact with the conductive layer 112, the conductive layer 112 functions as the other of the source electrode and the drain electrode of the transistor 100.

In the case where a metal oxide film is used as the semiconductor film to be the semiconductor layer 113, the formation of the metal oxide film is preferably followed by the above-described impurity removal treatment, specifically, microwave treatment, for example. For the details of the microwave treatment, the above description can be referred to. After that, heat treatment is preferably performed. The heat treatment can be performed in a temperature range where the metal oxide film does not become polycrystals, i.e., at higher than or equal to 250° C. and lower than or equal to 650° C., preferably higher than or equal to 400° C. and lower than or equal to 600° C. For the details of the heat treatment, the above description can be referred to. In this manner, the metal oxide film can be a CAAC-OS, for example, and a method for manufacturing a highly reliable semiconductor device can be provided.

Although the heat treatment is performed after the formation of the semiconductor film in the above, one embodiment of the present invention is not limited thereto. The heat treatment may be performed in a later step.

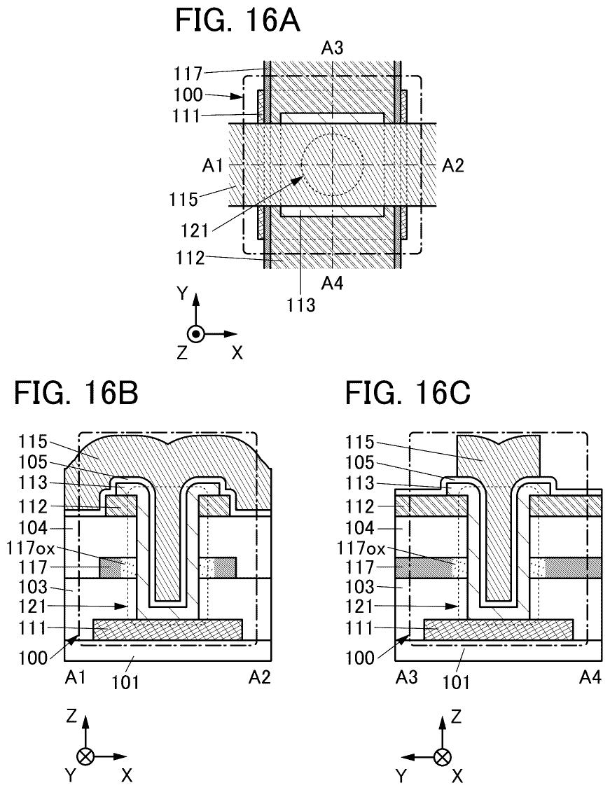

Next, a pattern is formed by a lithography method, for example, and then, the semiconductor film to be the semiconductor layer 113 is processed by an etching method using the pattern. Thus, the semiconductor layer 113 is formed (FIG. 16A, FIG. 16B, and FIG. 16C). Part of the semiconductor layer 113 is formed in the opening portion 121. The semiconductor layer 113 is in contact with the side surface and part of the top surface of the conductive layer 112. In the above-described manner, the semiconductor layer 113 is formed to include the region in contact with the top surface of the conductive layer 111, a region in contact with the side surface of the oxide region 117ox, the region in contact with the side surface of the conductive layer 112, and the region in contact with the top surface of the conductive layer 112 and to include the region positioned in the opening portion 121. Note that the semiconductor layer 113 can be formed to include the region in contact with the side surface of the insulating layer 103 and the region in contact with the side surface of the insulating layer 104 in the opening portion 121.

Next, the insulating layer 105 is formed over the semiconductor layer 113, the conductive layer 112, and the insulating layer 104 (FIG. 16A, FIG. 16B, and FIG. 16C). For the insulating layer 105, any of the above-described insulating materials can be appropriately used. The insulating layer 105 can be formed by using a film formation method such as a sputtering method, a CVD method, an MBE method, a PLD method, or an ALD method as appropriate. The insulating layer 105 is preferably formed in contact with the semiconductor layer 113 that is provided in the opening portion 121 having a high aspect ratio. Thus, the insulating layer 105 is preferably formed by a film formation method enabling favorable coverage, and is further preferably formed by a CVD method, an ALD method, or the like. For example, a film of silicon oxide is formed as the insulating layer 105 by an ALD method.

In the case where the sidewall of the opening portion 121 has a tapered shape, the method for forming the insulating layer 105 is not limited to a CVD method or an ALD method. For example, the insulating layer 105 may be formed by a sputtering method.

Next, the conductive layer 115 is formed to include the region positioned in the opening portion 121 and to include a region facing the semiconductor layer 113 with the insulating layer 105 sandwiched therebetween (FIG. 16A, FIG. 16B, and FIG. 16C). For example, a conductive film to be the conductive layer 115 is formed over the insulating layer 105 and processed, so that the conductive layer 115 can be formed. For the conductive film to be the conductive layer 115, any of the above-described conductive materials that can be used for the conductive layer 115 can be appropriately used.

The conductive film to be the conductive layer 115 can be formed by using a film formation method such as a sputtering method, a CVD method, an MBE method, a PLD method, or an ALD method as appropriate. Here, the conductive film is preferably formed in contact with the insulating layer 105 provided in the opening portion 121 with a high aspect ratio. Thus, the conductive film to be the conductive layer 115 is preferably formed by a film formation method enabling favorable coverage or a good filling property, and is further preferably formed by a CVD method, an ALD method, or the like.

In the case where the conductive film to be the conductive layer 115 is formed by a CVD method, the top surface of the conductive film sometimes has high average surface roughness. In that case, the conductive film may be planarized by a CMP method, for example. At this time, before the planarization treatment, a silicon oxide film or a silicon oxynitride film may be formed over the conductive film to be the conductive layer 115 and the planarization treatment may be performed until the silicon oxide film or the silicon oxynitride film is removed.

After the conductive film to be the conductive layer 115 is formed, a pattern is formed by a lithography method, for example, and the conductive film is processed by a dry etching method, a wet etching method, or the like using the pattern, whereby the conductive layer 115 can be formed. Here, for fine processing, the conductive film is preferably processed by a dry etching method.

The side end portion of the conductive layer 115 is preferably positioned inward from the side end portion of the semiconductor layer 113 as illustrated in FIG. 16A and FIG. 16C. In that case, parasitic capacitance formed by the conductive layer 112, the insulating layer 105, and the conductive layer 115 can be low as described above, for example.

In the above-described manner, the transistor 100 including the conductive layer 111, the conductive layer 112, the semiconductor layer 113, the insulating layer 105, the conductive layer 115, and the conductive layer 117 can be formed. As described above, the conductive layer 111 functions as the one of the source electrode and the drain electrode of the transistor 100, the conductive layer 112 functions as the other of the source electrode and the drain electrode of the transistor 100, the insulating layer 105 functions as the first gate insulating layer of the transistor 100, and the conductive layer 115 functions as the first gate electrode of the transistor 100. The conductive layer 117 functions as the second gate electrode of the transistor 100, and the oxide region 117ox functions as the second gate insulating layer of the transistor 100. Specifically, a region of the conductive layer 117 other than the oxide region 117ox functions as the second gate electrode of the transistor 100, and the oxide region 117ox of the conductive layer 117 functions as the second gate insulating layer of the transistor 100.

Next, the insulating layer 107 is formed to cover the transistor 100. Specifically, the insulating layer 107 is formed to cover the conductive layer 115 and the insulating layer 105 (FIG. 2A1, FIG. 2B, and FIG. 2C). Any of the above-described insulating materials can be appropriately used for the insulating layer 107. The insulating layer 107 can be formed by using a film formation method such as a sputtering method, a CVD method, an MBE method, a PLD method, or an ALD method as appropriate.

Through the above process, the semiconductor device including the transistor 100 illustrated in FIG. 2A1, FIG. 2B, and FIG. 2C can be manufactured.

### Manufacturing Method Example 2 of Semiconductor Device

As a method for manufacturing a semiconductor device of one embodiment of the present invention, an example of a method for manufacturing the semiconductor device illustrated in FIG. 4A to FIG. 4C is described below.

First, steps similar to the steps illustrated in FIG. 13A to FIG. 13C are performed.

Here, the conductive layer 111 can be formed by forming a conductive film to be the conductive layer 111a and a conductive film to be the conductive layer 111b over the conductive film and processing these conductive films. For the conductive film to be the conductive layer 111a, any of the above-described conductive materials that can be used for the conductive layer 111a can be used as appropriate. For the conductive film to be the conductive layer 111b, any of the above-described conductive materials that can be used for the conductive layer 111b can be used as appropriate.

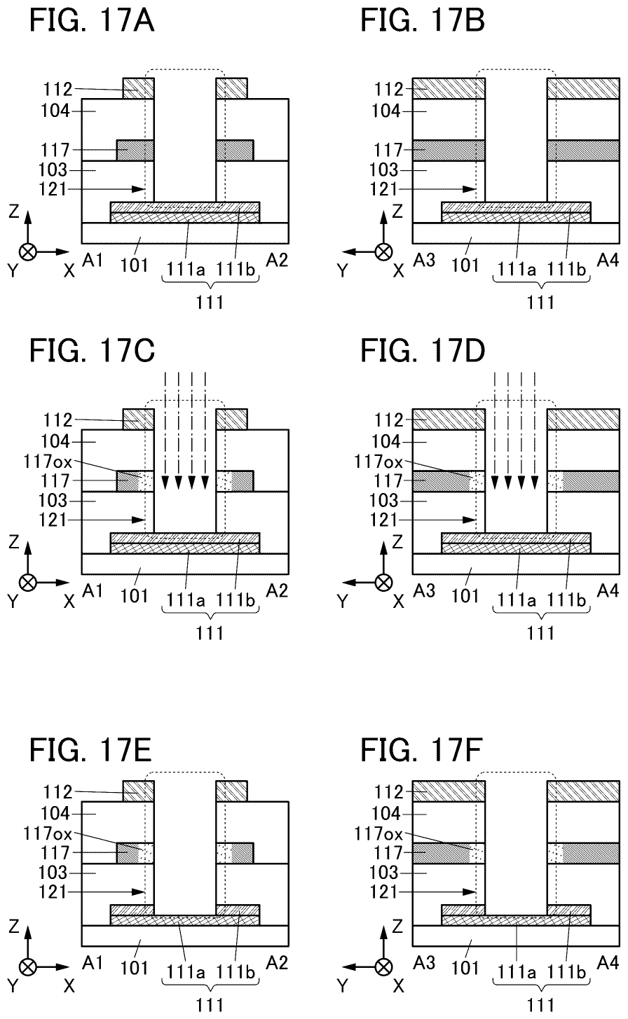

Next, part of the conductive layer 112, part of the insulating layer 104, part of the conductive layer 117, and part of the insulating layer 103 are processed to form the opening portion 121 reaching the conductive layer 111b (FIG. 17A and FIG. 17B). Note that FIG. 14A can be referred to for the plan view. FIG. 17A corresponds to a cross section along the dashed-dotted line A1-A2 in FIG. 14A. FIG. 17B corresponds to a cross section along the dashed-dotted line A3-A4 in FIG. 14A. The opening portion 121 can be formed by a method similar to that illustrated in FIG. 14A to FIG. 14C.

Next, oxidation treatment is performed on the side surface of the conductive layer 117 in the opening portion 121, so that the oxide region 117ox is formed in the conductive layer 117 (FIG. 17C and FIG. 17D). Note that FIG. 15A1 and FIG. 15A2 can be referred to for the plan views. FIG. 17C corresponds to a cross section along the dashed-dotted line A1-A2 in FIG. 15A1, and FIG. 17D corresponds to a cross section along the dashed-dotted line A3-A4 in FIG. 15A1. The oxidation treatment can be performed by a method similar to that illustrated in FIG. 15A1, FIG. 15A2, FIG. 15B, and FIG. 15C.

Next, a region of the conductive layer 111b that overlaps with the opening portion 121 is removed. This allows the opening portion 121 to reach the conductive layer 111a (FIG. 17E and FIG. 17F). Note that FIG. 15A1 and FIG. 15A2 can be referred to for the plan views. FIG. 17E corresponds to a cross section along the dashed-dotted line A1-A2 in FIG. 15A1. FIG. 17F corresponds to a cross section along the dashed-dotted line A3-A4 in FIG. 15A1. The opening portion 121 sometimes does not reach the conductive layer 111a, in which case a depressed portion including a region overlapping with the opening portion 121 is formed in the conductive layer 111b.

The conductive layer 111b can be partly removed by being processed by a dry etching method or a wet etching method, for example. Here, the conductive layer 111b is preferably processed under conditions where the etching selectivity between the conductive layer 111a and the conductive layer 111b is high, that is, conditions where the conductive layer 111b is easily etched and the conductive layer 111a is not easily etched. Note that in the case where the conductive layer 111b is processed under conditions where the etching selectivity between the conductive layer 111a and the conductive layer 111b is low, a depressed portion including a region overlapping with the opening portion 121 is sometimes formed in the conductive layer 111a. Furthermore, the conductive layer 111b is preferably processed under conditions where the etching selectivity between the conductive layer 111b and the conductive layer 112 is high, that is, conditions where the conductive layer 111b is easily etched and the conductive layer 112 is not easily etched. In that case, a pattern is not necessarily formed.

Even when the conductive layer 111b is oxidized by the above oxidation treatment, at least part of the oxidized region can be removed by performing the steps illustrated in FIG. 17E and FIG. 17F. This can reduce the electric resistance at the contact interface between the conductive layer 111 and the semiconductor layer 113 as described above. It is thus possible to inhibit the absence of current flow and a reduction in current flow in the semiconductor layer 113 between the conductive layer 111 and the conductive layer 112 in the transistor 100 that is in an on state, for example. Therefore, the semiconductor device can have high reliability. It is also possible to use a material with low oxidation resistance and high conductivity for the conductive layer 111, expanding the range of choices for the material of the conductive layer 111. As described above, for example, a conductive material with high conductivity can be used for one of the conductive layer 111a and the conductive layer 111b, and a conductive material containing oxygen can be used for the other of the conductive layer 111a and the conductive layer 111b. Note that also in the case where the conductive layer 111 is a single layer, for example, at least part of the oxidized region of the conductive layer 111 may be removed by a dry etching method or a wet etching method, for example, after the above oxidation treatment. In that case, a depressed portion including a region overlapping with the opening portion 121 is formed in the conductive layer 111.

Next, steps similar to the steps illustrated in FIG. 16A to FIG. 16C and the subsequent steps are performed. Through the above process, the semiconductor device including the transistor 100 illustrated in FIG. 4A to FIG. 4C can be manufactured.

### Manufacturing Method Example 3 of Semiconductor Device

A manufacturing method example different from the method for manufacturing the semiconductor device illustrated in FIG. 13A to FIG. 16C is described below.

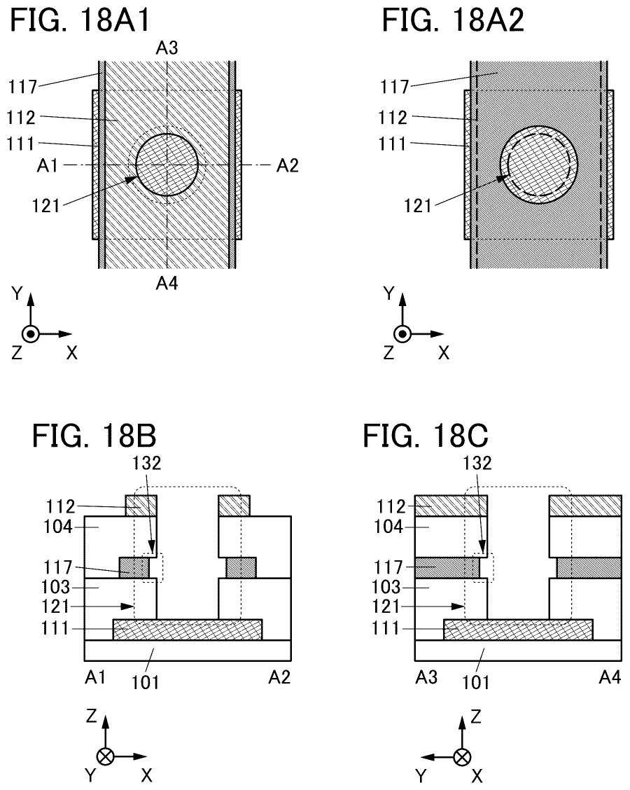

First, steps similar to the steps illustrated in FIG. 13A to FIG. 14C are performed. Then, the side surface of the conductive layer 117 in the opening portion 121 is processed to be recessed (FIG. 18A1, FIG. 18A2, FIG. 18B, and FIG. 18C). Thus, a depressed portion 132 is formed by the insulating layer 103, the insulating layer 104, and the conductive layer 117. The processing of the side surface can be performed by isotropic etching, for example. Here, the conductive layer 117 is preferably processed under conditions where the etching selectivity between the conductive layer 117 and the insulating layer 103, the insulating layer 104, the conductive layer 111, and the conductive layer 112 is high, that is, conditions where the conductive layer 117 is easily etched and the insulating layer 103, the insulating layer 104, the conductive layer 111, and the conductive layer 112 are not easily etched.

The step illustrated in FIG. 18A1, FIG. 18A2, FIG. 18B, and FIG. 18C can be regarded as a step of processing the conductive layer 117 in the horizontal direction (the direction perpendicular to the Z direction) to recess the side surface of the conductive layer 117 in the opening portion 121. Note that in FIG. 18A2, the conductive layer 112 illustrated in FIG. 18A1 is denoted by a dashed line without being hatched.

As described above, when the oxide region 117ox is formed by oxidation of the conductive layer 117, the volume of the conductive layer 117 including the oxide region 117ox sometimes increases. In that case, as illustrated in FIG. 9C and FIG. 9D, the oxide region 117ox may include a protruding region in the opening portion 121. The protruding region might prevent the semiconductor layer 113 from being in contact with the conductive layer 111, for example. In view of this, recessing the side surface of the conductive layer 117 in the opening portion 121 can inhibit the oxide region 117ox from including the protruding region in the opening portion 121. This can inhibit the semiconductor layer 113 from failing to be in contact with the conductive layer 111, for example. Thus, the method for manufacturing the semiconductor device can achieve high yield. In addition, the semiconductor device can be highly reliable.

After the side surface of the conductive layer 117 in the opening portion 121 is recessed, steps similar to the steps illustrated in FIG. 15A to FIG. 16C and the subsequent steps are performed. Through the above process, the semiconductor device including the transistor 100 illustrated in FIG. 2A1, FIG. 2B, and FIG. 2C can be manufactured. Note that in the case where the width of the recess of the conductive layer 117 in the opening portion 121 is large, as illustrated in FIG. 9A and FIG. 9B, the side surface of the oxide region 117ox may be positioned closer to the side surface of the conductive layer 111 than the side surfaces of the insulating layer 103 and the insulating layer 104 are, for example, in the opening portion 121.

### Manufacturing Method Example 4 of Semiconductor Device

As a method for manufacturing a semiconductor device of one embodiment of the present invention, an example of a method for manufacturing the semiconductor device illustrated in FIG. 6A and FIG. 6B is described below.

First, steps similar to the steps illustrated in FIG. 13A to FIG. 14C are performed. Here, the insulating layer 103 can be formed in the following manner: the insulating layer 103a and the insulating layer 103b over the insulating layer 103a are formed, the insulating layer 103b is planarized, and then, the insulating layer 103c is formed over the insulating layer 103b. The insulating layer 104 can be formed in the following manner: the insulating layer 104a and the insulating layer 104b over the insulating layer 104a are formed, the insulating layer 104b is planarized, and then, the insulating layer 104c is formed over the insulating layer 104b. The planarization can be performed by CMP treatment, for example.

Any of the above-described insulating materials can be used as appropriate for the insulating layer 103a, the insulating layer 103b, the insulating layer 103c, the insulating layer 104a, the insulating layer 104b, and the insulating layer 104c. For example, the insulating layer 103a, the insulating layer 103c, the insulating layer 104a, and the insulating layer 104c can be formed using an insulator containing nitrogen. The insulating layer 103b and the insulating layer 104b can be formed using an insulator containing oxygen.

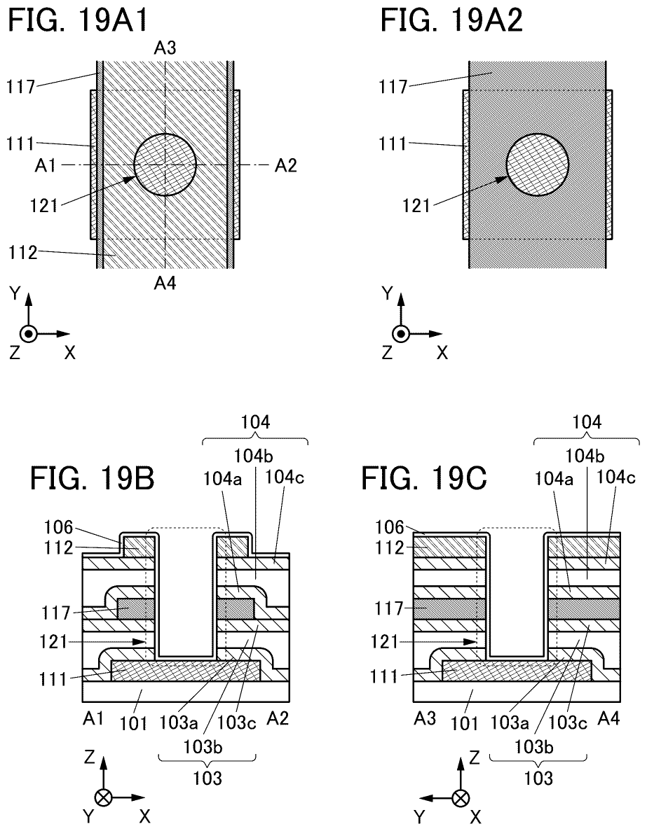

Next, the insulating layer 106 is formed over the conductive layer 111, the conductive layer 112, and the insulating layer 104c (FIG. 19A1, FIG. 19B, and FIG. 19C). Here, FIG. 19A2 is a plan view obtained by omitting the conductive layer 112 from FIG. 19A1. The insulating layer 106 is formed to include at least a region in contact with the side surface of the conductive layer 117 in the opening portion 121. The insulating layer 106 can be formed to include a region in contact with at least part of the top surface of the conductive layer 111, a region in contact with at least part of the side surface of the insulating layer 103, and a region in contact with at least part of the side surface of the insulating layer 104 in the opening portion 121. Furthermore, the insulating layer 106 can be formed to include a region in contact with at least part of the side surface of the conductive layer 112, a region in contact with at least part of the top surface of the conductive layer 112, and a region in contact with at least part of the top surface of the insulating layer 104c.

The insulating layer 106 can be formed using a material that can be used for the insulating layer 105, e.g., an insulator containing oxygen. For example, the insulating layer 106 can be formed using silicon oxide. The insulating layer 106 can be formed by a method similar to a method that can be used for forming the insulating layer 105. For example, an ALD method or a CVD method can be used for the insulating layer 106.

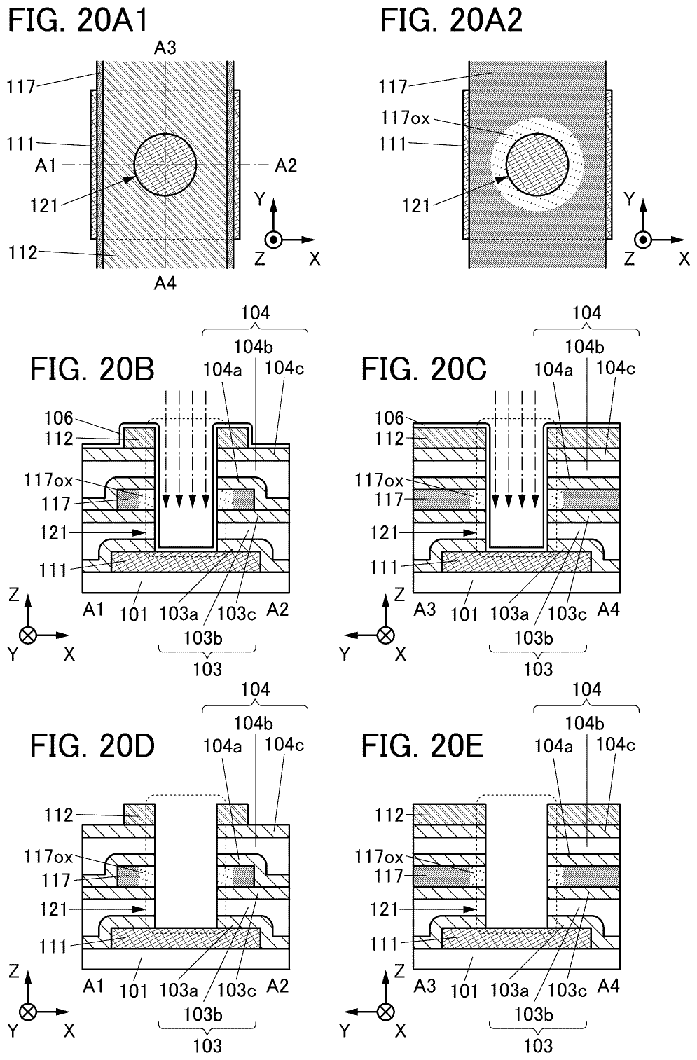

Next, oxidation treatment is performed on the side surface of the conductive layer 117 in the opening portion 121, so that the oxide region 117ox is formed in the conductive layer 117 (FIG. 20A1, FIG. 20B, and FIG. 20C). Here, FIG. 20A2 is a plan view obtained by omitting the conductive layer 112 from FIG. 20A1. The oxidation treatment can be performed by a method similar to that illustrated in FIG. 15A1, FIG. 15A2, FIG. 15B, and FIG. 15C. The oxidation treatment can be performed by microwave treatment in an atmosphere containing oxygen, for example.

The above oxidation treatment that is performed after the insulating layer 106 is formed to include a region in contact with the conductive layer 117 makes the oxide region 117ox include a component included in the conductive layer 117 and a component included in the insulating layer 106 and enables alloying of the conductive layer 117 and the insulating layer 106. In this case, the oxide region 117ox can be referred to as an alloyed region. For example, in the case where the conductive layer 117 is formed using tantalum nitride and the insulating layer 106 is formed using silicon oxide, the oxide region 117ox can include tantalum, silicon, oxygen, and nitrogen. In the case where the conductive layer 117 is formed using tungsten and the insulating layer 106 is formed using silicon oxide, the oxide region 117ox can include tungsten, silicon, and oxygen.

Here, the thickness of the insulating layer 106 is preferably small, in which case the conductive layer 117 is more easily oxidized and the oxide region 117ox can be more easily formed than in the case where the thickness of the insulating layer 106 is large. The thickness of the insulating layer 106 is preferably greater than or equal to 0.1 nm and less than or equal to 15 nm, further preferably greater than or equal to 0.1 nm and less than or equal to 10 nm, still further preferably greater than or equal to 0.1 nm and less than or equal to 5 nm, typically 1 nm. The thickness of the insulating layer 106 is preferably smaller than or equal to the thickness of the insulating layer 105 formed in a later step. At least part of the region of the insulating layer 106 that is in contact with the conductive layer 117 preferably includes a region having the above-described thickness.

Next, the insulating layer 106 is removed (FIG. 20D and FIG. 20E). FIG. 20D is a cross-sectional view taken along the dashed-dotted line A1-A2 in FIG. 20A1, and FIG. 20E is a cross-sectional view taken along the dashed-dotted line A3-A4 in FIG. 20A1. The insulating layer 106 can be removed by a dry etching method or a wet etching method, for example. Here, in the case where the insulating layer 106 is formed to include the region in contact with the top surface of the insulating layer 104c, the material included in the insulating layer 106 is preferably different from the material included in the insulating layer 104c. Furthermore, the insulating layer 106 is preferably removed under conditions where the etching selectivity between the insulating layer 104c and the insulating layer 106 is high, that is, conditions where the insulating layer 106 is easily etched and the insulating layer 104c is not easily etched. In that case, the insulating layer 104 can be inhibited from being processed at the time of removing the insulating layer 106. Note that the insulating layer 106 is removed in the manufacturing process of the semiconductor device and can thus be regarded to as a sacrificial layer.

Next, steps similar to the steps illustrated in FIG. 16A to FIG. 16C and the subsequent steps are performed. Through the above process, the semiconductor device including the transistor 100 illustrated in FIG. 6A and FIG. 6B can be manufactured. Note that part of the insulating layer 106 remains in the semiconductor device in some cases. For example, part of the insulating layer 106 remains on the sidewall of the opening portion 121 in some cases. At least part of the boundary between the sidewall of the opening portion 121 and the insulating layer 106 cannot be observed in some cases.

When the planarization treatment for the insulating layer 103b and the insulating layer 104b is performed for a longer time than that in the case of manufacturing the structure illustrated in FIG. 6A and FIG. 6B, for example, the structure illustrated in FIG. 6C and FIG. 6D can be manufactured. Note that in the cases of manufacturing the semiconductor devices having the structures illustrated in FIG. 6A to FIG. 6D, the oxide region 117ox may be formed in the conductive layer 117 without formation of the insulating layer 106. In the case of manufacturing a semiconductor device other than the semiconductor devices having the structures illustrated in FIG. 6A to FIG. 6D, the insulating layer 106 may be formed, the oxide region 117ox may be formed in the conductive layer 117, and then, the insulating layer 106 may be removed.

### Manufacturing Method Example 5 of Semiconductor Device

A manufacturing method example different from the method for manufacturing the semiconductor device illustrated in FIG. 13A to FIG. 16C is described below.

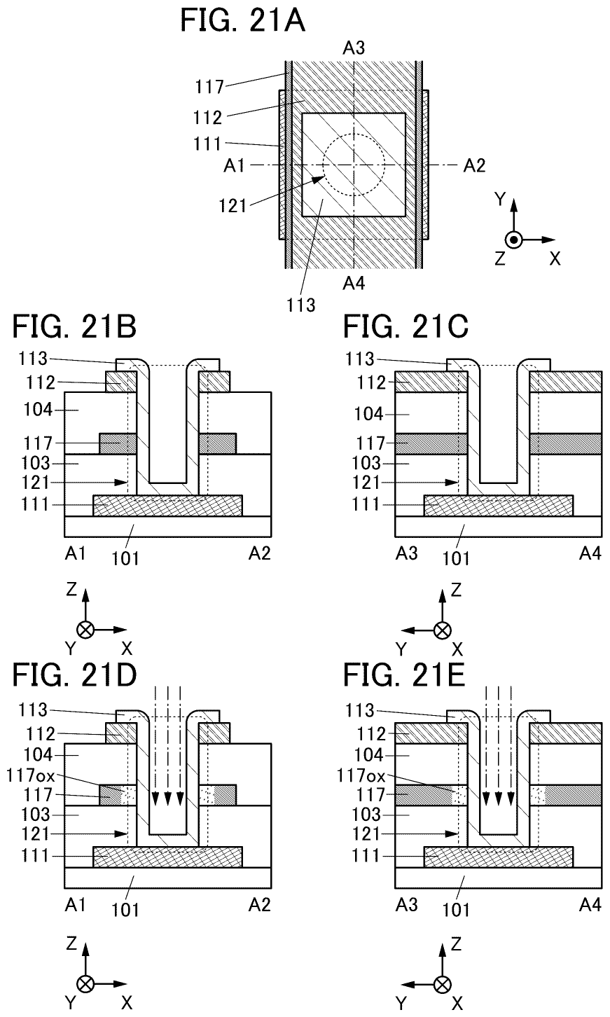

First, steps similar to the steps illustrated in FIG. 13A to FIG. 14C are performed. Next, the semiconductor layer 113 is formed by a method similar to that illustrated in FIG. 16A to FIG. 16C (FIG. 21A, FIG. 21B, and FIG. 21C). After that, oxidation treatment is performed on the side surface of the conductive layer 117 in the opening portion 121, so that the oxide region 117ox is formed in the conductive layer 117 (FIG. 21D and FIG. 21E). FIG. 21D is a cross-sectional view taken along the dashed-dotted line A1-A2 in FIG. 21A, and FIG. 21E is a cross-sectional view taken along the dashed-dotted line A3-A4 in FIG. 21A.

As in the example illustrated in FIG. 15B and FIG. 15C, the oxidation treatment can be performed by microwave treatment in an atmosphere containing oxygen, for example. Here, in the example illustrated in FIG. 21D and FIG. 21E, impurity removal treatment for the semiconductor layer 113 can be performed in parallel with the oxidation treatment for the conductive layer 117. Heat treatment is preferably performed after the oxidation treatment for the conductive layer 117. For the details of the oxidation treatment and the heat treatment, the above description can be referred to.

Next, the insulating layer 105 and the conductive layer 115 are formed by methods similar to those illustrated in FIG. 16A to FIG. 16C, so that the transistor 100 is formed. After that, the insulating layer 107 is formed to cover the transistor 100. Through the above process, the semiconductor device including the transistor 100 illustrated in FIG. 2A1, FIG. 2B, and FIG. 2C can be manufactured.

As described above, in the method for manufacturing the semiconductor device of one embodiment of the present invention, the transistor is formed such that the semiconductor layer, the first gate insulating layer, and the first gate electrode are provided in the opening portion formed in the first interlayer insulating layer and the second interlayer insulating layer over the first insulating layer. The transistor is formed such that the one of the source electrode and the drain electrode is provided under the opening portion and the other of the source electrode and the drain electrode is provided over the second interlayer insulating layer. The second gate electrode provided with the opening portion is formed between the first interlayer insulating layer and the second interlayer insulating layer, the side surface of the second gate electrode in the opening portion is oxidized, and the oxide region is used as the second gate insulating layer. In the above manner, the transistor whose channel length is short and whose threshold voltage can be controlled can be manufactured. Accordingly, one embodiment of the present invention can provide a method for manufacturing a semiconductor device that is driven at high speed and has favorable electrical characteristics, for example.

### Structure Example of Storage Device

Examples where the semiconductor device of one embodiment of the present invention is used in a storage device will be described below.

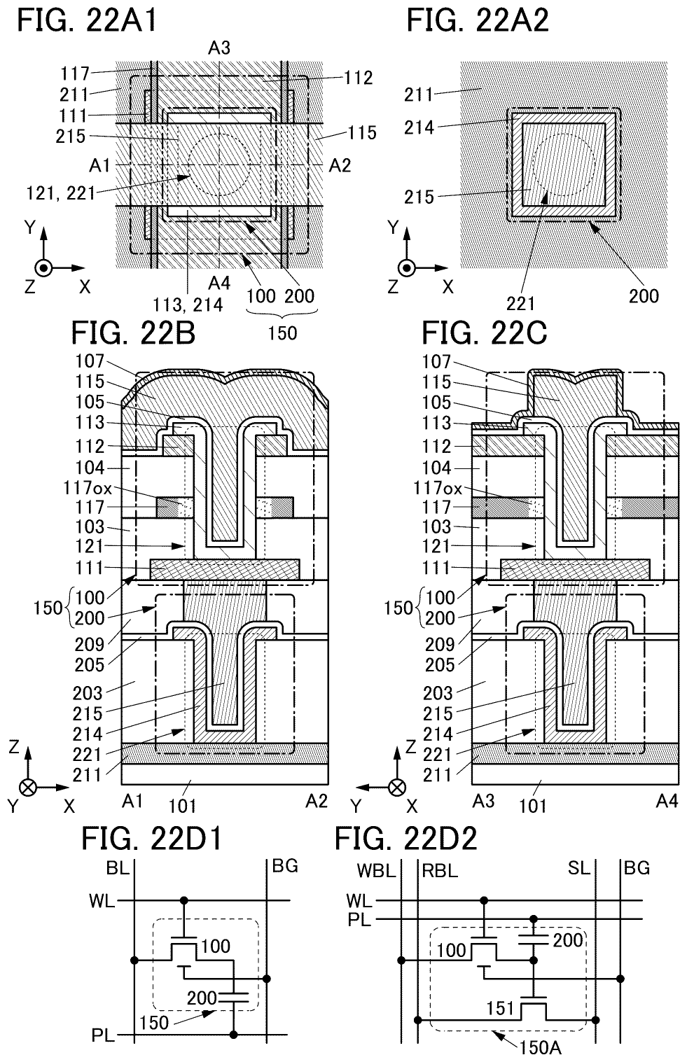

FIG. 22A1 is a plan view illustrating a structure example of a storage device of one embodiment of the present invention. The storage device of one embodiment of the present invention includes a memory cell 150 including the transistor 100 and a capacitor 200. FIG. 22A2 is a plan view obtained by omitting the components of the transistor 100 from FIG. 22A1 and illustrates a structure example of the capacitor 200. FIG. 22B is a cross-sectional view taken along the dashed-dotted line A1-A2 in FIG. 22A1, and FIG. 22C is a cross-sectional view taken along the dashed-dotted line A3-A4 in FIG. 22A1.

The storage device illustrated in FIG. 22A1, FIG. 22B, and FIG. 22C includes a conductive layer 211 and the capacitor 200 over the conductive layer 211, between the insulating layer 101 and each of the insulating layer 103 and the conductive layer 111. The storage device includes an insulating layer 203 over the conductive layer 211 and an insulating layer 209 over the insulating layer 203. Here, the conductive layer 211 can be provided to have a planar shape. The insulating layer 203 and the insulating layer 209 function as interlayer insulating layers.

The insulating layer 203 has an opening portion 221 reaching the conductive layer 211. FIG. 22A1 and FIG. 22A2 show an example in which the opening portion 221 is circular in a plan view. When the plan-view shape of the opening portion 221 is circular, the opening portion 221 can be formed with high processing accuracy and the opening portion 221 having a minute size can be formed. Note that the plan-view shape of the opening portion 221 is not limited to a circular shape and can be a shape similar to the shape that the opening portion 121 can have.

The capacitor 200 includes a conductive layer 214, an insulating layer 205, and a conductive layer 215. The conductive layer 214 and the conductive layer 215 function as a pair of electrodes of the capacitor 200, and the insulating layer 205 functions as a dielectric layer of the capacitor 200. The capacitor 200 can form a MIM (Metal-Insulator-Metal) capacitor.

The conductive layer 214 is provided to cover the opening portion 221 and to include a region positioned in the opening portion 221. The conductive layer 214 can have a shape along the top surface of the conductive layer 211 and a side surface and the top surface of the insulating layer 203. Thus, the conductive layer 214 has a depressed portion in a position overlapping with the opening portion 221. The conductive layer 214 can include a region in contact with the top surface of the conductive layer 211, a region in contact with the side surface of the insulating layer 203, and a region in contact with the top surface of the insulating layer 203.

The insulating layer 205 is provided to cover the opening portion 221 and to include a region positioned in the opening portion 221. The insulating layer 205 is provided over the conductive layer 214 and the insulating layer 203. The insulating layer 205 can have a shape along the shapes of the top surface and a side surface of the conductive layer 214 and the top surface of the insulating layer 203. Since the insulating layer 205 has the shape along the top surface and the side surface of the conductive layer 214, the insulating layer 205 has a depressed portion in a position overlapping with the opening portion 221. The insulating layer 205 can include a region in contact with the top surface of the conductive layer 214, a region in contact with the side surface of the conductive layer 214, and a region in contact with the top surface of the insulating layer 203.

The conductive layer 215 is provided over the insulating layer 205 and can include a region in contact with the top surface of the insulating layer 205 and a side surface of the depressed portion of the insulating layer 205. The conductive layer 215 includes a region positioned in the opening portion 221. The conductive layer 215 and the conductive layer 214 face each other with the insulating layer 205 sandwiched therebetween in a position along not only the bottom portion of the opening portion 221 but also the sidewall thereof. Thus, the deeper the opening portion 221 is, the larger the capacitance value per unit area of the capacitor 200 can be. Accordingly, the reading operation of the storage device can be performed stably, and the storage device can be highly reliable. The capacitance value can be ensured even when the capacitor 200 has a small footprint; thus, the storage device can be miniaturized and highly integrated. Accordingly, the storage device can be small and have high capacity. Here, the conductive layer 214 can cover a side surface and the bottom surface of the conductive layer 215 with the insulating layer 205 therebetween in the opening portion 221. For example, in the opening portion 221, the insulating layer 205 can include the region in contact with the side surface of the conductive layer 214, a region in contact with the top surface of the depressed portion of the conductive layer 214, a region in contact with the side surface of the conductive layer 215, and a region in contact with the bottom surface of the conductive layer 215.

In the example illustrated in FIG. 22A1, FIG. 22A2, FIG. 22B, and FIG. 22C, a side end portion of the conductive layer 215 is positioned inward from a side end portion of the conductive layer 214 in both the X direction and the Y direction. Note that the side end portion of the conductive layer 215 may be positioned outward from the side end portion of the conductive layer 214 in one or both of the X direction and the Y direction.

In the capacitor 200, the conductive layer 214 and the insulating layer 205 are stacked along the side surface of the insulating layer 203 and the top surface of the conductive layer 211, and the conductive layer 215 is provided over the insulating layer 205 to fill the opening portion 221. A capacitor with such a structure can be referred to as a trench-type capacitor or a trench capacitor.

The sidewall of the opening portion 221 is preferably perpendicular to the top surface of the conductive layer 211. In that case, the opening portion 221 has a cylindrical shape, for example. When such a structure is employed, the storage device can be miniaturized and highly integrated. Note that the sidewall of the opening portion 221 may have a tapered shape like the sidewall of the opening portion 121 illustrated in FIG. 5A to FIG. 5D, for example.

The insulating layer 209 covers a side surface of the conductive layer 215 outside the opening portion 221. The insulating layer 209 includes a region in contact with the side surface of the conductive layer 215 outside the opening portion 221, for example. The insulating layer 209 and the conductive layer 215 are planarized, so that the top surface of the insulating layer 209 and the top surface of the conductive layer 215 can be level or substantially level with each other. Although the insulating layer 205 is provided to have a planar shape in the example shown in FIG. 22B and FIG. 22C, a side end portion of the insulating layer 205 and the side end portion of the conductive layer 215 may be aligned or substantially aligned with each other. For example, when the insulating layer 205 is processed with the same pattern as the conductive layer 215, the side end portion of the insulating layer 205 and the side end portion of the conductive layer 215 can be aligned or substantially aligned with each other.

To form the capacitor 200 illustrated in FIG. 22A1, FIG. 22A2, FIG. 22B, and FIG. 22C, a conductive film to be the conductive layer 215 is formed over the insulating layer 205 after the conductive layer 214 and the insulating layer 205 are formed. Then, a pattern is formed by a lithography method, for example, and the conductive film is processed by a dry etching method, a wet etching method, or the like using the pattern, whereby the conductive layer 215 is formed. After that, the insulating layer 209 is formed over the conductive layer 215 and the insulating layer 205, and planarization treatment is performed on the insulating layer 209 by a CMP method, for example, to expose the top surface of the conductive layer 215. At this time, the top surface of the conductive layer 215 is preferably also planarized to facilitate formation of the transistor 100 over the capacitor 200, for example. The above is an example of a method for manufacturing the capacitor 200.

Components of the storage device of one embodiment of the present invention will be described below.

As the conductive layer 211, a single layer or stacked layers of any of the conductors described in the above-described section [Conductor] can be used. The conductive layer 211 can be formed using a conductive material with high conductivity, e.g., tungsten.

A single layer or stacked layers of a conductive material that is less likely to be oxidized, a conductive material having a function of inhibiting diffusion of oxygen, or the like can be used as the conductive layer 211. For example, titanium nitride, indium tin oxide to which silicon is added, or the like may be used. Alternatively, a structure in which titanium nitride is stacked over tungsten may be used. Further alternatively, a structure in which tungsten is stacked over first titanium nitride and second titanium nitride is stacked over the tungsten may be used. With such a structure, the conductive layer 211 can be inhibited from being oxidized by the insulating layer 203 in the case of using an oxide insulator for the insulating layer 203.

The insulating layer 203 and the insulating layer 209 function as the interlayer insulating layers and thus preferably have a low relative permittivity. The use of a material having a low relative permittivity for the interlayer insulating layers can reduce the parasitic capacitance generated between wirings. As each of the insulating layer 203 and the insulating layer 209, a single layer or stacked layers of any of the insulators each including a material with a low relative permittivity and described in the above-described section [Insulator] can be used. In particular, silicon oxide and silicon oxynitride are preferable because they are thermally stable.

As each of the conductive layer 214 and the conductive layer 215, a single layer or stacked layers of any of the conductors described in the above-described section [Conductor] can be used. A conductive material that is less likely to be oxidized, a conductive material having a function of inhibiting diffusion of oxygen, or the like is preferably used for each of the conductive layer 214 and the conductive layer 215. For example, titanium nitride, tantalum nitride, or the like can be used. Alternatively, a structure in which tantalum nitride is stacked over titanium nitride may be used. With such a structure, the conductive layer 214 and the conductive layer 215 can be inhibited from being oxidized by the insulating layer 205 in the case of using an oxide insulator for the insulating layer 205. Furthermore, the conductive layer 214 can be inhibited from being oxidized by the insulating layer 203 in the case of using an oxide insulator for the insulating layer 203. The conductive layer 215 can be inhibited from being oxidized by the insulating layer 209 in the case of using an oxide insulator for the insulating layer 209.

For the insulating layer 205, any of the materials with a high relative permittivity, that is, high-k materials, described in the above-described section [Insulator] is preferably used. Using a high-k material for the insulating layer 205 allows the insulating layer 205 to be thick enough to inhibit a leakage current and the capacitor 200 to have a sufficiently large capacitance value.

It is preferable for the insulating layer 205 to include stacked insulating layers formed of any of the high-k materials, and it is preferable to use a stacked-layer structure of a high relative permittivity (high-k) material and a material having a higher dielectric strength than the high-k material. For the insulating layer 205, an insulating film in which zirconium oxide, aluminum oxide, and zirconium oxide are stacked in this order can be used, for example. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. Using stacked insulators with relatively high dielectric strength, such as aluminum oxide, as the insulating layer 205 can increase the dielectric strength of the insulating layer 205 and inhibit electrostatic breakdown of the capacitor 200.

Alternatively, a material that can have ferroelectricity may be used for the insulating layer 205. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or in the neighborhood thereof. Examples of the material that can have ferroelectricity also include a material in which an element J2 (the element 2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

FIG. 22D1 is a circuit diagram illustrating a connection relation between the transistor 100 and the capacitor 200 included in the memory cell 150 illustrated in FIG. 22A1, FIG. 22B, and FIG. 22C. One of a source and a drain of the transistor 100 is electrically connected to one electrode of the capacitor 200. The other of the source and the drain of the transistor 100 is electrically connected to a wiring BL. A first gate of the transistor 100 is electrically connected to a wiring WL. A second gate of the transistor 100 is electrically connected to a wiring BG. The other electrode of the capacitor 200 is electrically connected to a wiring PL.

The wiring BL corresponds to the conductive layer 112, the wiring WL corresponds to the conductive layer 115, the wiring BG corresponds to the conductive layer 117, and the wiring PL corresponds to the conductive layer 211. In other words, the conductive layer 112 includes a region functioning as the wiring BL, the conductive layer 115 includes a region functioning as the wiring WL, the conductive layer 117 includes a region functioning as the wiring BG, and the conductive layer 211 includes a region functioning as the wiring PL. Note that the conductive layer 214 may include a region functioning as the wiring PL.

The transistor 100 functions as a switch and has a function of controlling writing of data to the memory cell 150 and reading of data from the memory cell 150. When the transistor 100 is turned on, data is written to the memory cell 150 or data is read from the memory cell 150. When the transistor 100 is turned off, data written to the memory cell 150 is retained.

The wiring BL functions as a bit line for writing and reading data. The wiring WL functions as a word line for controlling on or off (a conduction state or a non-conduction state) of the transistor 100 functioning as the switch. The wiring PL functions as a constant potential line connected to the capacitor 200. The potential of the wiring BG is the potential of the second gate of the transistor 100.

FIG. 22D2 is a circuit diagram illustrating a structure example of a memory cell 150A obtained by adding a transistor 151 to the memory cell 150 illustrated in FIG. 22D1. In the memory cell 150A, the one of the source and the drain of the transistor 100 and the one electrode of the capacitor 200 are electrically connected to a gate of the transistor 151. The other of the source and the drain of the transistor 100 is electrically connected to a wiring WBL. One of a source and a drain of the transistor 151 is electrically connected to a wiring RBL. The other of the source and the drain of the transistor 151 is electrically connected to a wiring SL.

Although the transistor 151 does not include a second gate electrode in the example illustrated in FIG. 22D2, the transistor 151 may include not only a first gate electrode but also a second gate electrode. In that case, the second gate electrode of the transistor 151 may be supplied with a constant potential, for example, or may be supplied with a potential equal to the potential of the first gate electrode of the transistor 151. The potential of a second gate potential of the transistor 151 may be different between the case where data is read from the memory cell 150A and the other cases.

The wiring WBL functions as a bit line for writing data and is also referred to as a write bit line. The wiring RBL functions as a bit line for reading data and is also referred to as a read bit line. The wiring SL functions as a constant potential line.

In the memory cell 150A, when the transistor 100 is turned on, data is written through the wiring WBL. In the case where the transistor 151 is an n-channel transistor here, the potential of the wiring PL is a low potential. When the transistor 100 is turned off and the potential of the wiring PL is changed from the low potential to a high potential, a current corresponding to the data retained in the memory cell 150A flows from the wiring SL to the wiring RBL, and data is read from the memory cell 150A. Thus, in the memory cell 150A, a pulse signal (a signal whose potential changes in a period of performing a specific operation) is supplied to the wiring PL. Note that a pulse signal may be supplied to the wiring SL. In that case, a constant potential can be supplied to the wiring PL.

An OS transistor has an extremely low current that flows between a source and a drain in an off state, that is, an extremely low leakage current. Thus, when the transistor 100 is an OS transistor, charge corresponding to data retained in the memory cell can be retained in the capacitor 200 for a long time. This enables the memory cell to retain data for a long period. Accordingly, the storage device does not require refresh operation or has extremely low frequency of the refresh operation, which leads to a sufficient reduction in power consumption of the storage device. Since the OS transistor has high frequency characteristics, data can be written to and read from the memory cell at high speed.

The transistor 151 can be a transistor having a higher on-state current than the OS transistor, and can be a Si transistor, for example. In that case, data can be read from the memory cell 150A at high speed. An OS transistor may be used as the transistor 151. In that case, all the transistors included in the memory cell 150A can be of the same type. This allows all the transistors included in the memory cell 150A to be formed in the same process, for example.

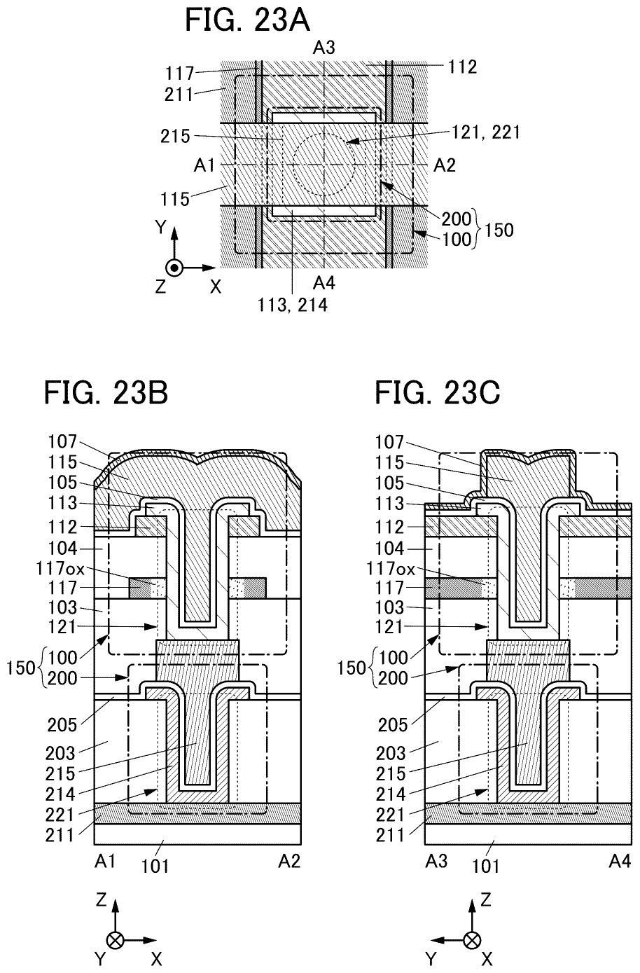

FIG. 23A, FIG. 23B, and FIG. 23C illustrate an example in which the conductive layer 111 and the insulating layer 209 illustrated in FIG. 22A1, FIG. 22B, and FIG. 22C are not provided. In the example illustrated in FIG. 23B and FIG. 23C, the opening portion 121 reaches the conductive layer 215, and the bottom surface of the semiconductor layer 113 is in contact with the conductive layer 215. In the example illustrated in FIG. 23B and FIG. 23C, the insulating layer 103 covers the side surface and part of the top surface of the conductive layer 215.

In the example illustrated in FIG. 23A to FIG. 23C, the conductive layer 215 functions as the one of the source electrode and the drain electrode of the transistor 100. In this case, the conductive layer 215 is preferably formed using a material similar to the material that can be used for the conductive layer 111. For example, the conductive layer 215 is preferably formed using a material that is less likely to be oxidized than the conductive layer 117 or a material having conductivity even after being oxidized.

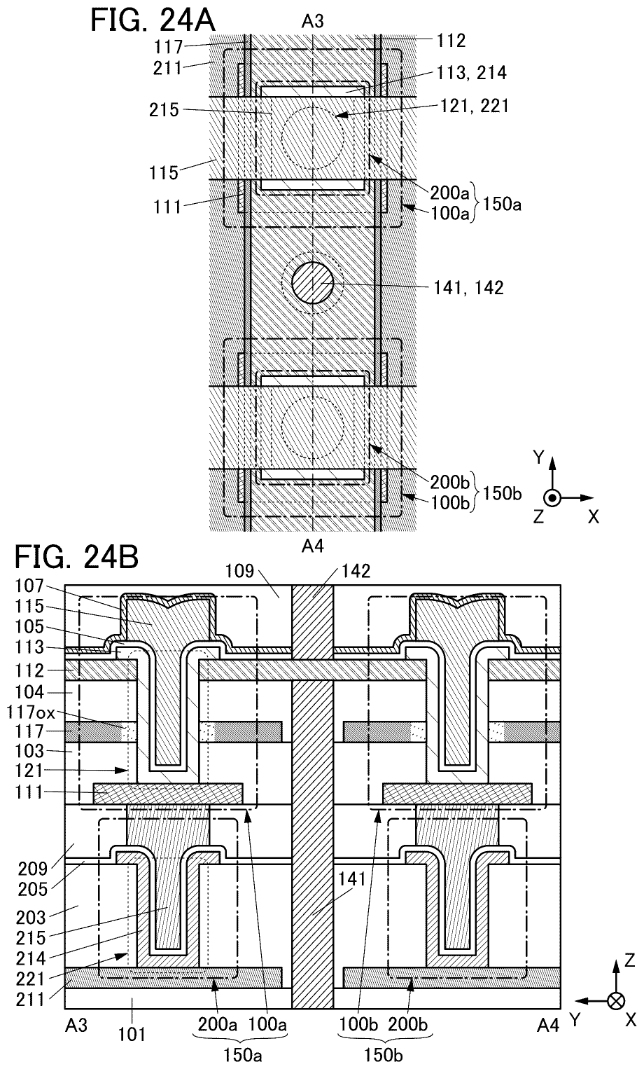

FIG. 24A is a plan view illustrating an example of a storage device in which two of the memory cells 150 (hereinafter referred to as a memory cell 150a and a memory cell 150b) are connected to one wiring. FIG. 24B is a cross-sectional view along the dashed-dotted line A3-A4 in FIG. 24A.

Here, the memory cell 150a and the memory cell 150b illustrated in FIG. 24A and FIG. 24B each have a structure similar to that of the memory cell 150. The memory cell 150a includes a capacitor 200a and a transistor 100a, and the memory cell 150b includes a capacitor 200b and a transistor 100b. Thus, in the storage device illustrated in FIG. 24A and FIG. 24B, components having the same functions as the components of the storage device illustrated in FIG. 22A1, FIG. 22B, and FIG. 22C are denoted by the same reference numerals.

As illustrated in FIG. 24A and FIG. 24B, the conductive layer 115 functioning as the wiring WL is provided in each of the memory cell 150a and the memory cell 150b. The conductive layer 112 functioning as part of the wiring BL is provided to be shared by the memory cell 150a and the memory cell 150b. That is, the conductive layer 112 includes a region in contact with the semiconductor layer 113 of the memory cell 150a and a region in contact with the semiconductor layer 113 of the memory cell 150b. An insulating layer 109 functioning as an interlayer insulating layer is provided over the insulating layer 107.

Here, the storage device illustrated in FIG. 24A and FIG. 24B includes a conductive layer 141 and a conductive layer 142 electrically connected to the memory cell 150a and the memory cell 150b and functioning as plugs (which also can be referred to as connection electrodes). The conductive layer 141 is placed in an opening portion formed in the insulating layer 101, the insulating layer 203, the insulating layer 205, the insulating layer 209, the insulating layer 103, and the insulating layer 104 and is in contact with the bottom surface of the conductive layer 112. The conductive layer 142 is placed in an opening portion formed in the insulating layer 109, the insulating layer 107, and the insulating layer 105 and is in contact with the top surface of the conductive layer 112. Note that a conductive material that can be used for the conductive layer 112, for example, can be used for the conductive layer 141 and the conductive layer 142.

The insulating layer 109 functions as the interlayer insulating layer and thus preferably has a low relative permittivity. The use of a material having a low relative permittivity for the interlayer insulating layer can reduce the parasitic capacitance generated between wirings. As the insulating layer 109, a single layer or stacked layers of any of the insulators each including a material with a low relative permittivity and described in the above-described section [Insulator] can be used.

The concentration of impurities such as water and hydrogen in the insulating layer 109 is preferably reduced. This can inhibit entry of impurities such as water and hydrogen into the channel formation region of the semiconductor layer 113.

The conductive layer 141 and the conductive layer 142 function as the plugs or wirings for electrically connecting the memory cell 150a and the memory cell 150b to circuit elements such as a switch, a transistor, a capacitor, an inductor, a resistor, and a diode, a wiring, an electrode, or a terminal. For example, the conductive layer 141 can be electrically connected to a sense amplifier (not illustrated) provided below the storage device illustrated in FIG. 24B, and the conductive layer 142 can be electrically connected to a similar storage device (not illustrated) provided above the storage device illustrated in FIG. 24B. In that case, the conductive layer 141 and the conductive layer 142 function as part of the wiring BL. When the storage device or the like is provided above or below the storage device illustrated in FIG. 24B in this manner, the memory capacity per unit area can be increased.

The memory cell 150a and the memory cell 150b are line-symmetrical to each other with a perpendicular bisector of the dashed-dotted line A3-A4 as the symmetric axis. Thus, the transistor 100a and the transistor 100b are also arranged symmetrically with the conductive layer 141 and the conductive layer 142 sandwiched therebetween. Here, the conductive layer 112 has a function of the other of a source electrode and a drain electrode of the transistor 100a and a function of the other of a source electrode and a drain electrode of the transistor 100b. The transistor 100a and the transistor 100b share the conductive layer 141 and the conductive layer 142 functioning as the plugs. Accordingly, when the two transistors are connected to the plugs as described above, the storage device can be miniaturized or highly integrated.

Note that the conductive layer 211 functioning as the wiring PL may be provided in each of the memory cell 150a and the memory cell 150b or may be provided to be shared by the memory cell 150a and the memory cell 150b. Likewise, the conductive layer 117 functioning as the wiring BG may be provided in each of the memory cell 150a and the memory cell 150b or may be provided to be shared by the memory cell 150a and the memory cell 150b. Note that as illustrated in FIG. 24B, the conductive layer 211 is provided to be apart from the conductive layer 141 to prevent a short circuit between the conductive layer 211 and the conductive layer 141. Likewise, the conductive layer 117 is provided to be apart from the conductive layer 141 to prevent a short circuit between the conductive layer 117 and the conductive layer 141.

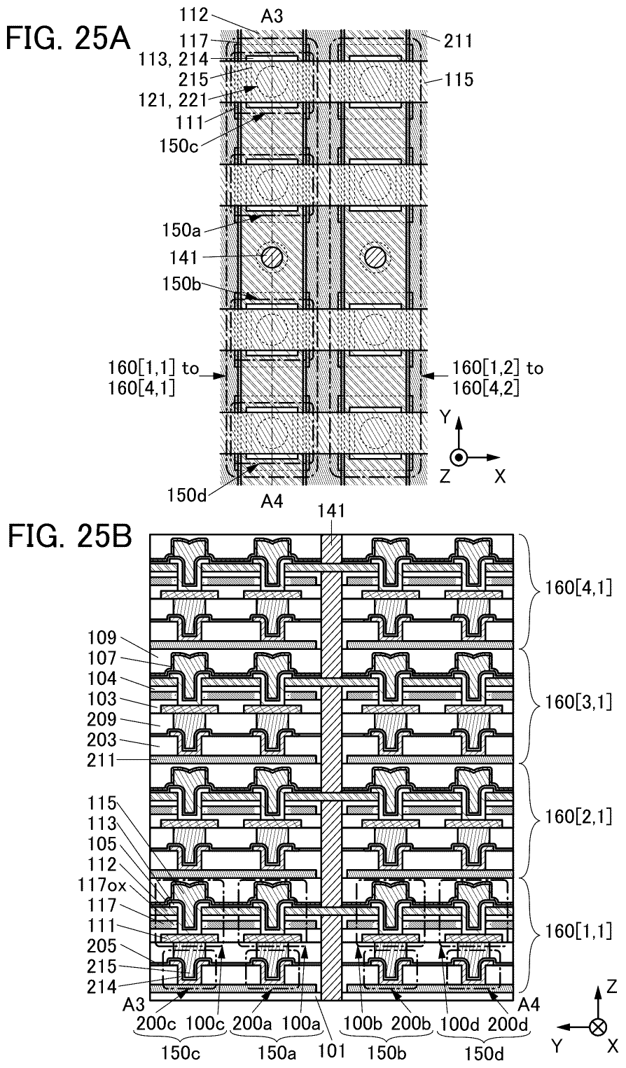

Note that the memory cells 150 can be three-dimensionally arranged in a matrix to form a memory cell array. As an example of the memory cell array, FIG. 25A and FIG. 25B illustrate an example of a storage device in which 2×4×4 of the memory cells 150 are arranged in the X direction, the Y direction, and the Z direction. FIG. 25A is a plan view illustrating a structure example of the storage device. FIG. 25B is a cross-sectional view taken along the dashed-dotted line A3-A4 in FIG. 25A.

Here, the memory cell 150a to a memory cell 150d illustrated in FIG. 25A and FIG. 25B each have a structure similar to that of the memory cell 150. The memory cell 150a includes the capacitor 200a and the transistor 100a, the memory cell 150b includes the capacitor 200b and the transistor 100b, the memory cell 150c includes a capacitor 200c and a transistor 100c, and the memory cell 150d includes a capacitor 200d and a transistor 100d. Thus, in the storage device illustrated in FIG. 25A and FIG. 25B, components having the same functions as the components of the storage device illustrated in FIG. 22A1, FIG. 22A2, FIG. 22B, and FIG. 22C are denoted by the same reference numerals.

Hereinafter, a set of a plurality of the memory cells 150 is referred to as a memory unit. The storage device illustrated in FIG. 25A and FIG. 25B is provided with a memory unit 160 including the memory cell 150a, the memory cell 150b, the memory cell 150c, and the memory cell 150d. FIG. 25A and FIG. 25B illustrate a memory unit 160[1,1] to a memory unit 160[4,2]. The memory unit 160[1, 1] to the memory unit 160[4, 1] are stacked in this order. The memory unit 160[1,2] to the memory unit 160[4,2] are stacked in this order. Furthermore, the memory unit 160[1,2] to the memory unit 160[4,2] are provided adjacent to the memory unit 160[1, 1] to the memory unit 160[4,1], respectively, in the X direction.

In the memory unit 160, with the conductive layer 141 as the center, the memory cell 150c is placed outside the memory cell 150a and the memory cell 150d is placed outside the memory cell 150b as illustrated in FIG. 25B. In other words, the storage device illustrated in FIG. 25A and FIG. 25B can be regarded as the storage device in FIG. 24A and FIG. 24B in which the memory cell 150c is provided adjacent to the memory cell 150a and the memory cell 150d is provided adjacent to the memory cell 150b.

As illustrated in FIG. 25A and FIG. 25B, the conductive layer 115 functioning as the wiring WL is shared by the memory cells 150 adjacent to each other in the X direction. The conductive layer 112 functioning as part of the wiring BL is shared in the same memory unit. That is, the conductive layer 112 includes regions that are in contact with the semiconductor layers 113 of the memory cell 150a to the memory cell 150d.

The conductive layer 141 is provided between the conductive layers 112 included in the memory units adjacent to each other in the Z direction. For example, as illustrated in FIG. 25B, the conductive layer 141 is provided in contact with the top surface of the conductive layer 112 of the memory unit 160[1,1] and the bottom surface of the conductive layer 112 of the memory unit 160[2,1]. In this manner, the conductive layer 112 and the conductive layer 141 provided in each of the memory units 160 form the wiring BL. The conductive layer 141 is electrically connected to a sense amplifier (not illustrated) provided below the storage device illustrated in FIG. 25B. As described above, when a plurality of memory units are stacked in the storage device illustrated in FIG. 25B, the memory capacity per unit area can be increased.

The memory cell 150a and the memory cell 150c are line-symmetrical to the memory cell 150b and the memory cell 150d with a perpendicular bisector of the dashed-dotted line A3-A4 as the symmetric axis. Thus, the transistor 100a and the transistor 100c are also arranged symmetrically to the transistor 100b and the transistor 100d with the conductive layer 141 sandwiched therebetween. Here, the conductive layer 112 has a function of the other of the source electrode and the drain electrode of each of the transistor 100a to the transistor 100d. The transistor 100a to the transistor 100d share the conductive layer 141 functioning as the plug. Accordingly, when the four transistors are connected to the plug as described above, the storage device can be miniaturized or highly integrated.

When the plurality of memory cells 150 are stacked as illustrated in FIG. 25B, cells can be integrated without increasing the footprint of the memory cell array. In other words, a 3D memory cell array can be formed. Although FIG. 25A and FIG. 25B illustrate the structure in which four layers each including two of the memory units 160 are stacked, one embodiment of the present invention is not limited to the structure. The storage device may include one layer including at least one memory cell 150 or may include two or more stacked layers each including at least one memory cell 150.

In the structure illustrated in FIG. 25A and FIG. 25B, the conductive layer 141 functioning as the plug is placed between the memory cells 150. In other words, the conductive layer 141 functioning as the plug is placed inside the memory unit 160. Note that one embodiment of the present invention is not limited thereto. The conductive layer 141 may be placed outside the memory unit.

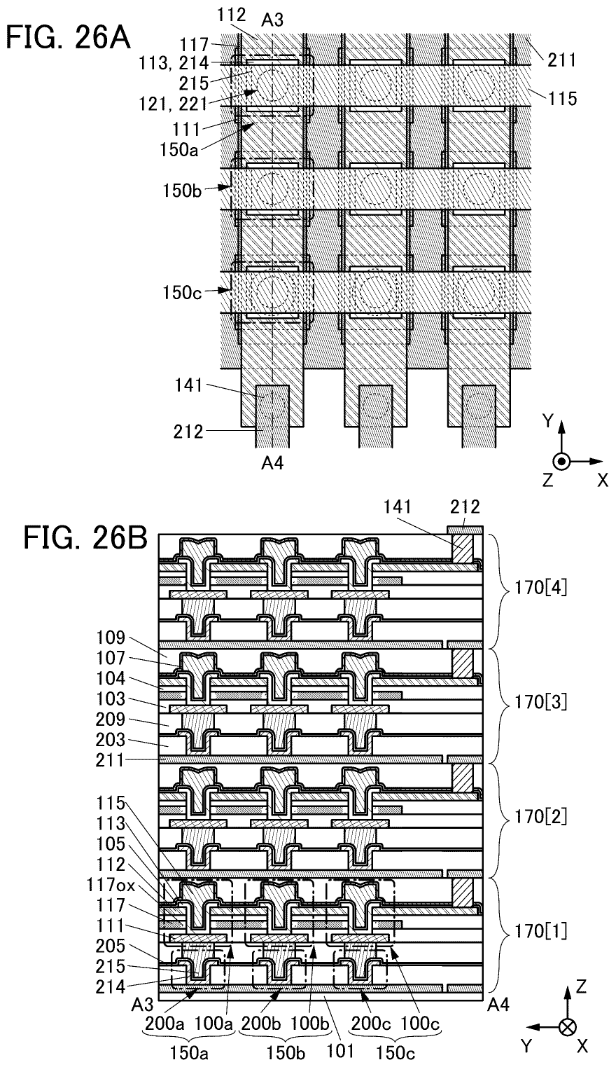

As an example of the memory cell array, FIG. 26A and FIG. 26B illustrate an example of a storage device in which 3×3×4 of the memory cells 150 are arranged in the X direction, the Y direction, and the Z direction. FIG. 26A is a plan view illustrating a structure example of the storage device. FIG. 26B is a cross-sectional view taken along the dashed-dotted line A3-A4 in FIG. 26A. In the example illustrated in FIG. 26B, the layer where the memory cell 150 is provided is a layer 170, and a layer 170[1] to a layer 170[4] are stacked in this order.

In the example illustrated in FIG. 26A and FIG. 26B, the conductive layer 141 is provided outside the region where the memory cell 150 is provided. The conductive layer 141 can be electrically connected to a conductive layer 212 provided above the layer including the conductive layer 141. For example, the conductive layer 141 provided in the layer 170[1] is electrically connected to the conductive layer 212 provided in the layer 170[2]. Note that the conductive layer 212 provided in the layer 170[2] is provided in the same layer as the conductive layer 211 included in the layer 170[2], for example. That is, the conductive layer 212 can be formed through the same steps as the conductive layer 211.

Although the conductive layer 141 is electrically connected to the conductive layer 212 provided above the layer including the conductive layer 141 in the structure illustrated in FIG. 26A and FIG. 26B, one embodiment of the present invention is not limited thereto. For example, the conductive layer 141 may be electrically connected to the conductive layer 212 provided in the layer including the conductive layer 141. For example, the conductive layer 141 provided in the layer 170[1] may be electrically connected to the conductive layer 212 provided in the layer 170[1].

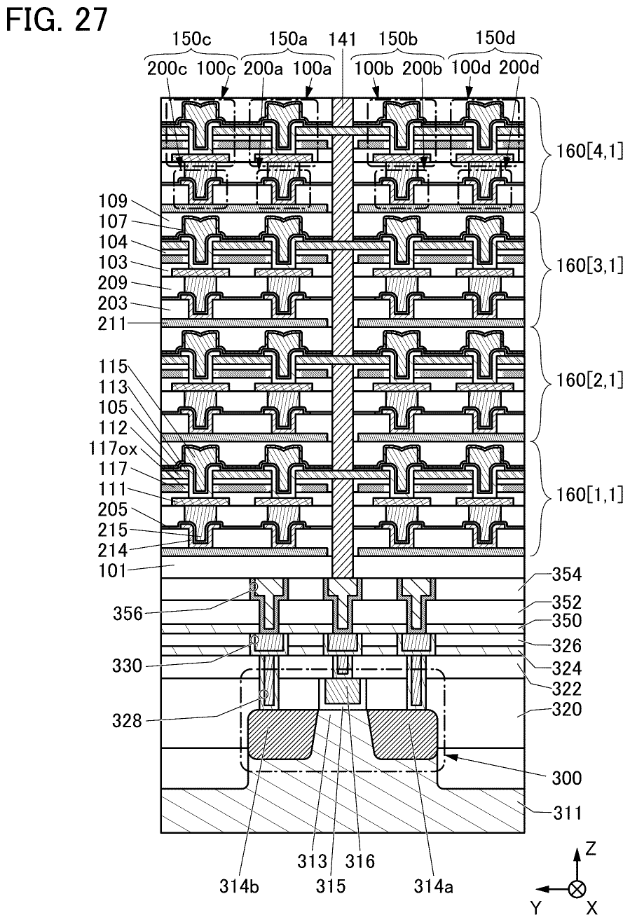

FIG. 27 is a diagram illustrating a structure example of a transistor 300 below the memory unit 160[1,1] to the memory unit 160[4, 1] illustrated in FIG. 25B. In the example illustrated in FIG. 27, a gate electrode of the transistor 300 is electrically connected to the conductive layer 141 functioning as part of the wiring BL. The transistor 300 can be a transistor provided in a driver circuit, which is a circuit having a function of controlling the driving of the semiconductor device of one embodiment of the present invention. For example, the transistor 300 illustrated in FIG. 27 can be a transistor included in a bit line driver circuit that controls writing and reading of data to/from the memory cell 150, and can be, for example, a transistor included in a sense amplifier included in the bit line driver circuit.

The transistor 300 is provided over a substrate 311 and includes a conductive layer 316 functioning as the gate electrode, an insulating layer 315 functioning as a gate insulating layer, a semiconductor region 313 that is part of the substrate 311, a low-resistance region 314a functioning as one of a source region and a drain region, and a low-resistance region 314b functioning as the other of the source region and the drain region. The transistor 300 may be either an n-channel transistor or a p-channel transistor.

In the example illustrated in FIG. 27, the transistor 300 is provided to overlap with the memory unit 160. Accordingly, the wiring BL functioning as the bit line can be shortened, so that parasitic capacitance (also referred to as bit line capacitance) formed by the wiring BL can be reduced. Thus, even when the storage capacitance of the memory cell 150 is low, it is possible to maintain the difference between the potential of the wiring BL of the case where data whose value is “1” is read from the memory cell 150 and the potential of the wiring BL of the case where data whose value is “0” is read from the memory cell 150. Thus, even when the storage capacitance of the memory cell 150 is low, the semiconductor device of one embodiment of the present invention can correctly read data retained in the memory cell 150. Since the storage capacitance of the memory cell 150 can be low, the capacitance value of the capacitor 200 can be small, for example; thus, the footprint of the capacitor 200 can be small. Thus, the footprint of the memory cell 150 can be small. Accordingly, the storage device can be miniaturized or highly integrated.

Here, in the transistor 300 shown in FIG. 27, the semiconductor region 313 (part of the substrate 311) in which the channel is formed has a projecting shape. In addition, the conductive layer 316 is provided to cover a side surface and the top surface of the semiconductor region 313 with the insulating layer 315 therebetween. Note that a material adjusting the work function may be used for the conductive layer 316. Such a transistor 300 is also referred to as a FIN-type transistor because it utilizes the projecting portion of the semiconductor substrate. Note that an insulating layer functioning as a mask for forming the projecting portion may be provided in contact with an upper portion of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 27 is an example and the structure is not limited thereto; an appropriate transistor can be used in accordance with a circuit structure or a driving method.

A wiring layer provided with an interlayer insulating layer, a wiring, a plug, and the like may be provided between the components. A plurality of wiring layers can be provided in accordance with the design. Here, a plurality of conductive layers functioning as plugs or wirings are collectively denoted by the same reference numeral in some cases. Moreover, in this specification and the like, a wiring and a plug electrically connected to the wiring may be a single component. That is, part of a conductive layer functions as a wiring in some cases and part of the conductive layer functions as a plug in other cases.

For example, an insulating layer 320, an insulating layer 322, an insulating layer 324, and an insulating layer 326 are sequentially stacked over the transistor 300 as interlayer insulating layers. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 function as a plug or a wiring.

As described above, the layers functioning as the interlayer insulating layers may be planarized. For example, the top surface of the insulating layer 322 may be planarized through planarization treatment using a CMP method or the like to increase the planarity.

A wiring layer may be provided over the insulating layer 326 and the conductive layer 330. For example, in FIG. 27, an insulating layer 350, an insulating layer 352, and an insulating layer 354 are stacked sequentially. Furthermore, a conductive layer 356 is formed in the insulating layer 350, the insulating layer 352, and the insulating layer 354. The conductive layer 356 functions as a plug or a wiring.

The insulating layer 101 is provided over the insulating layer 354 and the conductive layer 356. The conductive layer 141 is provided over the conductive layer 356. For example, the conductive layer 141 includes a region in contact with the top surface of the conductive layer 356, the conductive layer 356 includes a region in contact with the top surface of the conductive layer 330, and the conductive layer 330 includes a region in contact with the conductive layer 316. Thus, the conductive layer 141 functioning as part of the wiring BL is electrically connected to the conductive layer 316 functioning as the gate electrode of the transistor 300.

The insulating layer 352, the insulating layer 354, and the like functioning as the interlayer insulating layers can be formed using a material similar to the material that can be used for the insulating layer 101, for example.

As each of the conductive layers functioning as plugs or wirings, such as the conductive layer 328, the conductive layer 330, and the conductive layer 356, any of the conductive layers described in [Conductor] above can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

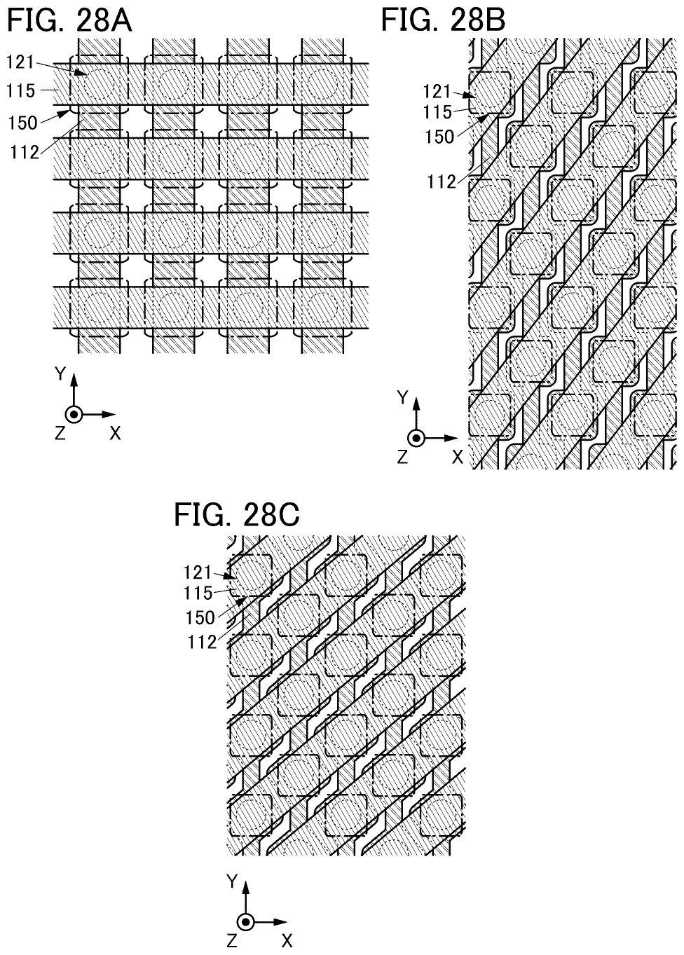

FIG. 28A is a plan view illustrating a structure example of a storage device of one embodiment of the present invention, and illustrates a region including 4 of the memory cells 150 in FIG. 22A1 in each of the X direction and the Y direction, i.e., a total of 16 of the memory cells 150. FIG. 28A illustrates the conductive layer 115 functioning as the wiring WL, the conductive layer 112 functioning as the wiring BL, and the opening portion 121. Note that the memory cell 150 is provided in a region where the conductive layer 115, the conductive layer 112, and the opening portion 121 overlap with each other. In other words, the opening portion 121 is provided in a region of the conductive layer 112 where the conductive layer 112 intersects with the conductive layer 115.

In the structure illustrated in FIG. 28A, the memory cells 150 are arranged in a matrix. In addition, the opening portions 121 are arranged in a matrix. In addition, the conductive layer 115 is provided to extend in the X direction and the conductive layer 112 is provided to extend in the Y direction. In other words, the conductive layer 115 and the conductive layer 112 are orthogonal to each other. In addition, the width of the conductive layer 115 is uniform in the direction (Y direction) perpendicular to the extending direction of the conductive layer 115, and the width of the conductive layer 112 is uniform in the direction (X direction) perpendicular to the extending direction of the conductive layer 112. Note that one embodiment of the present invention is not limited thereto.

FIG. 28B is another example of a plan-view layout of the storage device. In the plan-view layout in FIG. 28B, the conductive layer 115, the conductive layer 112, and the opening portion 121 are illustrated as in FIG. 28A. The storage device illustrated in FIG. 28B is different from the storage device illustrated in FIG. 28A mainly in the arrangement of the memory cells 150 (the opening portions 121), the shape of the conductive layer 112, and the extending direction of the conductive layer 115.

As illustrated in FIG. 28B, the memory cells 150 (the opening portions 121) may be arranged in a zigzag manner in the X direction. In FIG. 28B, a memory cell adjacent to a first memory cell in the Y direction is referred to as a second memory cell, and a memory cell adjacent to the first memory cell and the second memory cell in the X direction is referred to as a third memory cell. For example, it is preferable that the center of the third memory cell be positioned on a straight line that is parallel to the X direction and passes midway between the first memory cell and the second memory cell. In that case, it can be said that the third memory cell is positioned at a position shifted by half in the Y direction from the first memory cell and the second memory cell.

As illustrated in FIG. 28B, the conductive layer 112 includes a first region and a second region. The first region is a region including the opening portion 121 and the vicinity thereof, and the width of the first region in the X direction is referred to as a first width. In the plan view, the first region can be regarded as having a quadrangular shape with rounded corners. The second region is a region between the adjacent opening portions 121 in one conductive layer 112, and the width of the second region in the X direction is referred to as a second width. In this case, the second width is preferably smaller than the first width. With such a structure, in the case where the memory cells 150 (the opening portions 121) are arranged in a zigzag manner in the X direction, the physical distance between the conductive layers 112 can be shortened. Accordingly, miniaturization and high integration of the storage device can be achieved.

In FIG. 28B, the extending direction of the conductive layer 115 is inclined relative to the X direction. That is, the extending direction of the conductive layer 115 is not orthogonal to the extending direction of the conductive layer 112 in some cases depending on the arrangement of the memory cells 150 (the opening portions 121). In other words, the conductive layer 115 preferably intersects with the conductive layer 112.

FIG. 28C is another example of a plan-view layout of the storage device. In the plan-view layout in FIG. 28C, the conductive layer 115, the conductive layer 112, and the opening portion 121 are illustrated as in FIG. 28B. The storage device illustrated in FIG. 28C is different from the storage device illustrated in FIG. 28B mainly in the shape of the first region of the conductive layer 112.

The first region of the conductive layer 112 illustrated in FIG. 28B has a quadrangular shape with rounded corners in the plan view, and one side of the quadrangular shape is parallel to the X direction or the Y direction. Meanwhile, the first region of the conductive layer 112 illustrated in FIG. 28C has a quadrangular shape with rounded corners in the plan view, and the diagonal of the quadrangular shape is parallel to the X direction or the Y direction. With such a structure, in the case where the memory cells 150 (the opening portions 121) are arranged in a zigzag manner in the X direction, the physical distance between the conductive layers 112 can be shortened. Accordingly, miniaturization and high integration of the storage device can be achieved.

Although FIG. 28B and FIG. 28C each illustrate an example in which the first region of the conductive layer 112 has a quadrangular shape with rounded corners in the plan view, one embodiment of the present invention is not limited thereto.

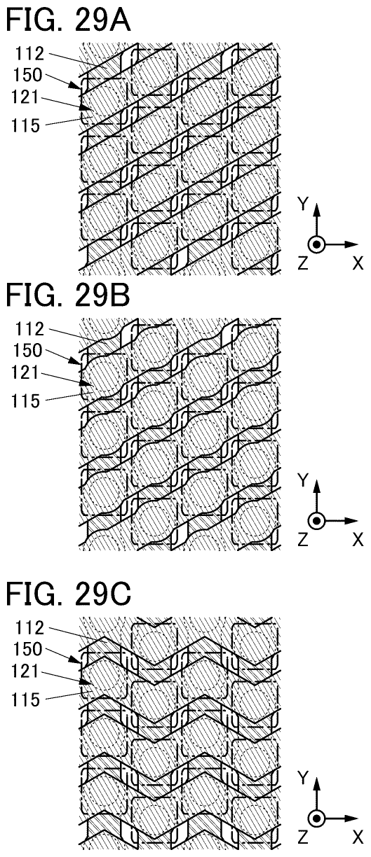

FIG. 29A is another example of a plan-view layout of the storage device. In the plan-view layout in FIG. 29A, the conductive layer 115, the conductive layer 112, and the opening portion 121 are illustrated as in FIG. 28B and FIG. 28C. The storage device illustrated in FIG. 29A is different from the storage devices illustrated in FIG. 28B and FIG. 28C mainly in the shape of the first region of the conductive layer 112.

The first region of the conductive layer 112 illustrated in FIG. 29A has a circular shape in the plan view. With such a structure, in the case where the memory cells 150 (the opening portions 121) are arranged in a zigzag manner in the X direction, the physical distance between the conductive layers 112 can be shortened. Accordingly, miniaturization and high integration of the storage device can be achieved.

Note that the shape of the first region of the conductive layer 112 in the plan view is not limited to the above-described shapes. For example, the first region of the conductive layer 112 in the plan view may have a substantially circular shape such as an elliptical shape, a polygonal shape such as a quadrangular shape, or a polygonal shape such as a quadrangular shape with rounded corners.

Although FIG. 29A illustrates the structure in which the width of the conductive layer 115 is uniform in the direction perpendicular to the extending direction of the conductive layer 115, one embodiment of the present invention is not limited to the structure.

FIG. 29B is another example of a plan-view layout of the storage device. In the plan-view layout in FIG. 29B, the conductive layer 115, the conductive layer 112, and the opening portion 121 are illustrated as in FIG. 29A. The storage device illustrated in FIG. 29B is different from the storage device illustrated in FIG. 29A mainly in the shape of the conductive layer 115.

Like the conductive layer 112, the conductive layer 115 illustrated in FIG. 29B includes a first region and a second region. The first region is a region including the opening portion 121 and the vicinity thereof and has a circular shape in the plan view. The second region is a region between the adjacent opening portions 121 in one conductive layer 115. Note that the first region of the conductive layer 115 overlaps with the first region of the conductive layer 112. With such a structure, in the case where the memory cells 150 (the opening portions 121) are arranged in a zigzag manner in the X direction, the physical distance between the conductive layers 112 can be shortened. Accordingly, miniaturization and high integration of the storage device can be achieved.

FIG. 29C is another example of a plan-view layout of the storage device. In the plan-view layout in FIG. 29C, the conductive layer 115, the conductive layer 112, and the opening portion 121 are illustrated as in FIG. 29A. The storage device illustrated in FIG. 29C is different from the storage device illustrated in FIG. 29A mainly in the shape and the extending direction of the conductive layer 115.

The conductive layer 115 illustrated in FIG. 29C has a serpentine shape like a triangle wave in the plan view and is provided to extend in the X direction. With such a structure, in the case where the memory cells 150 (the opening portions 121) are arranged in a zigzag manner in the X direction, the physical distance between the conductive layers 112 can be shortened. Accordingly, miniaturization and high integration of the storage device can be achieved. Note that the conductive layer 115 in the plan view is not limited to the above, and may have a meander shape, for example.

The above structure can shorten one or both of the physical distance between the conductive layers 115 and the physical distance between the conductive layers 112, in which case the storage device can be miniaturized and highly integrated.

The storage device including the 3D memory cell array will be described in detail in a later embodiment.

At least part of the structure, method, and the like described above in this embodiment can be implemented in appropriate combination with the other embodiments or the example described in this specification.

### Embodiment 2

In this embodiment, structure examples of storage devices using the memory cell described in the above embodiment are described. In this embodiment, structure examples of storage devices in which a layer including a functional circuit having functions of amplifying and outputting a data potential retained in a memory cell is provided between stacked layers including memory cells are described.

### Structure Example of Storage Device

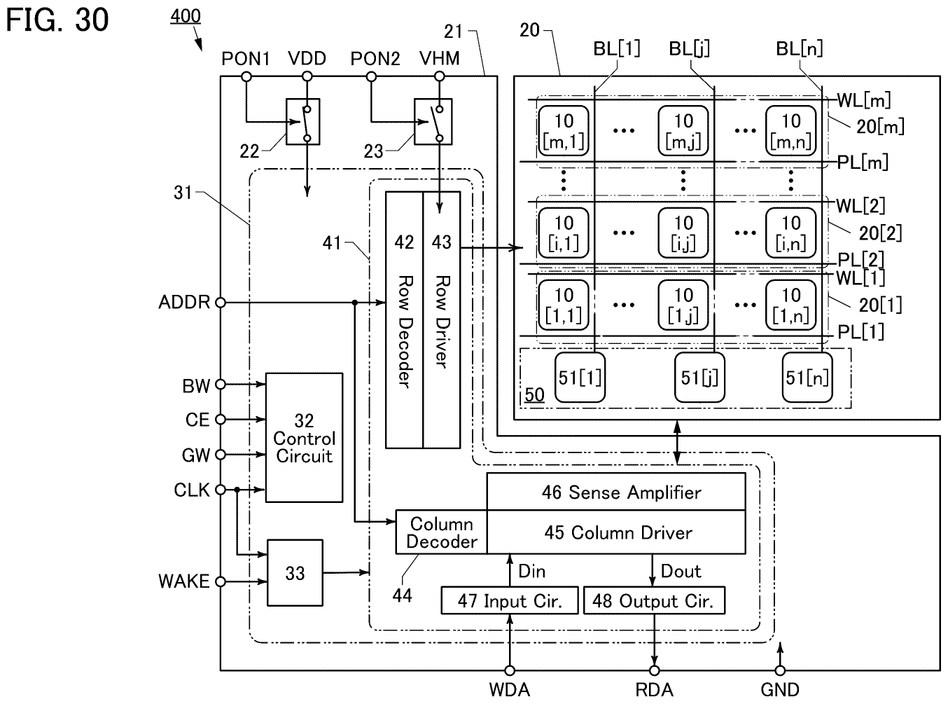

FIG. 30 is a block diagram illustrating a structure example of a storage device 400 that is a storage device of one embodiment of the present invention. The storage device 400 illustrated in FIG. 30 includes a driver circuit 21 and a memory array 20. The memory array 20 includes a functional layer 50 including a plurality of memory cells 10 and a plurality of functional circuits 51.

FIG. 30 illustrates an example in which the memory array 20 includes the plurality of memory cells 10 arranged in a matrix of m rows and n columns (each of m and n is an integer greater than or equal to 2). The functional circuit 51 is provided for each of the wirings BL functioning as bit lines, for example. The plurality of functional circuits 51 corresponding to n of the wirings BL are provided in the example illustrated in FIG. 30.

In FIG. 30, the memory cell 10 in the first row and the first column is referred to as a memory cell 10[1,1], and the memory cell 10 in the m-th row and the n-th column is referred to as a memory cell 10[m,n]. In this embodiment, for example, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment, for example, the memory cell 10 in the i-th row and the j-th column is referred to as a memory cell 10[i,j]. Note that in this embodiment, for example, “i+a” (a is a positive or negative integer) is not below 1 and does not exceed m. Similarly, “j+a” is not below 1 and does not exceed n.

The memory array 20 includes m of the wirings WL extending in the row direction, m of the wirings PL extending in the row direction, and the n wirings BL extending in the column direction. In this embodiment, for example, the first (first row) wiring WL is referred to as a wiring WL[1] and the m-th (m-th row) wiring WL is referred to as a wiring WL[m]. Similarly, the first (first row) wiring PL is referred to as a wiring PL[1] and the m-th (m-th row) wiring PL is referred to as a wiring PL[m]. Similarly, the first (first column) wiring BL is referred to as a wiring BL[1] and the n-th (n-th column) wiring BL is referred to as a wiring BL[n].

The plurality of memory cells 10 provided in the i-th row are electrically connected to the wiring WL in the i-th row (wiring WL[i]) and the wiring PL in the i-th row (wiring PL[i]). The plurality of memory cells 10 provided in the j-th column are electrically connected to the wiring BL in the j-th column (wiring BL[j]).

A DOSRAM (registered trademark) (Dynamic Oxide Semiconductor Random Access Memory) can be used for the memory array 20. A DOSRAM is a RAM including a 1T (transistor) 1C (capacitor) type memory cell and refers to a memory in which an access transistor is an OS transistor. An OS transistor has an extremely low current that flows between a source and a drain in an off state, that is, an extremely low leakage current. A DOSRAM can retain charge corresponding to data retained in a capacitor for a long time by turning off an access transistor. For this reason, the refresh operation frequency of a DOSRAM can be lower than that of a DRAM formed with a Si transistor. As a result, power consumption can be reduced.

The memory cells 10 can be provided in stacked layers by stacking OS transistors as described in Embodiment 1. For example, in the memory array 20 illustrated in FIG. 30, a plurality of memory arrays 20[1] to 20[m] can be provided in stacked layers. When the memory arrays 20[1] to 20[m] included in the memory array 20 are provided in a direction perpendicular to a surface of the substrate provided with the driver circuit 21, the memory density of the memory cells 10 can be increased. The memory array 20 can be formed by repeating the same process in the perpendicular direction. The manufacturing cost of the memory array 20 in the storage device 400 can be reduced. Thus, the storage device 400 can be inexpensive.

As described in Embodiment 1, the wiring BL functions as a bit line for writing and reading data. The wiring WL functions as a word line for controlling an on state or an off state of an access transistor serving as a switch. The wiring PL functions as a constant potential line connected to a capacitor.

The memory cell 10 included in each of the memory arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance values of the capacitors included in the memory cells 10 are reduced, operation is possible.

The functional circuit 51 has functions of amplifying a data potential retained in the memory cell 10 and outputting the amplified data potential to a sense amplifier 46 included in the driver circuit 21 through a wiring GBL (not illustrated) described later. With this structure, a slight difference in the potential of the wiring BL can be amplified at the time of data reading. Like the wiring BL, the wiring GBL can be provided in the direction perpendicular to the surface of the substrate provided with the driver circuit 21. When the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

Note that the wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductive layer provided in contact with the region functioning as the source or the drain in the semiconductor layer of the transistor included in the memory cell 10. In other words, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, the resistance and parasitic capacitance between the driver circuit 21 and the memory array 20 are reduced, so that power consumption and signal delays can be reduced. In addition, the storage device 400 can be downsized.

The functional circuit 51 can be provided in any desired position, e.g., over a circuit that is formed using Si transistors, in a manner similar to that of the memory arrays 20[1] to 20[m] when the functional circuit 51 is formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized, so that the storage device 400 can be downsized.

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the storage device 400, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 400. For example, the control circuit performs a logical operation on the signal CE, the signal GW, and the signal BW to determine an operation mode (e.g., a writing operation or a reading operation) of the storage device 400. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 is a circuit that outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the storage device 400. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 400, a high power supply voltage is VDD and a low power supply voltage is GND (a ground potential). In addition, VHM is a high power supply voltage used to set a word line at a high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 30 but can be more than one. In that case, a power switch is provided for each power domain.

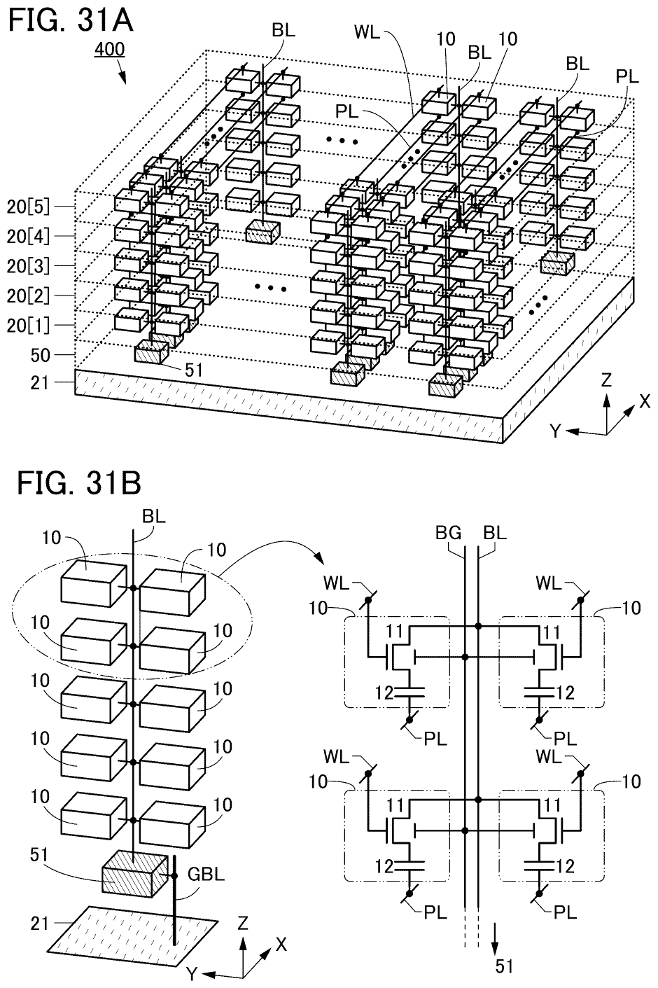

In the memory array 20 including the memory arrays 20[1] to 20[m] (m is an integer greater than or equal to 2) and the functional layer 50, a plurality of layers of the memory arrays 20 can be provided over the driver circuit 21 to overlap with the driver circuit 21. Stacking the plurality of layers of the memory arrays 20 can increase the memory density of the memory cells 10. FIG. 31A is a perspective view of the storage device 400 in which five layers of the memory arrays 20[1] to 20[5] (m=5) and the functional layer 50 are provided over the driver circuit 21 to overlap with the driver circuit 21.

In FIG. 31A, the memory array 20 provided in the first layer is denoted as the memory array 20[1], the memory array 20 provided in the second layer is denoted as the memory array 20[2], and the memory array 20 provided in the fifth layer is denoted as the memory array 20[5]. FIG. 31A also illustrates the wiring WL and the wiring PL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not illustrated. Although FIG. 31A illustrates the structure in which the wiring PL extends in the X direction, one embodiment of the present invention is not limited to the structure. For example, the wiring PL may extend in the Y direction, or the wiring PL may extend in the X direction and the Y direction, for example, the wiring PL may be provided to have a planar shape.

FIG. 31B is a schematic view for describing a structure example of the functional circuit 51, which is connected to the wiring BL, and the memory cells 10 included in the memory arrays 20[1] to 20[5], which are connected to the wiring BL, illustrated in FIG. 31A. FIG. 31B illustrates the wiring GBL provided between the functional circuit 51 and the driver circuit 21. Note that a structure in which a plurality of memory cells (the memory cells 10) are electrically connected to one of the wirings BL is also referred to as “memory string”. In the drawings, the wiring GBL is sometimes represented by a bold line for increasing visibility.

FIG. 31B illustrates an example of a circuit structure of the memory cell 10 connected to the wiring BL. The memory cell 10 includes a transistor 11 and a capacitor 12. As for the transistor 11, the capacitor 12, and the wirings (e.g., the wiring BL and the wiring WL), for example, the wiring BL[1] and the wiring WL[1] are referred to as the wiring BL and the wiring WL in some cases.

The memory cell 10 illustrated in FIG. 31B corresponds to the memory cell 150 described in Embodiment 1 with reference to, for example, FIG. 22D1. The transistor 11 and the capacitor 12 included in the memory cell 10 correspond to the transistor 100 and the capacitor 200, respectively. Here, an example is described in which second gate electrodes of four of the transistors 11 illustrated in FIG. 31B are electrically connected to one wiring BG.

The wiring PL is a wiring for supplying a constant potential for retaining the potential of the capacitor 12.

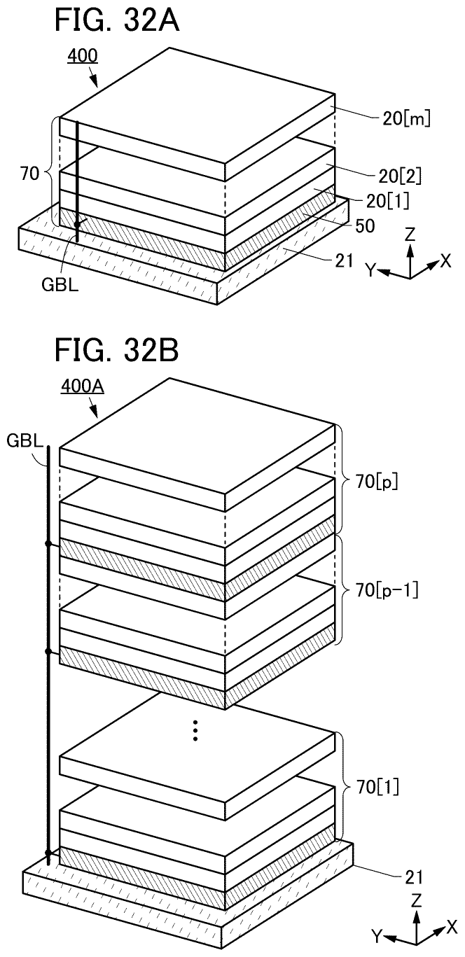

The wiring GBL illustrated in FIG. 31B is provided to electrically connect the driver circuit 21 and the functional layer 50. FIG. 32A is a schematic view of the storage device 400 in which the functional layer 50 and the memory arrays 20[1] to 20[m] are regarded as a repeating unit 70. Note that although FIG. 32A illustrates one of the wirings GBL, the wiring GBL is provided as appropriate depending on the number of functional circuits 51 provided in the functional layer 50.

Note that the wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductive layer provided in contact with the region functioning as the source or the drain in the semiconductor layer of the transistor included in the functional circuit 51. In other words, the wiring GBL is a wiring for electrically connecting the driver circuit 21 and one of the source and the drain of the transistor included in the functional circuit 51 in the functional layer 50 in the perpendicular direction.

The repeating unit 70 including the functional circuit 51 and the memory arrays 20[1] to 20[m] may have a stacked-layer structure. A storage device 400A of one embodiment of the present invention can include repeating units 70[1] to 70[p] (p is an integer greater than or equal to 2) as illustrated in FIG. 32B. The wiring GBL is connected to the functional layers 50 included in the repeating units 70. The wiring GBL is provided as appropriate depending on the number of functional circuits 51.

In one embodiment of the present invention, OS transistors are provided in stacked layers and a wiring functioning as a bit line is provided in the direction perpendicular to the surface of the substrate provided with the driver circuit 21. Since the wiring provided to extend from the memory array 20 and function as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the storage device 400 can be downsized. Moreover, even when the capacitance of the capacitors 12 included in the memory cells 10 is reduced, operation is possible.

### Structure Examples of Memory Array 20 and Functional Circuit 51

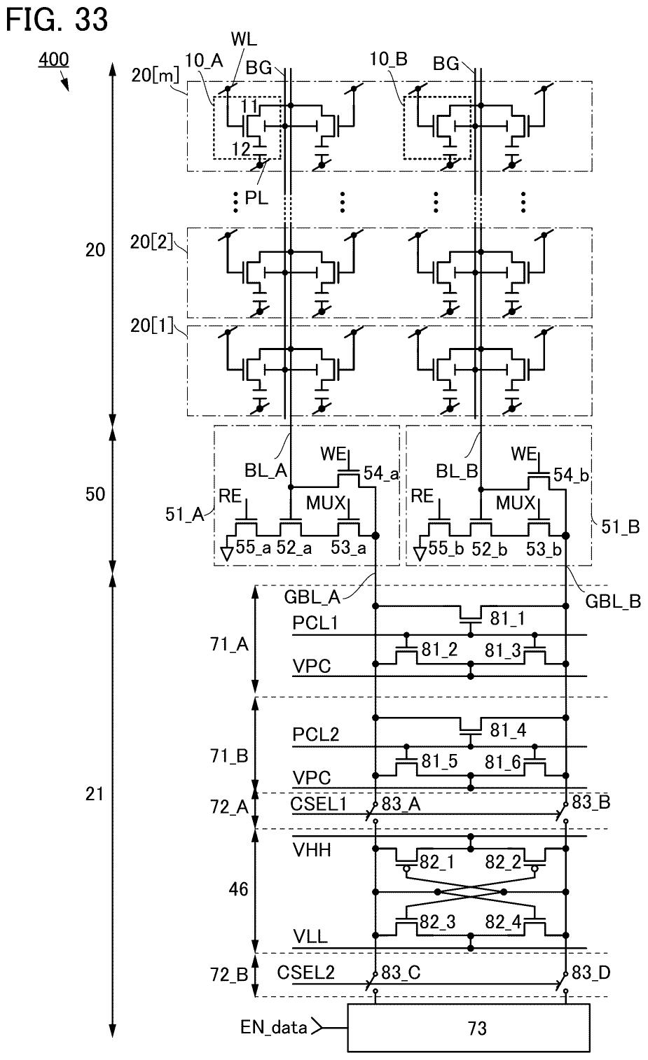

A structure example of the functional circuit 51 and structure examples of the memory array 20 and the sense amplifier 46 included in the driver circuit 21, which are described with reference to FIG. 30 to FIG. 32, are described with reference to FIG. 33. FIG. 33 illustrates the driver circuit 21 connected to the wirings GBL (GBL_A and GBL_B) connected to the functional circuits 51 (51_A and 51_B) connected to the memory cells 10 (10_A and 10_B) connected to different wirings BL (BL_A and BL_B). FIG. 33 also illustrates, as the driver circuit 21, a precharge circuit 71_A, a precharge circuit 71_B, a switch circuit 72_A, a switch circuit 72_B, and a write/read circuit 73 in addition to the sense amplifier 46.

Although the wiring BG electrically connected to the second gate electrode of the transistor 11 provided in the memory cell 10_A is different from the wiring BG electrically connected to the second gate electrode of the transistor 11 provided in the memory cell 10_B in the example illustrated in FIG. 33, these wirings BG may be one wiring.

As the functional circuit 51_A and the functional circuit 51_B, a transistor 52_a, a transistor 52_b, a transistor 53_a, a transistor 53_b, a transistor 54_a, a transistor 54_b, a transistor 55_a, and a transistor 55_b are illustrated. The transistors 52_a, 52_b, 53_a, 53_b, 54_a, 54_b, 55_a, and 55_b illustrated in FIG. 33 are OS transistors like the transistor 11 included in the memory cell 10. The functional layer 50 including the functional circuits 51 can be provided in stacked layers like the memory arrays 20[1] to 20[m].

The wirings BL_A and BL_B are connected to gates of the transistors 52_a and 52_b. Ones of sources and drains of the transistors 53_a, 53_b, 54_a, and 54_b are connected to the wirings GBL_A and GBL_B. The wirings GBL_A and GBL_B are provided in the perpendicular direction like the wirings BL_A and BL_B and connected to the transistors included in the driver circuit 21. As illustrated in FIG. 33, control signals WE, RE, and MUX are supplied to gates of the transistors 53_a, 53_b, 54_a, 54_b, 55_a, and 55_b.

A transistor 81_1 to a transistor 81_6 and a transistor 82_1 to a transistor 82_4 included in the sense amplifier 46, the precharge circuit 71_A, and the precharge circuit 71_B illustrated in FIG. 33 are Si transistors. Switches 83_A to 83_D included in the switch circuit 72_A and the switch circuit 72_B can also be Si transistors. The ones of the sources and the drains of the transistors 53_a, 53_b, 54_a, and 54_b are connected to the transistors or switches included in the precharge circuit 71_A, the precharge circuit 71_B, the sense amplifier 46, and the switch circuit 72_A.

The precharge circuit 71_A includes the n-channel transistor 81_1 to the n-channel transistor 81_3. The precharge circuit 71_A is a circuit for precharging the wirings BL_A and BL_B with an intermediate potential VPC corresponding to a potential VDD/2 between VDD and VSS in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistor 82_1, the p-channel transistor 82_2, the n-channel transistor 82_3, and the n-channel transistor 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged are changed by selecting the memory cell 10_A and the memory cell 10_B, and the potentials of the wiring GBL_A and the wiring GBL_B are set to the high power supply potential VDD or the low power supply potential VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on and off states of the switch circuit 72_A are switched under the control of a switch signal CSEL1. In the case where the switch 83_A and the switch 83_B are n-channel transistors, the switch 83_A and the switch 83_B are turned on and off when the switch signal CSEL1 is at a high level and a low level, respectively. The switch circuit 72_B is a circuit for controlling electrical continuity between the write/read circuit 73 and the bit line pair connected to the sense amplifier 46. The on and off states of the switch circuit 72_B are switched under the control of a switching signal CSEL2. The switches 83_C and 83_D are similar to the switches 83_A and 83_B.

As illustrated in FIG. 33, the storage device 400 can have a structure where the memory cell 10, the functional circuit 51, and the sense amplifier 46 are connected to each other through the wiring BL and the wiring GBL provided in the perpendicular direction which is the shortest distance. Even with addition of the functional layer 50 including transistors included in the functional circuit 51, the load of the wiring BL is reduced, whereby the writing time can be shortened and data reading can be facilitated.

As illustrated in FIG. 33, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can function as a sense amplifier formed with OS transistors. With this structure, a slight difference in the potential of the wiring BL can be amplified at the time of reading to drive the sense amplifier 46 formed using Si transistors.

When a plurality of the memory cell arrays and the driver circuit are stacked as described above, the storage device can be highly integrated and have a high storage capacity.

At least part of the structure, method, and the like described above in this embodiment can be implemented in appropriate combination with the other embodiments or the example described in this specification.

### Embodiment 3

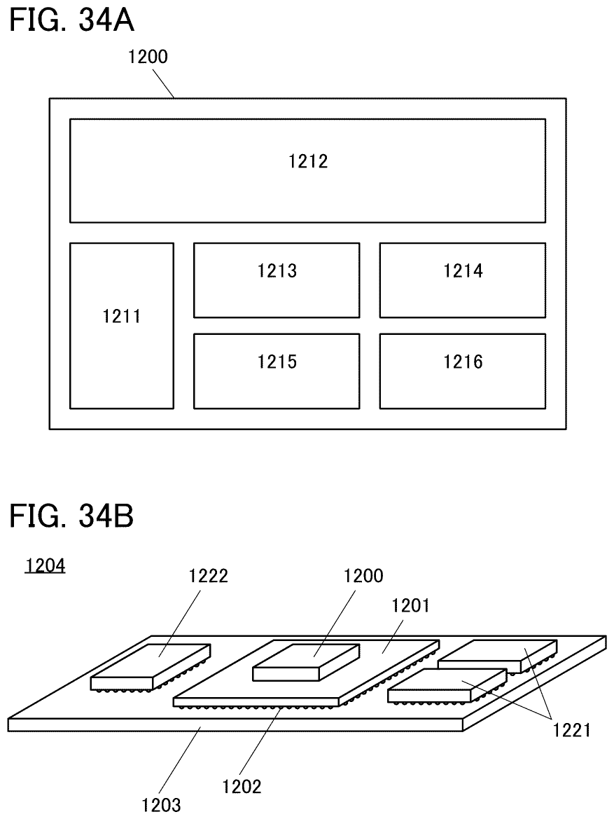

In this embodiment, an example of a chip 1200 on which the storage device of one embodiment of the present invention is mounted is described with reference to FIG. 34A and FIG. 34B. A plurality of circuits (systems) are mounted on the chip 1200. A technique for integrating a plurality of circuits (systems) into one chip is referred to as system on chip (SoC) in some cases.

As illustrated in FIG. 34A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 34B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Storage devices such as DRAMs 1221 or a flash memory 1222 may be provided over the motherboard 1203. For example, the DOSRAM described in the above embodiment can be used as the DRAM 1221. In that case, the DRAMs 1221 can have lower power consumption, higher speed, and higher capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a large number of pieces of data and thus can be used for image processing or product-sum operation. When an image processing circuit or a product-sum operation circuit including an oxide semiconductor of one embodiment of the present invention is provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an externally connected device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in portable electronic appliances such as a smartphone, a tablet terminal, a laptop PC, and a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described above in this embodiment can be implemented in appropriate combination with the other embodiments or the example described in this specification.

### Embodiment 4

In this embodiment, examples of electronic components and electronic appliances in which the storage device described in the above embodiment is incorporated are described. When the storage device described in the above embodiment is used for the following electronic components and electronic appliances, the electronic components and electronic appliances can have lower power consumption and higher speed.

### <Electronic Component>

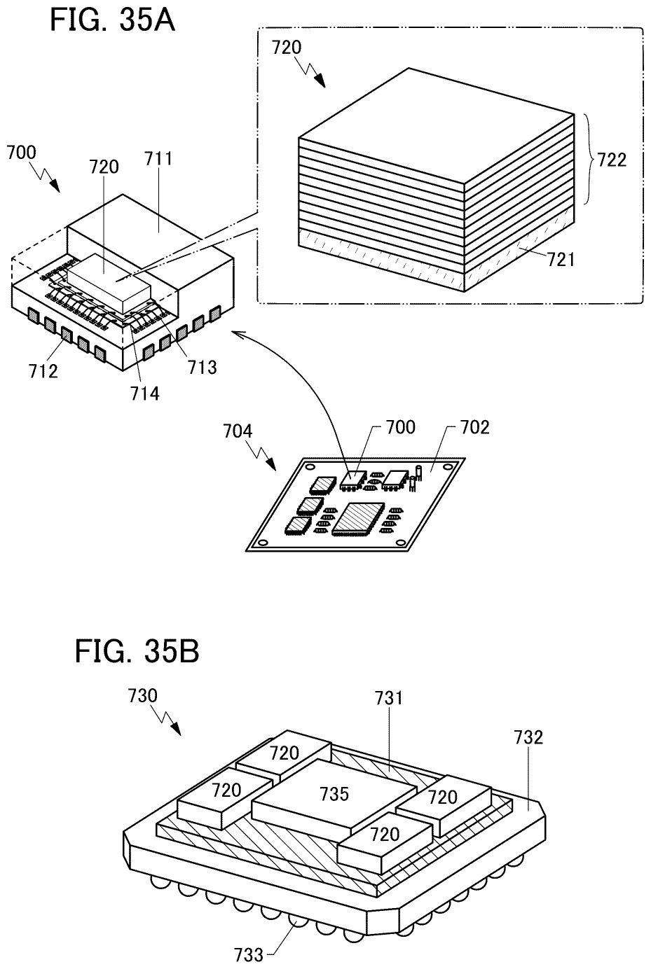

First, examples of an electronic component including a storage device 720 are described with reference to FIG. 35A and FIG. 35B.

FIG. 35A is a perspective view of an electronic component 700 and a substrate (mounting board 704) on which the electronic component 700 is mounted. The electronic component 700 illustrated in FIG. 35A includes the storage device 720 in a mold 711. FIG. 35A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the mounting board 704.

The storage device 720 includes a driver circuit layer 721 and a storage circuit layer 722.

FIG. 35B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the storage devices 720 are provided over the interposer 731. When the storage device described in the above embodiment is used as the storage device 720, power consumption can be reduced and higher speed can be achieved.

An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because the silicon interposer does not need to be provided with an active element. Meanwhile, since wirings of the silicon interposer can be formed through a semiconductor process, the formation of minute wirings, which is difficult for a resin interposer, is easily achieved.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package substrate 732 to mount the electronic component 730 on another substrate. FIG. 35B illustrates an example where the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods other than BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

At least part of the structure, method, and the like described above in this embodiment can be implemented in appropriate combination with the other embodiments or the example described in this specification.

### Embodiment 5

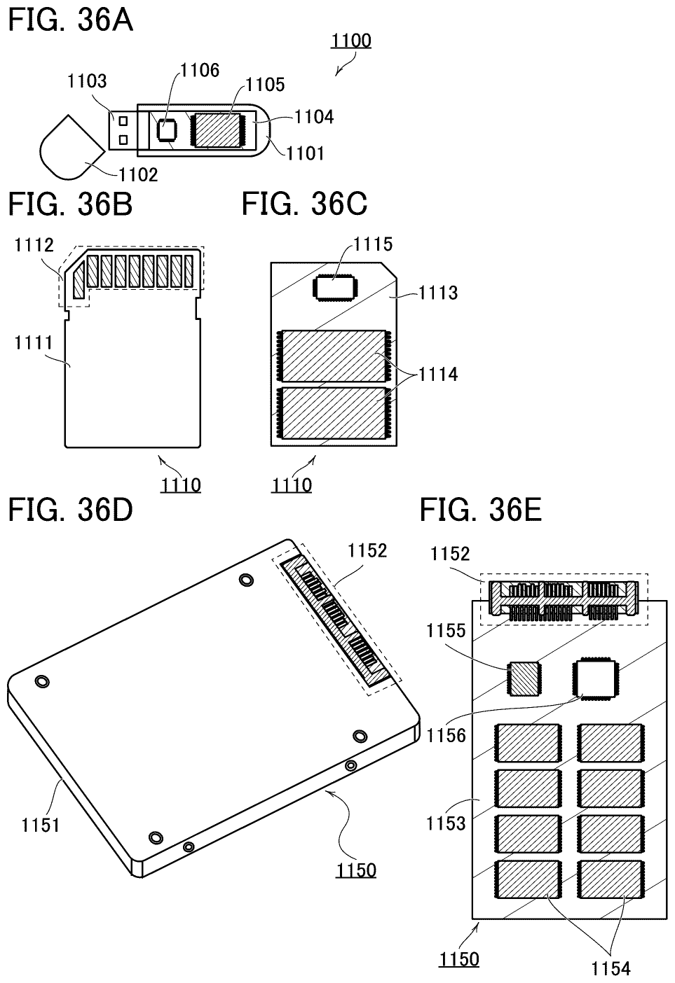

In this embodiment, application examples of the storage device using the storage device described in the above embodiment are described. The storage device described in the above embodiment can be applied to, for example, storage devices of a variety of electronic appliances (e.g., information terminals, computers, smartphones, e-book readers, digital cameras (including video cameras), video recording/reproducing devices, and navigation systems). When the storage device described in the above embodiment is used for the storage devices of the above electronic appliances, the electronic appliances can have lower power consumption and higher speed. Here, the computers refer not only to tablet computers, notebook computers, and desktop computers, but also to large computers such as server systems. Alternatively, the storage device described in the above embodiment is applied to a variety of removable storage devices such as memory cards (e.g., SD cards), USB memories, and SSDs (solid state drives). FIG. 36A to FIG. 36E schematically illustrate some structure examples of removable storage devices. The storage device described in the above embodiment is processed into a packaged memory chip and used in a variety of storage devices and removable memories, for example.

FIG. 36A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The storage device described in the above embodiment can be incorporated in the memory chip 1105, for example.

FIG. 36B is a schematic external view of an SD card, and FIG. 36C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The storage device described in the above embodiment can be incorporated in the memory chip 1114, for example.

FIG. 36D is a schematic external view of an SSD, and FIG. 36E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The storage device described in the above embodiment can be incorporated in the memory chip 1154, for example.

At least part of the structure, method, and the like described above in this embodiment can be implemented in appropriate combination with the other embodiments or the example described in this specification.

### Embodiment 6

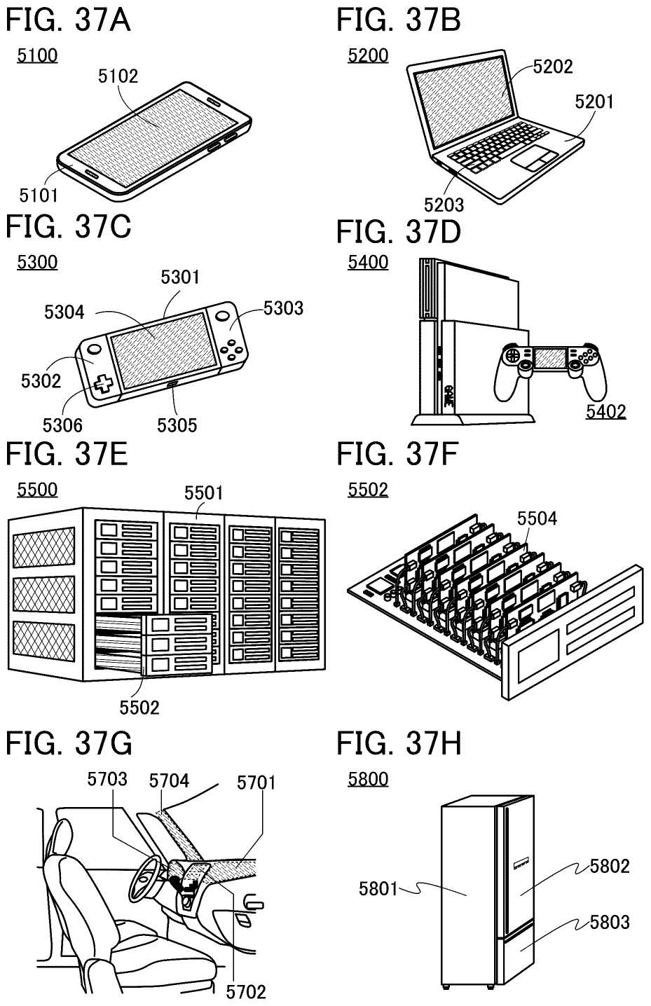

The storage device of one embodiment of the present invention can be used for a processor, e.g., a CPU or a GPU, or a chip. When such a processor, e.g., a CPU or a GPU, or such a chip is used for an electronic appliance, the electronic appliance can have lower power consumption and higher speed. FIG. 37A to FIG. 37H illustrate specific examples of electronic appliances provided with the processor, e.g., the CPU or the GPU, or the chip that includes the storage device.

### <Electronic Appliance and System>

The GPU or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, information, and the like on a display portion. When the electronic appliance includes the antenna and a secondary battery, the antenna may be used for contactless power transmission.

The electronic appliance of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, a current, a voltage, electric power, radioactive rays, flow rate, humidity, a gradient, oscillation, odor, or infrared rays).

The electronic appliance of one embodiment of the present invention can have a variety of functions. For example, the electronic appliance can have a function of displaying a variety of information (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium. FIG. 37A to FIG. 37H illustrate examples of electronic appliances.

### [Information Terminal]

FIG. 37A illustrates a mobile phone (smartphone), which is a type of information terminal. An information terminal 5100 includes a housing 5101 and a display portion 5102; as input interfaces, a touch panel is provided in the display portion 5102 and a button is provided in the housing 5101.

The use of the chip of one embodiment of the present invention for the information terminal 5100 can reduce power consumption and enables higher speed.

FIG. 37B illustrates a notebook information terminal 5200. The notebook information terminal 5200 includes a main body 5201 of the information terminal, a display portion 5202, and a keyboard 5203.

As in the information terminal 5100 described above, the use of the chip of one embodiment of the present invention can reduce power consumption and enables higher speed of the notebook information terminal 5200.

Although FIG. 37A and FIG. 37B illustrate the smartphone and the notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 37C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, multiple players can play a game at the same time. The chip described in the above embodiment can be incorporated into the chip or the like provided on a substrate in the housing 5301, the housing 5302, and the housing 5303.

FIG. 37D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 or the stationary game machine 5400 can achieve a low-power-consumption game machine. Moreover, heat generation from a circuit can be reduced owing to low power consumption; thus, the influence of heat generation on the circuit, a peripheral circuit, and a module can be reduced.

Furthermore, by using the GPU or the chip of one embodiment of the present invention in the portable game machine 5300, low power consumption and high speed can be achieved.

Although the portable game machine and the stationary game machine are illustrated as examples of game machines in FIG. 37C and FIG. 37D, the game machine using the GPU or the chip of one embodiment of the present invention is not limited thereto. Examples of the game machine in which the GPU or the chip of one embodiment of the present invention is used include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 37E is a diagram illustrating a supercomputer 5500 as an example of a large computer. FIG. 37F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, on which the GPU or the chip described in the above embodiment can be mounted.

The supercomputer 5500 is a large computer used mainly for scientific computation. In scientific computation, an enormous amount of arithmetic operation needs to be processed at high speed; hence, power consumption is high and chips generate a large amount of heat. For example, the amount of digital data used in a data center including a plurality of the supercomputers 5500 is quite voluminous. Specifically, the amount of digital data in the world is estimated to exceed 1024 (yota) byte or 1030 (quetta) byte.

Using the GPU or the chip of one embodiment of the present invention in the supercomputer 5500 can achieve a low-power-consumption supercomputer. Moreover, heat generation from a circuit can be reduced owing to low power consumption; thus, the influence of heat generation on the circuit, a peripheral circuit, and a module can be reduced. Using the GPU or the chip including the storage device of one embodiment of the present invention enables achieving a low-power-consumption supercomputer. Thus, the amount of digital data in the world is expected to be reduced, leading to a great contribution to global warming countermeasures.

Although a supercomputer is illustrated as an example of a large computer in FIG. 37E and FIG. 37F, a large computer using the GPU or the chip of one embodiment of the present invention is not limited thereto. Other examples of large computers for which the GPU or the chip of one embodiment of the present invention is usable include a computer that provides service (a server) and a large general-purpose computer (a mainframe).

### [Moving Vehicle]

The GPU or the chip of one embodiment of the present invention can be used in an automobile, which is a moving vehicle, and the periphery of a driver's seat in the automobile.

FIG. 37G is a diagram illustrating an area around a windshield inside an automobile, which is an example of a moving vehicle. FIG. 37G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, or the like. In addition, the content, layout, and the like of the display on the display panels can be changed as appropriate to suit the user's preference, and thus the design quality can be increased. The display panel 5701 to the display panel 5703 can also be used as lighting devices.

The display panel 5704 can complement a view obstructed by the pillar (a blind spot) by showing an image taken with an image capturing device (not illustrated) provided for the automobile. That is, displaying an image taken with the image capturing device provided on the exterior of the automobile leads to compensation for the blind spot and an increase in safety. In addition, displaying an image to complement a portion that cannot be seen makes it possible for the driver to confirm the safety more naturally and comfortably. The display panel 5704 can also be used as a lighting device.

Since the GPU or the chip of one embodiment of the present invention can be used as a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Although the automobile is described above as an example of a moving vehicle, the moving vehicle is not limited to an automobile. Examples of the moving vehicle include a train, a monorail train, a ship, and a flying vehicle, and these moving vehicles can each have a system utilizing artificial intelligence when the chip of one embodiment of the present invention is used in each of these moving vehicles. Examples of the flying vehicle include a helicopter, an unmanned aircraft (a drone), an airplane, and a rocket.

### [Household Appliance]

FIG. 37H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is used in the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, and the like, a function of automatically adjusting the temperature to be suitable for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described above in this embodiment can be implemented in appropriate combination with the other embodiments or the example described in this specification.

### Embodiment 7

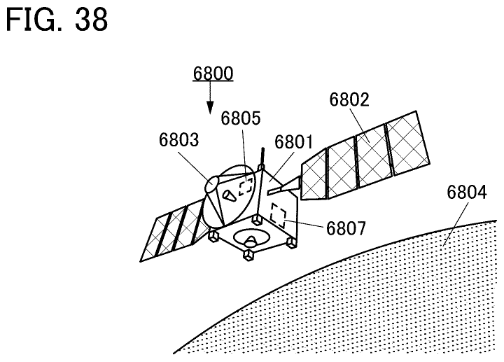

The storage device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, OS transistors can be suitably used in outer space. In this embodiment, a specific example of using the storage device of one embodiment of the present invention in a device for space will be described with reference to FIG. 38.

FIG. 38 illustrates an artificial satellite 6800 as an example of a device for space. The artificial satellite 6800 includes a body 6801, a solar panel 6802, an antenna 6803, a secondary battery 6805, and a control device 6807. In FIG. 38, a planet 6804 in outer space is illustrated. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the storage device that is one embodiment of the present invention and that includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The storage device of one embodiment of the present invention can be suitably used for a device for space such as a spacecraft, a space capsule, or a space probe, for example.

At least part of the structure, method, and the like described above in this embodiment can be implemented in appropriate combination with the other embodiments or the example described in this specification.

### EXAMPLE

In this example, results of cross-sectional STEM (Scanning Transmission Electron Microscopy) observation and electrical characteristics measurement performed for fabricated samples are described.

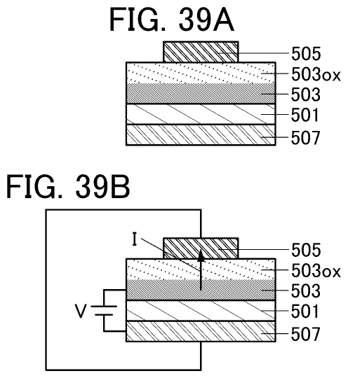

FIG. 39A is a cross-sectional view illustrating a structure of the sample fabricated in this example. In this example, Sample 1 to Sample 3 were fabricated. First, for each of Sample 1 to Sample 3, a film of tantalum nitride was formed over a silicon substrate 501 by a sputtering method as a conductive layer 503 with the target thickness set to 50 nm. Next, for Sample 1 and Sample 2, microwave treatment was performed for the purpose of forming an oxide region 503ox by oxidation of the conductive layer 503. In the microwave treatment, an argon gas at 150 sccm and an oxygen gas at 50 sccm were used as treatment gases, the pressure was 400 Pa, the power was 400 W, and the treatment temperature was 400° C. The treatment time was 10 minutes for Sample 1 and 30 minutes for Sample 2. Here, the microwave treatment was not performed for Sample 3.

Next, for each of Sample 1 to Sample 3, a film of an alloy of aluminum and titanium was formed as a conductive layer 505 by a sputtering method using a metal mask with the target thickness set to 200 nm. After that, as a conductive layer 507, a film of aluminum was formed on the rear surface of the silicon substrate 501 (the surface opposite to the conductive layer 503) by a sputtering method with the target thickness set to 400 nm. Sample 1 to Sample 3 were fabricated as described above.

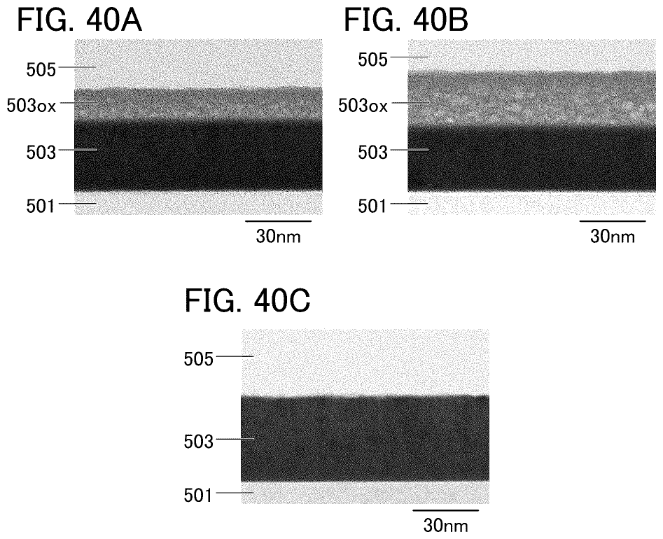

FIG. 40A, FIG. 40B, and FIG. 40C are cross-sectional STEM images of Sample 1, Sample 2, and Sample 3, respectively. As shown in FIG. 40A and FIG. 40B, it was confirmed that the oxide region 503ox was formed in Sample 1 and Sample 2, which were subjected to the microwave treatment after the formation of the conductive layer 503. Meanwhile, the oxide region 503ox was not formed in Sample 3, which was not subjected to the microwave treatment. Here, the main component of the oxide region 503ox was tantalum oxide.

In Sample 1 to Sample 3, the thickness of the oxide region 503ox was 17.9 nm, 29.5 nm, and 0 nm, respectively, and the thickness of the conductive layer 503 was 33.8 nm, 30.5 nm, and 42.9 nm, respectively. Thus, it was confirmed that the formation of the oxide region 503ox by the microwave treatment reduced the thickness of the region of the conductive layer 503 that was not oxidized. It was also confirmed that the thickness of the oxide region 503ox was larger and the thickness of the region of the conductive layer 503 that was not oxidized was smaller in the case where the microwave treatment was performed for 30 minutes than in the case where the microwave treatment was performed for 10 minutes. Note that the above-described thickness “0 nm” of the oxide region 503ox means that the oxide region 503ox was not formed.

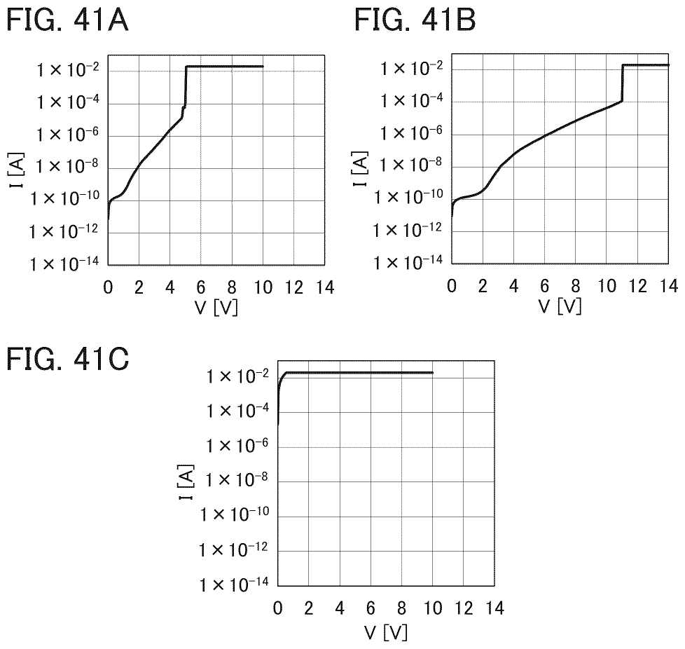

FIG. 39B is a schematic view illustrating a measurement system of electrical characteristics. As illustrated in FIG. 39B, a voltage V was applied between the conductive layer 503 and the conductive layer 507. Then, the conductive layer 505 and the conductive layer 507 were electrically connected to each other, and a current I flowing between the conductive layer 503 and the conductive layer 505 was measured. FIG. 41A, FIG. 41B, and FIG. 41C are graphs showing the measurement results of the I-V characteristics of Sample 1, Sample 2, and Sample 3, respectively.

It was confirmed that as shown in FIG. 41A to FIG. 41C, the current I of each of Sample 1 and Sample 2, in which the oxide region 503ox was formed, was lower than the current I of Sample 3, in which the oxide region 503ox was not formed, at the voltage V lower than or equal to 5 V in Sample 1, and at the voltage V lower than or equal to 11 V in Sample 2. Thus, it was confirmed that the oxide region 503ox had a higher electrical resistivity than the conductive layer 503 and the conductive layer 505. It was confirmed that at the voltage V lower than or equal to 11 V, the current I was lower in the case where the microwave treatment was performed for 30 minutes than in the case where the microwave treatment was performed for 10 minutes. From the above, it is confirmed that the thickness of the oxide region 503ox was larger and the electric resistance between the conductive layer 503 and the conductive layer 505 was resultantly higher in the case where the microwave treatment was performed for 30 minutes than in the case where the microwave treatment was performed for 10 minutes.

### REFERENCE NUMERALS

10: memory cell, 11: transistor, 12: capacitor, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51: functional circuit, 52_a: transistor, 52_b: transistor, 53_a: transistor, 53_b: transistor, 54_a: transistor, 54_b: transistor, 55_a: transistor, 55_b: transistor, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 100a: transistor, 100b: transistor, 100c: transistor, 100d: transistor, 100: transistor, 101: insulating layer, 103a: insulating layer, 103b: insulating layer, 103c: insulating layer, 103: insulating layer, 104a: insulating layer, 104b: insulating layer, 104c: insulating layer, 104: insulating layer, 105a: insulating layer, 105b: insulating layer, 105c: insulating layer, 105: insulating layer, 106: insulating layer, 107: insulating layer, 109: insulating layer, 111a: conductive layer, 111b: conductive layer, 111: conductive layer, 112: conductive layer, 113a: semiconductor layer, 113b: semiconductor layer, 113i: region, 113na: region, 113nb: region, 113: semiconductor layer, 115a: conductive layer, 115b: conductive layer, 115: conductive layer, 117ox: oxide region, 117: conductive layer, 121a: opening portion, 121b: opening portion, 121: opening portion, 131: depressed portion, 132: depressed portion, 141: conductive layer, 142: conductive layer, 150A: memory cell, 150a: memory cell, 150b: memory cell, 150c: memory cell, 150d: memory cell, 150: memory cell, 151: transistor, 160: memory unit, 170: layer, 200a: capacitor, 200b: capacitor, 200c: capacitor, 200d: capacitor, 200: capacitor, 203: insulating layer, 205: insulating layer, 209: insulating layer, 211: conductive layer, 212: conductive layer, 214: conductive layer, 215: conductive layer, 221: opening portion, 300: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 400A: storage device, 400: storage device, 501: silicon substrate, 503ox: oxide region, 503: conductive layer, 505: conductive layer, 507: conductive layer, 700: electronic component, 702: printed circuit board, 704: mounting board, 711: mold, 712: land, 713: electrode pad, 714: wire, 720: storage device, 721: driver circuit layer, 722: storage circuit layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door, 6800: artificial satellite, 6801: body, 6802: solar panel, 6803: antenna, 6804: planet, 6805: secondary battery, 6807: control device

1. A semiconductor device comprising:
a transistor, a first insulating layer, and a second insulating layer,
wherein the transistor comprises a first conductive layer, a second conductive layer, a third conductive layer, a fourth conductive layer, a semiconductor layer, and a third insulating layer,
wherein the first insulating layer is provided over the first conductive layer,
wherein the second conductive layer is provided over the first insulating layer,
wherein the second insulating layer is provided over the second conductive layer,
wherein the third conductive layer is provided over the second insulating layer,
wherein the first insulating layer, the second conductive layer, the second insulating layer, and the third conductive layer are provided with an opening portion reaching the first conductive layer,
wherein the second conductive layer is provided with an oxide region comprising a side surface in the opening portion,
wherein the semiconductor layer is provided to comprise a region positioned in the opening portion,
wherein the semiconductor layer comprises a region in contact with the first conductive layer, a region in contact with the oxide region, and a region in contact with the third conductive layer,
wherein the third insulating layer is provided over the semiconductor layer to comprise a region positioned in the opening portion, and
wherein the fourth conductive layer is provided to comprise a region positioned in the opening portion and to comprise a region facing the semiconductor layer with the third insulating layer sandwiched between the region and the semiconductor layer.

2. The semiconductor device according to claim 1,
wherein the oxide region comprises an oxide of a material of the second conductive layer.

3. The semiconductor device according to claim 1,
wherein the second conductive layer and the fourth conductive layer comprise regions sandwiching a channel formation region of the semiconductor layer in the opening portion.

4. The semiconductor device according to claim 1,
wherein the first conductive layer comprises a first layer and a second layer,
wherein the second layer is provided over the first layer, and
wherein the semiconductor layer comprises a region in contact with a top surface of the first layer and a region in contact with a side surface of the second layer.

5. The semiconductor device according to claim 1,
wherein the first insulating layer comprises a first layer, a second layer, and a third layer,
wherein the second insulating layer comprises a fourth layer, a fifth layer, and a sixth layer,
wherein the second layer is provided over the first layer,
wherein the third layer is provided over the second layer,
wherein the fifth layer is provided over the fourth layer,
wherein the sixth layer is provided over the fifth layer, and
wherein the first layer, the third layer, the fourth layer, and the sixth layer comprise nitrogen.

6. The semiconductor device according to claim 5,
wherein the second layer and the fifth layer comprise oxygen.

7. The semiconductor device according to claim 1,
wherein the semiconductor layer comprises a metal oxide.

8. The semiconductor device according to claim 7,
wherein the metal oxide comprises one or more selected from indium, zinc, and an element M, and
wherein the element Mis one or more selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

9. An electronic device comprising the semiconductor device according to claim 1, and a camera.

10. A method for manufacturing a semiconductor device, the method comprising the steps of:
forming a first conductive layer;
forming a first insulating layer over the first conductive layer;
forming a second conductive layer over the first insulating layer;
forming a second insulating layer over the second conductive layer;
forming a third conductive layer over the second insulating layer;
forming, in the first insulating layer, the second conductive layer, the second insulating layer, and the third conductive layer, an opening portion reaching the first conductive layer;
performing oxidation treatment on a side surface of the second conductive layer in the opening portion to form an oxide region in the second conductive layer;
forming a semiconductor layer to comprise a region positioned in the opening portion and to comprise a region in contact with the first conductive layer, a region in contact with the oxide region, and a region in contact with the third conductive layer;
forming a third insulating layer over the semiconductor layer to comprise a region positioned in the opening portion; and
forming a fourth conductive layer to comprise a region positioned in the opening portion and to comprise a region facing the semiconductor layer with the third insulating layer sandwiched between the region and the semiconductor layer.

11. The method for manufacturing the semiconductor device, according to claim 10,
wherein the oxidation treatment is performed by microwave treatment in an atmosphere comprising oxygen.

12. The method for manufacturing the semiconductor device, according to claim 10,
wherein a first layer and a second layer over the first layer are formed as the first conductive layer,
wherein the opening portion in the first insulating layer, the second conductive layer, the second insulating layer, and the third conductive layer is formed to reach the second layer, and
wherein the method further comprises the step of removing a region of the second layer overlapping with the opening portion after the oxidation treatment but before formation of the semiconductor layer.

13. The method for manufacturing the semiconductor device, according to claim 10, further comprising the step of:
processing the side surface of the second conductive layer in the opening portion after formation of the opening portion but before formation of the oxide region.

14. The method for manufacturing the semiconductor device, according to claim 13,
wherein the processing is performed by isotropic etching.

15. The method for manufacturing the semiconductor device, according to claim 11, further comprising the steps of:
forming a fourth insulating layer comprising a region in contact with the side surface of the second conductive layer in the opening portion after formation of the opening portion but before formation of the oxide region by the oxidation treatment; and
removing the fourth insulating layer before formation of the semiconductor layer.

16. The method for manufacturing the semiconductor device, according to claim 15,
wherein as the first insulating layer, a first layer, a second layer over the first layer, and a third layer over the second layer are formed,
wherein as the second insulating layer, a fourth layer, a fifth layer over the fourth layer, and a sixth layer over the fifth layer are formed,
wherein the fourth insulating layer is formed to comprise a region in contact with a top surface of the sixth layer,
wherein the fourth insulating layer comprises oxygen, and
wherein the sixth layer comprises nitrogen.

17. The method for manufacturing the semiconductor device, according to claim 16,
wherein the first layer, the third layer, and the fourth layer comprise nitrogen.

18. The method for manufacturing the semiconductor device, according to claim 17,
wherein the second layer and the fifth layer comprise oxygen.

19. The method for manufacturing the semiconductor device, according to claim 10,
wherein the semiconductor layer comprises a metal oxide.

20. The method for manufacturing the semiconductor device, according to claim 19,
wherein the metal oxide comprises one or more selected from indium, zinc, and an element M, and
wherein the element Mis one or more selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.
